(19) United States
(12) Patent Application Publication
(10) Pub. No.: US 2025/0012838 A1
(43) Pub. Date: Jan. 9, 2025

(54) INTELLIGENT DIAGNOSTIC PROBE

(71) Applicant: Power Probe Group, Inc., Charlotte, NC (US)

(72) Inventors: Wayne Russell, Brea, CA (US); Jason Rowe, Brea, CA (US)

(73) Assignee: Power Probe Group, Inc., Charlotte, NC (US)

(21) Appl. No.: 18/889,507

(22) Filed: Sep. 19, 2024

Related U.S. Application Data
(62) Division of application No. 16/446,493, filed on Jun. 19, 2019.
(60) Provisional application No. 62/687,185, filed on Jun. 19, 2018.

(51) Int. Cl. G01R 31/00; B60R 16/023; F02B 77/08; G06N 20/00

(52) U.S. Cl. CPC G01R 31/007; B60R 16/0234; F02B 77/083; G06N 20/00

(57) ABSTRACT

Provided herein are systems and methods for an intelligent diagnostic probe configured to provide troubleshooting guidance during diagnosing faults within vehicle electrical systems. The intelligent diagnostic probe is configured, in some embodiments, to receive raw measurement data, such as voltage, current, and resistance, from tools and take the data into an intelligence system so as to interpret the data and provide actionable output for practitioners operating the intelligent diagnostic probe. The intelligent diagnostic probe is configured, in some embodiments, to divide vehicle electrical diagnosis procedures of into segments, include appropriate tolerance ranges for readings, and provide feedback and suggestions regarding the readings. The intelligent diagnostic probe is configured, in some embodiments, to operate as an artificial intelligence that uses a large number of previously coded measurements to learn to accurately diagnose electrical faults based on currently measured raw data.

### PRIORITY

This application is a divisional of U.S. Non-Provisional patent application Ser. No. 16/446,493 filed Jun. 19, 2019, which claims the benefit of and priority to U.S. Provisional Patent Application Ser. No. 62/687,185 filed Jun. 19, 2018.

### FIELD

Embodiments of the present disclosure generally relate to the field of electrical measuring devices. More specifically, embodiments of the disclosure relate to systems and methods for an intelligent diagnostic probe configured to provide troubleshooting guidance during diagnosing faults within vehicle electrical systems.

### BACKGROUND

Motor vehicles, such as automobiles and trucks, are becoming increasingly technologically sophisticated, requiring correspondingly more sophisticated testing equipment for maintenance and diagnostic testing. Much of the increased complexity of motor vehicles is due in part to the increased complexity of electrical circuitry and systems incorporated therein. Troubleshooting and diagnosing problems with such electrical systems requires the use of a wide array of complex test equipment.

Such test equipment may include, for example, devices commonly referred to as multi-meters that are configured to measure various electrical parameters, such as resistance, voltage, current, and the like. Other diagnostic testing that is typically performed on motor vehicle electrical systems includes logic probes that measure and detect the presence and polarity of voltages, as well as determining continuity in electrical circuits.

A drawback to conventional test equipment, however, is that while the complexity of vehicle electrical circuitry has skyrocketed, there remains little, if any, guidance available to practitioners attempting to detect and identify faults within such electrical systems. As such, there is a continuous need for testing equipment that is capable of guiding practitioners and assisting with troubleshooting during diagnosing faults within vehicle electrical systems.

### SUMMARY

A system and a method are provided for an intelligent diagnostic probe configured to provide troubleshooting guidance during diagnosing faults within vehicle electrical systems. The intelligent diagnostic probe is configured, in some embodiments, to receive raw measurement data, such as voltage, current, and resistance, from tools and take the data into an intelligence system so as to interpret the data and provide actionable output for practitioners operating the intelligent diagnostic probe. The intelligent diagnostic probe is configured, in some embodiments, to divide vehicle electrical diagnosis procedures of into segments, include appropriate tolerance ranges for readings, and provide feedback and suggestions regarding the readings. The intelligent diagnostic probe is configured, in some embodiments, to operate as an artificial intelligence that uses a large number of previously coded measurements to learn to accurately diagnose electrical faults based on currently measured raw data.

In an exemplary embodiment, an intelligent diagnostic probe for providing troubleshooting guidance during diagnosing faults within vehicle electrical systems comprises: a housing configured to be grasped in a hand; a conductive probe element protruding distally from the housing; a distal probe tip of the conductive probe element configured to be placed into contact with an electrical circuit; a display screen configured to display measurement data; a power cable extending from a bottom end of the housing and configured to be connected to a motor vehicle battery; and a ground lead coupled with the power cable and configured to be electrically connected a ground source.

In another exemplary embodiment, the intelligent diagnostic probe is configured to interpret the measurement data so as to provide actionable output for a practitioner operating the intelligent diagnostic probe. In another exemplary embodiment, the intelligent diagnostic probe is configured to divide diagnosing faults within the vehicle electrical system into procedural segments. In another exemplary embodiment, the intelligent diagnostic probe is configured to provide appropriate tolerance ranges related to the measurement data. In another exemplary embodiment, the intelligent diagnostic probe is configured to provide feedback and suggestions regarding the measurement data.

In another exemplary embodiment, the intelligent diagnostic probe is configured to operate as an artificial intelligence that uses a large number of previously coded measurements to learn to accurately diagnose electrical faults based on the current measurement data. In another exemplary embodiment, the intelligent diagnostic probe comprises a database server system which stores data that is needed during operation of the intelligent diagnostic probe. In another exemplary embodiment, the database server system comprises data specific to vehicle electrical diagnosis procedures, such as vehicle types, makes and models, measurable tolerance ranges for various components, and any other vehicle-related information that may be associated with operating the intelligent diagnostic probe. In another exemplary embodiment, the intelligent diagnostic probe is configured to predict vehicle electrical diagnoses by using the vehicle-related data stored in the database server system and raw measurement data to intelligently predict the most likely electrical faults.

In another exemplary embodiment, the intelligent diagnostic probe includes one or more illumination lights that are configured to convey visual indications to an operator of the probe. In another exemplary embodiment, the one or more illumination lights are light emitting diodes (LEDs) that are configured to emit green and red light so as to convey information to the operator. In another exemplary embodiment, a green light indicates a measured voltage that is close to a ground voltage and a red light indicates a voltage near a battery voltage.

In another exemplary embodiment, the display screen is configured to display different background colors to indicate different measurement modes. In another exemplary embodiment, the intelligent diagnostic probe is configured to provide an icon-based user interface. In another exemplary embodiment, the icon-based user interface includes any one or more of a Multimeter icon, an Injector icon, an EZ-Leaming icon, a Settings icon, a Guided Diagnostics icon, and a Sensors icon. In another exemplary embodiment, the intelligent diagnostic probe includes one or more navigation buttons and a selection button configured to facilitate an operator interacting with the icon-based user interface.

In another exemplary embodiment, the intelligent diagnostic probe further includes a guided multimeter functionality that is divided into a series guided segments in which suitable minimum and maximum values are shown in relation to each measured value. In another exemplary embodiment, the guided multimeter functionality is configured to facilitate measuring DC/AC voltages, electrical resistance, and electrical frequencies. In another exemplary embodiment, the intelligent diagnostic probe further includes a guided fuel injector analysis functionality that is configured to guide a practitioner through a series of steps comprising a fuel injector analysis. In another exemplary embodiment, the intelligent diagnostic probe further includes a sensor diagnosis functionality that is configured to guide a practitioner through a series of sensor analysis steps and provide troubleshooting based on measured values. In another exemplary embodiment, the intelligent diagnostic probe further includes a guided diagnostic functionality that is configured to guide a practitioner through a series of steps comprising measuring and diagnosing faults in various components comprising a vehicle electrical system.

### BRIEF DESCRIPTION OF THE DRAWINGS

The drawings refer to embodiments of the present disclosure in which:

FIGS. 1-5 illustrate an exemplary embodiment of an intelligent diagnostic probe configured to assist with troubleshooting and provide guidance during diagnosing faults within vehicle electrical systems;

FIGS. 6-13 illustrate a multiplicity of icons comprising an exemplary embodiment of an icon-based user interface comprising the intelligent diagnostic probe of FIGS. 1-5;

FIGS. 14-33 illustrate an exemplary embodiment of a guided multimeter functionality of the intelligent diagnostic probe of FIGS. 1-5 that is accessible by selecting a Multimeter icon shown in FIG. 14;

FIGS. 34-38 illustrate an exemplary embodiment of a guided fuel injector analysis functionality of the intelligent diagnostic probe of FIGS. 1-5 that is accessible by selecting an Injector icon shown in FIG. 34;

FIGS. 39-41 illustrate an exemplary embodiment of an educational reference functionality of the intelligent diagnostic probe of FIGS. 1-5 that is accessible by selecting an EZ-Leaming icon shown in FIG. 39;

FIGS. 42-97 illustrate an exemplary embodiment of a sensor diagnosis functionality of the intelligent diagnostic probe of FIGS. 1-5 that is accessible by selecting a Sensors icon shown in FIG. 42;

FIGS. 98-123 illustrate an exemplary embodiment of a guided diagnostic functionality of the intelligent diagnostic probe of FIGS. 1-5 that is accessible by selecting a Guided Diagnostics icon shown in FIG. 97;

FIGS. 124-125 illustrates an exemplary embodiment of a Settings icon that may be selected to access a multiplicity of settings that affect the operation of the intelligent diagnostic probe of FIGS. 1-5;

FIGS. 126-128 illustrate a multiplicity of settings that affect the operation of an exemplary embodiment of a wireless connectivity functionality of the intelligent diagnostic probe of FIGS. 1-5 that is accessible by selecting a Bluetooth icon shown in FIG. 126;

FIGS. 129-131 illustrate a multiplicity of settings that affect a start mode of the intelligent diagnostic probe of FIGS. 1-5 that is accessible by selecting a Start Mode icon shown in FIG. 129;

FIGS. 132-134 illustrate a multiplicity of settings that facilitate updating an operating system of the intelligent diagnostic probe of FIGS. 1-5 that is accessible by selecting an Updates icon shown in FIG. 132;

FIGS. 135-137 illustrate a multiplicity of setting that facilitate selecting a desired operational language of the intelligent diagnostic probe of FIGS. 1-5 that is accessible by selecting a Language icon shown in FIG. 135;

FIG. 138 illustrates an exemplary embodiment of Home icon whereby the intelligent diagnostic probe of FIGS. 1-5 may be returned to a default home screen shown in FIG. 1;

FIGS. 139-146 illustrate a multiplicity of screens that may be displayed on the intelligent diagnostic probe of FIGS. 1-5, according to the present disclosure; and

FIGS. 139-146 illustrate exemplary embodiments of various alert screens that may be displayed during the course of operating the intelligent diagnostic probe 100 of FIGS. 1-5, as described with respect to FIGS. 1-138.

While the present disclosure is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the present disclosure.

### DETAILED DESCRIPTION

In the following description, numerous specific details are set forth in order to provide a thorough understanding of the present disclosure. It will be apparent, however, to one of ordinary skill in the art that the invention disclosed herein may be practiced without these specific details. In other instances, specific numeric references such as “first circuit,” may be made. However, the specific numeric reference should not be interpreted as a literal sequential order but rather interpreted that the “first circuit” is different than a “second circuit.” Thus, the specific details set forth are merely exemplary. The specific details may be varied from and still be contemplated to be within the spirit and scope of the present disclosure. The term “coupled” is defined as meaning connected either directly to the component or indirectly to the component through another component. Further, as used herein, the terms “about,” “approximately,” or “substantially” for any numerical values or ranges indicate a suitable dimensional tolerance that allows the part or collection of components to function for its intended purpose as described herein.

As the complexity of vehicle electrical circuity has increased, conventional testing equipment offered little, if any, guidance to practitioners attempting to detect and identify faults within such electrical systems. Therefore, a continuous need exists for testing equipment that is capable of guiding practitioners and assisting with troubleshooting during diagnosing faults within vehicle electrical systems. Provided herein, in some embodiments, are systems and methods for an intelligent diagnostic probe configured to provide troubleshooting guidance during diagnosing faults within vehicle electrical systems. The intelligent diagnostic probe is configured, in some embodiments, to receive raw measurement data, such as voltage, current, and resistance, from tools and take the data into an intelligence system so as to interpret the data and provide actionable output for practitioners operating the intelligent diagnostic probe. The intelligent diagnostic probe is configured, in some embodiments, to divide vehicle electrical diagnosis procedures of into segments, include appropriate tolerance ranges for readings, and provide feedback and suggestions regarding the readings. Further, in some embodiments, the intelligent diagnostic probe is configured as an artificial intelligence that uses a large number of previously coded measurements to learn to accurately diagnose electrical faults based on currently measured raw data.

In some embodiments, the intelligent diagnostic probe further comprises a database server system which stores any data that may be needed during the operation of the probe. In some embodiments, the database server system may comprise data specific to vehicle electrical diagnosis procedures, such as vehicle types, makes and models, measurable tolerance ranges for various components, and any other vehicle-related information that may be associated with operating the intelligent diagnostic probe. It is contemplated that, in some embodiments, the intelligent diagnostic probe may be configured to predict vehicle electrical diagnoses. For example, the intelligent diagnostic probe may use the vehicle-related data stored in the database server system and raw measurement data to intelligently predict the most likely electrical faults. With access to the database server system, the intelligent diagnostic probe may be configured as an artificial intelligence that uses a large number of previously coded events to learn to accurately diagnose electrical faults based on currently measured raw data. It is contemplated, therefore, that the intelligent diagnostic probe may be configured to provide a guidance and troubleshooting system that is exponentially more accurate than relying on practitioner experience alone.

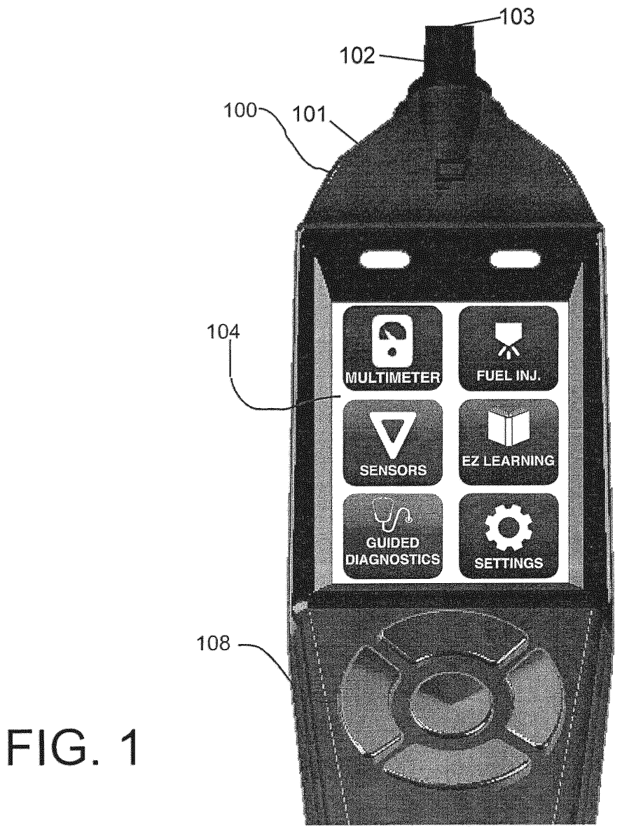

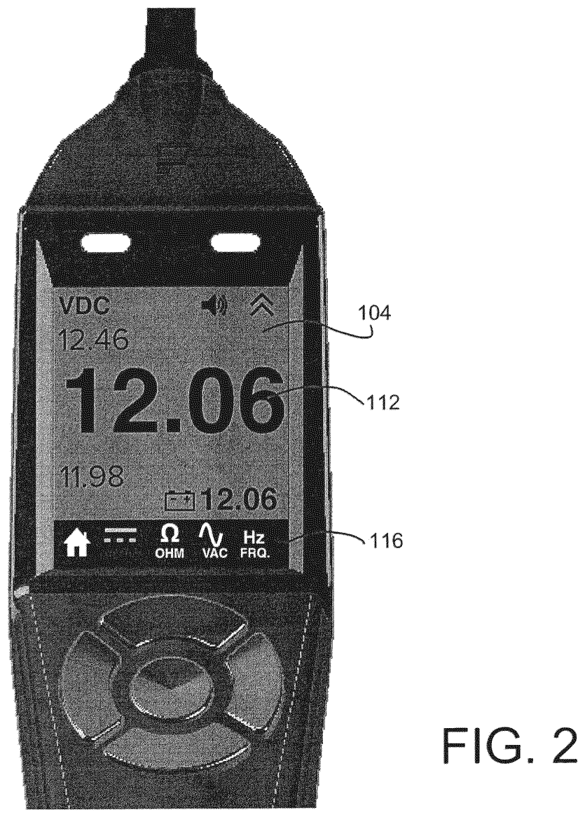

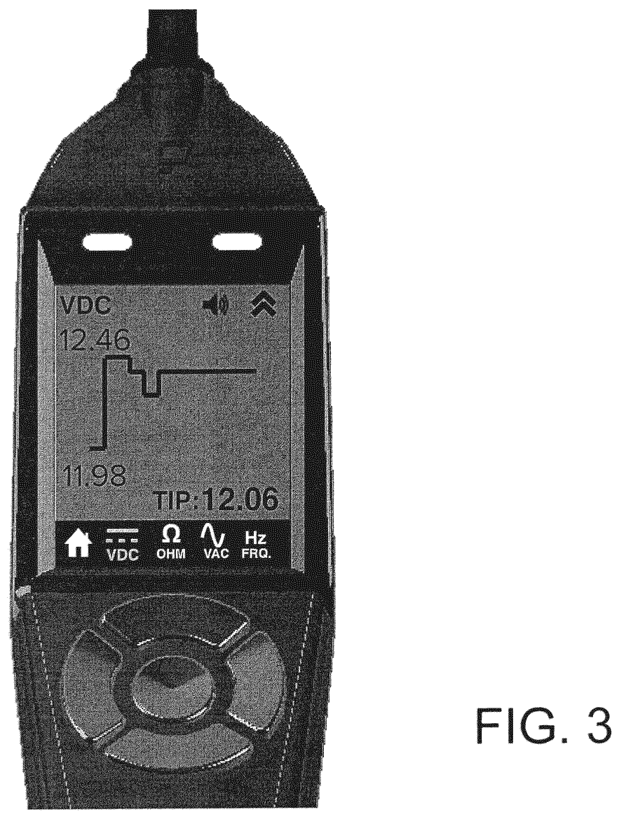

FIGS. 1-5 illustrate an exemplary embodiment of an intelligent diagnostic probe 100 configured to assist with troubleshooting and provide guidance during diagnosing faults within vehicle electrical systems. In the illustrated embodiment, the intelligent diagnostic probe 100 includes an icon-based user interface displayed on a screen 104 and 4-directional navigation buttons 108. The navigation buttons 108 are configured to enable a practitioner to navigate and select icons comprising the icon-based interface 104. As shown in FIGS. 2-3, the probe 100 is capable of displaying minimum and maximum readings respectively below and above a center tip reading 112. As will be appreciated, the center tip reading 112 generally is a value of a parameter detected upon touching a distal probe tip to a component in the electrical system. Menu icons 116 at a bottom of the screen 104 indicate the type of parameter currently being measured. As shown in FIG. 3, all measurement modes included with the probe 100 allow for graphing, as well as minimum and maximum readings to provide instant ranging. The menu icons 116 enable a practitioner to change measurement modes, as desired.

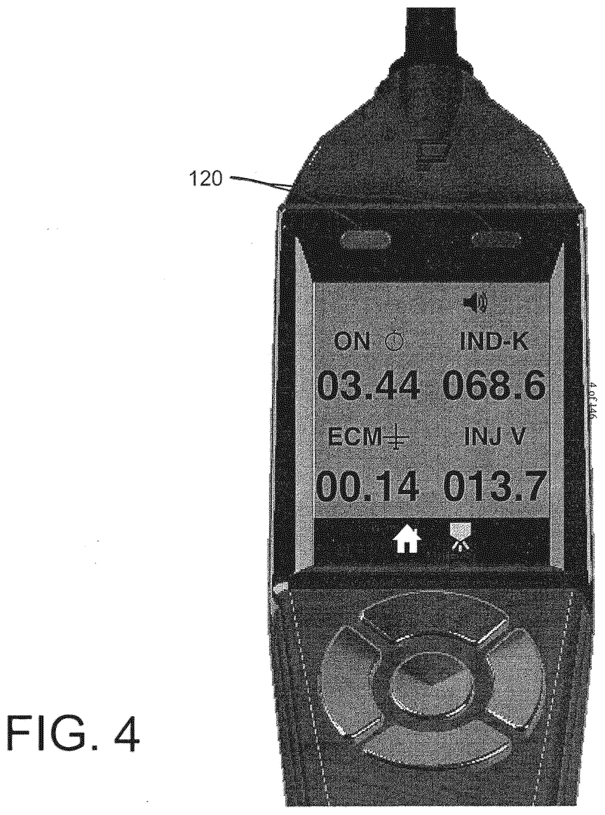

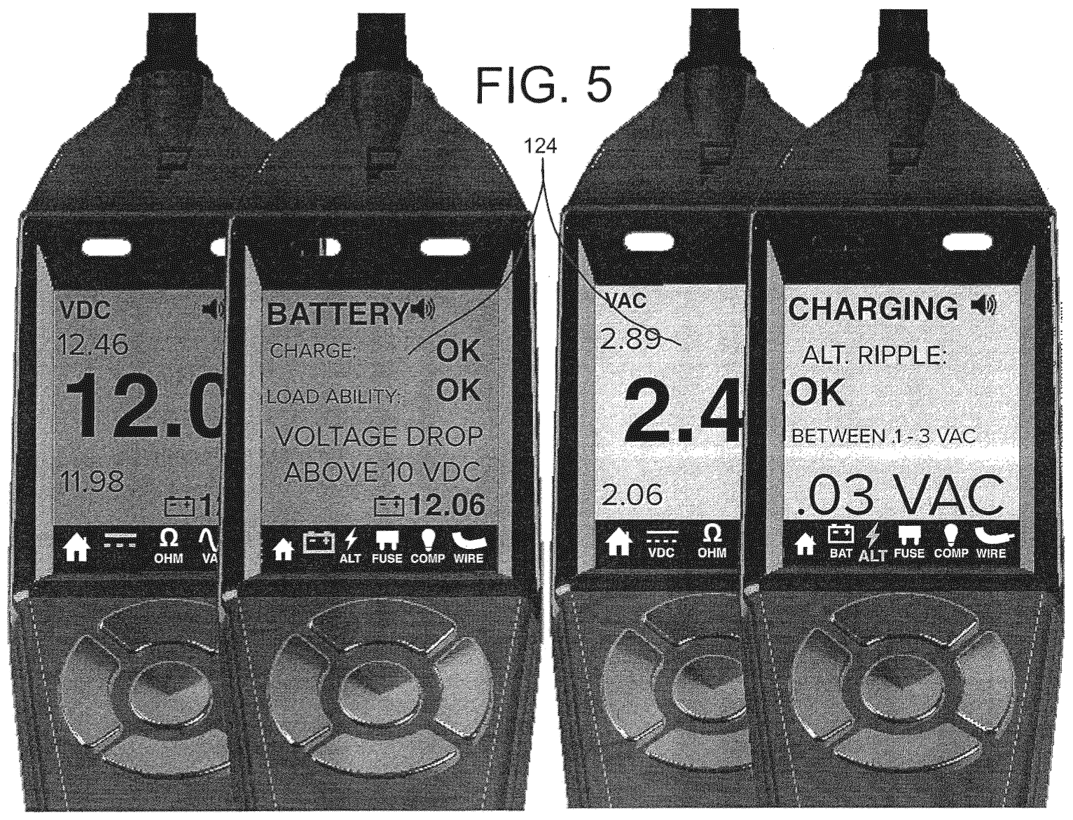

As shown in FIG. 4, the probe 100 may include one or more illumination lights 120 that are configured to convey visual indications to a practitioner operating the probe. In some embodiments, the illumination lights 120 are light emitting diodes (LEDs) that are configured to emit green and red light so as to convey information to the practitioner. For example, in some embodiments, a green light indicates a measured voltage that is close to the ground voltage, and a red light indicates a voltage near the battery voltage. Further, the screen 116 background may be displayed with different colors so as to indicate the current measurement mode, as shown in FIG. 5.

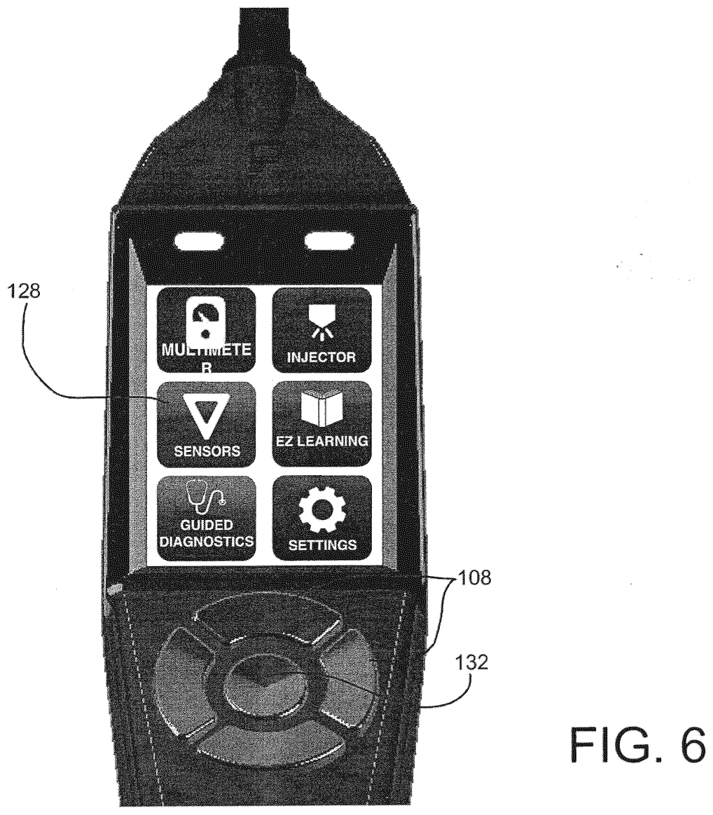

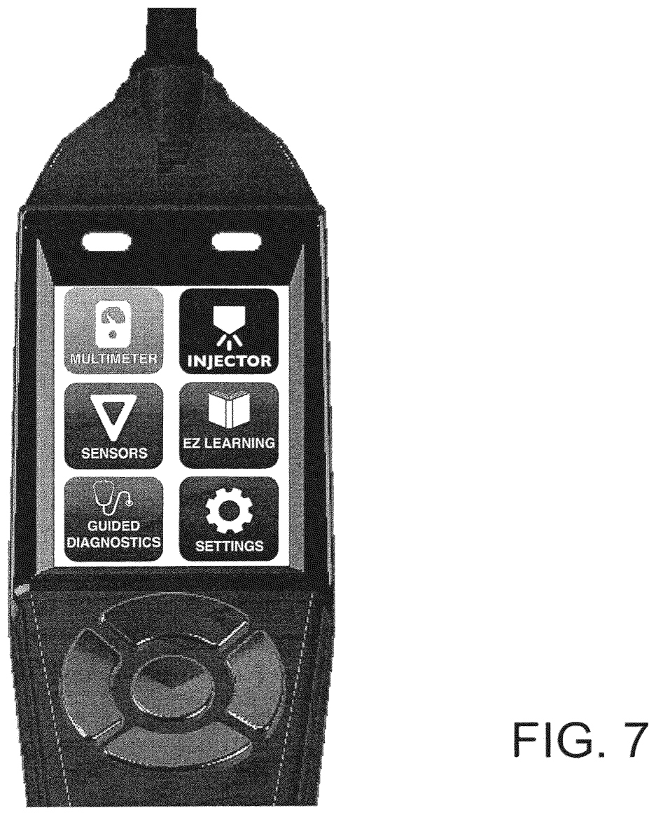

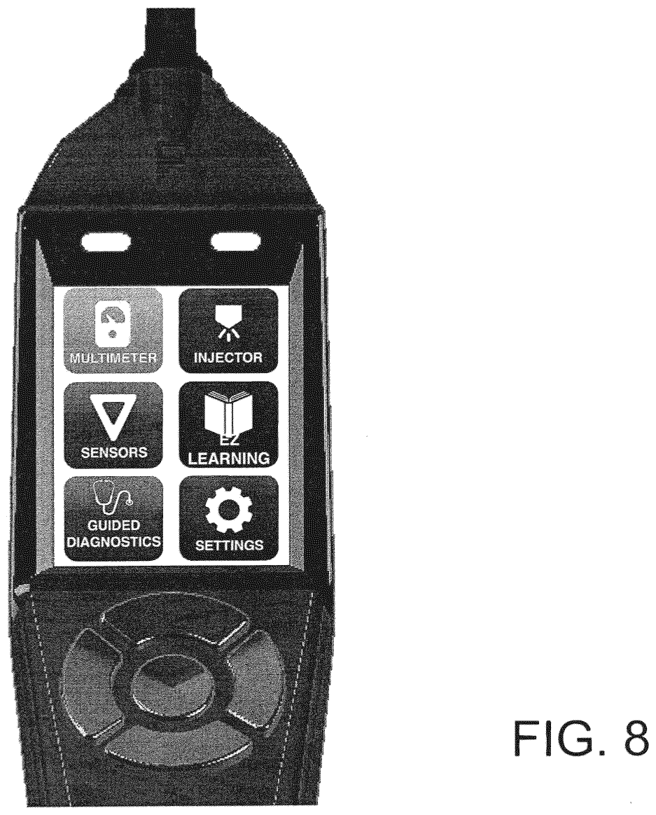

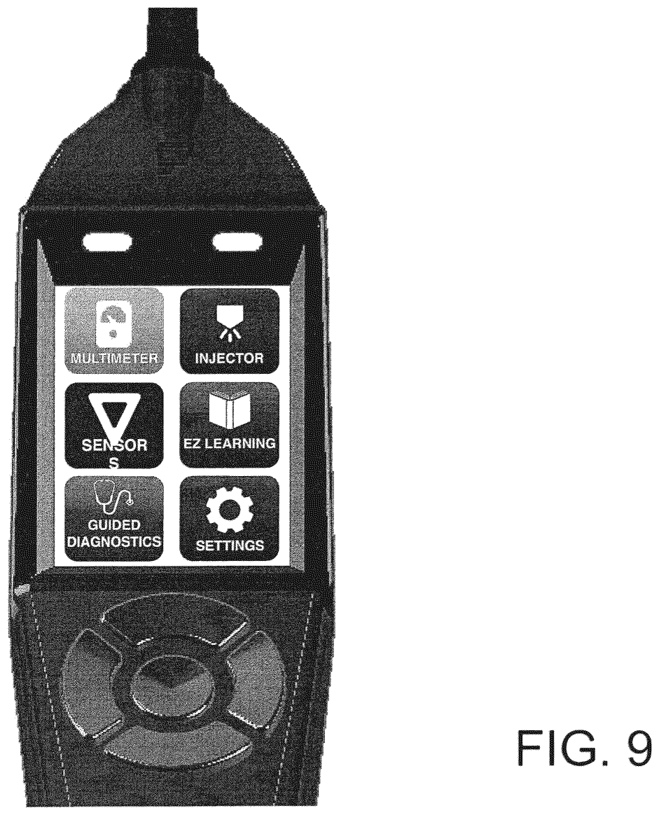

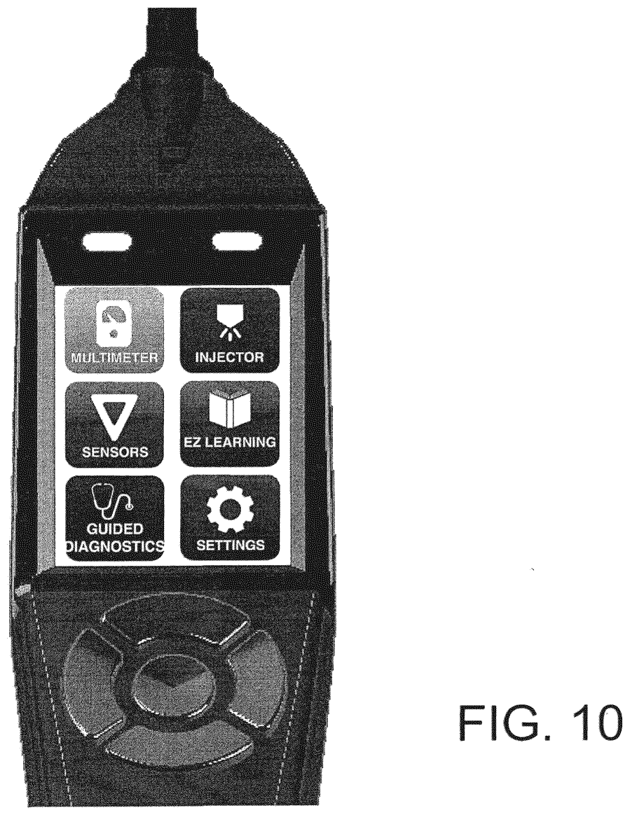

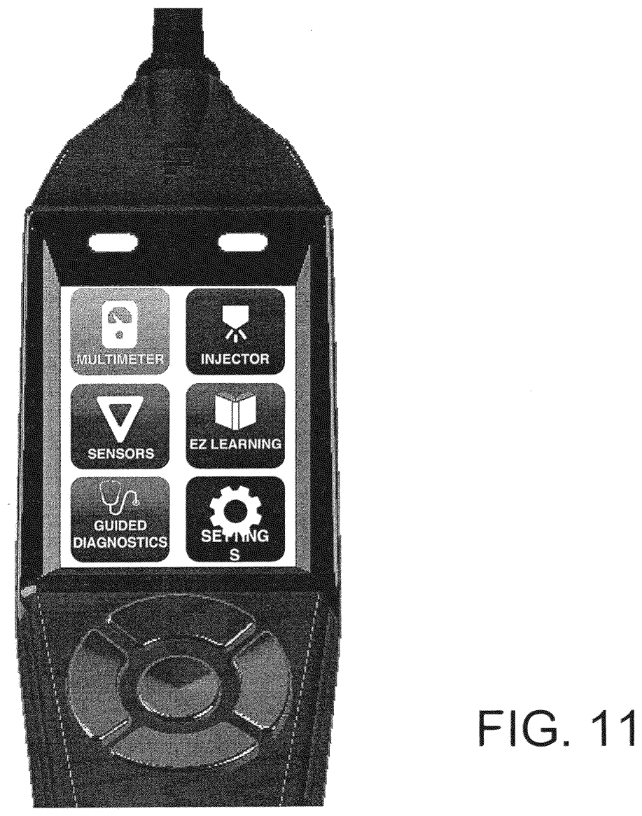

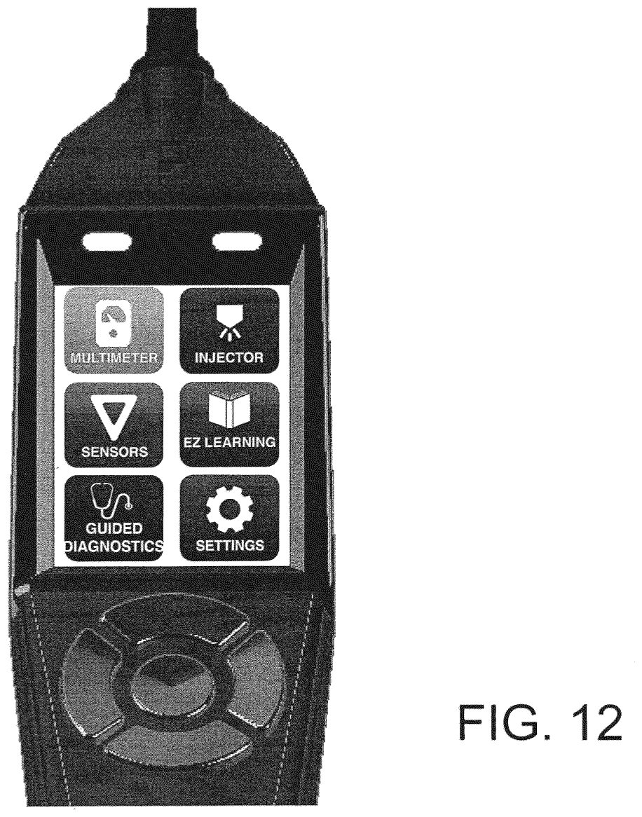

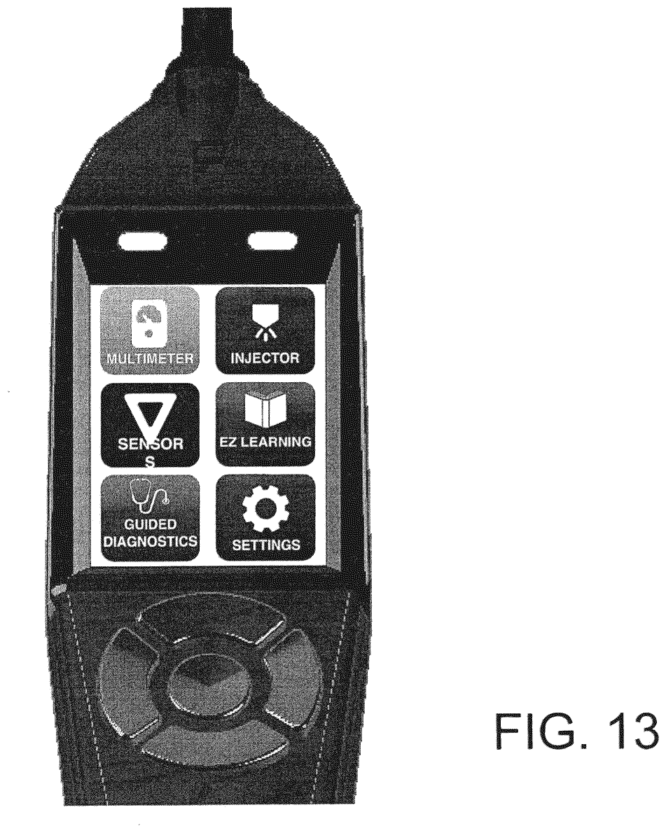

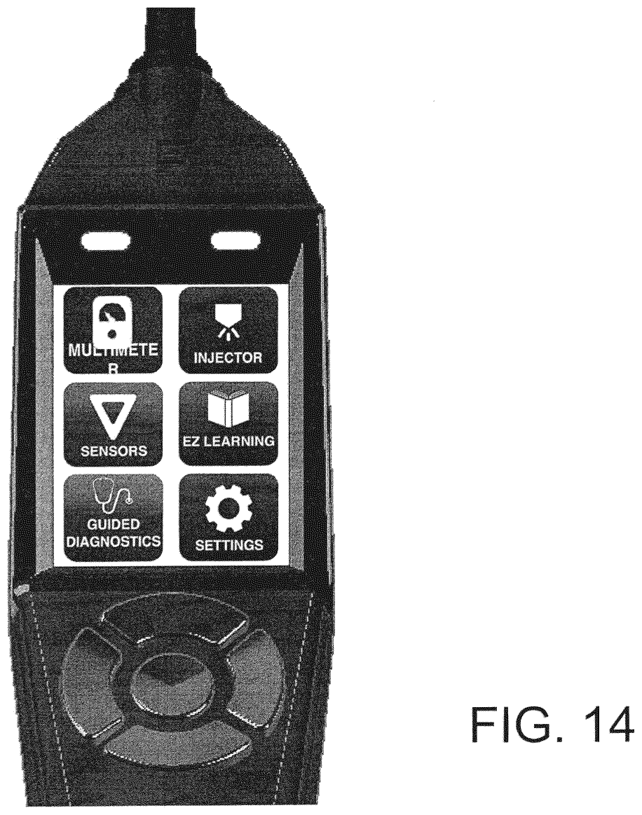

FIGS. 6-13 illustrate a multiplicity of icons 128 comprising an exemplary embodiment of an icon-based user interface 104 comprising the intelligent diagnostic probe 100 of FIGS. 1-5. In the illustrated embodiment, the icons 128 include a Multimeter icon, an Injector icon, an EZ-Learning icon, a Settings icon, a Guided Diagnostics icon, and a Sensors icon. Any one of the icons 128 may be selected by pressing the navigation buttons 108 to move the selection focus among the icons and then pressing a selection button 132 to select the desired icon. As shown in FIGS. 6-13, the icon 128 currently having the selection focus becomes highlighted and bolded.

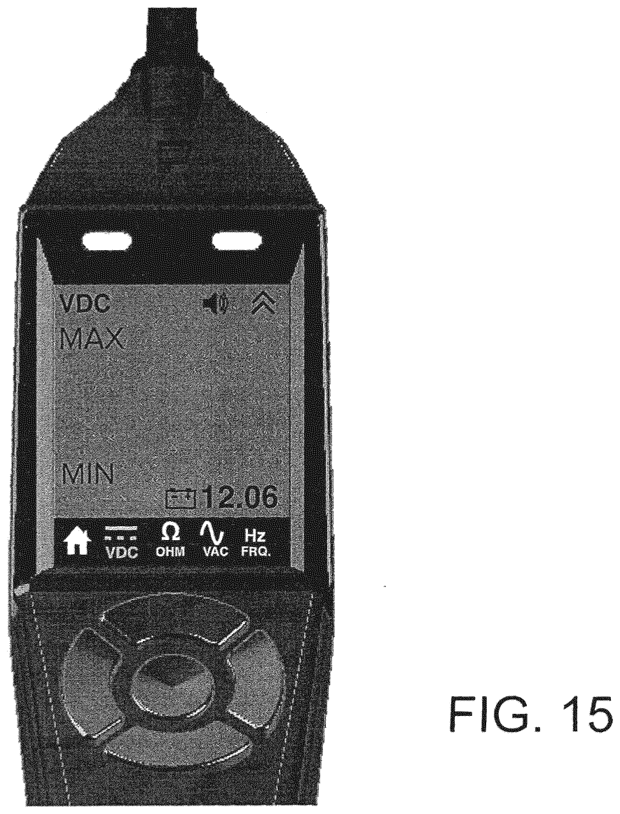

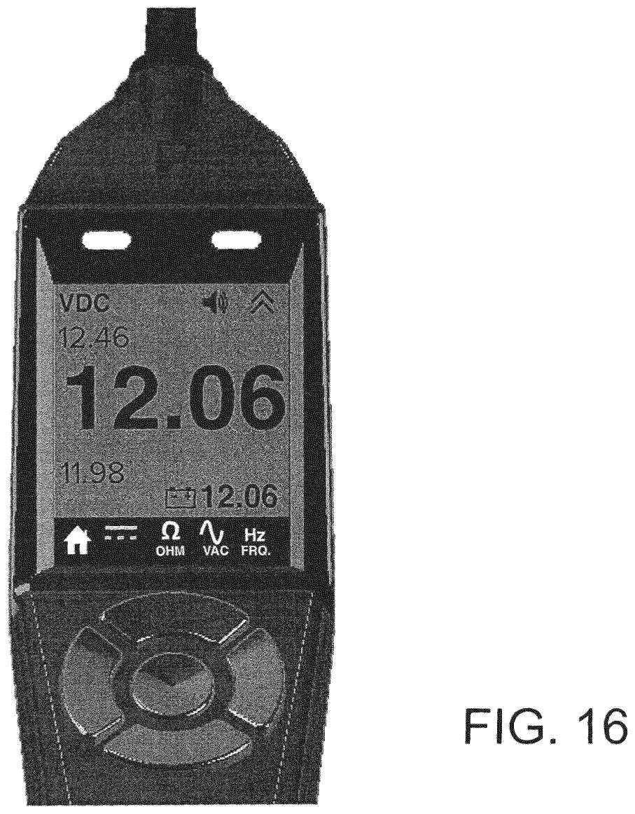

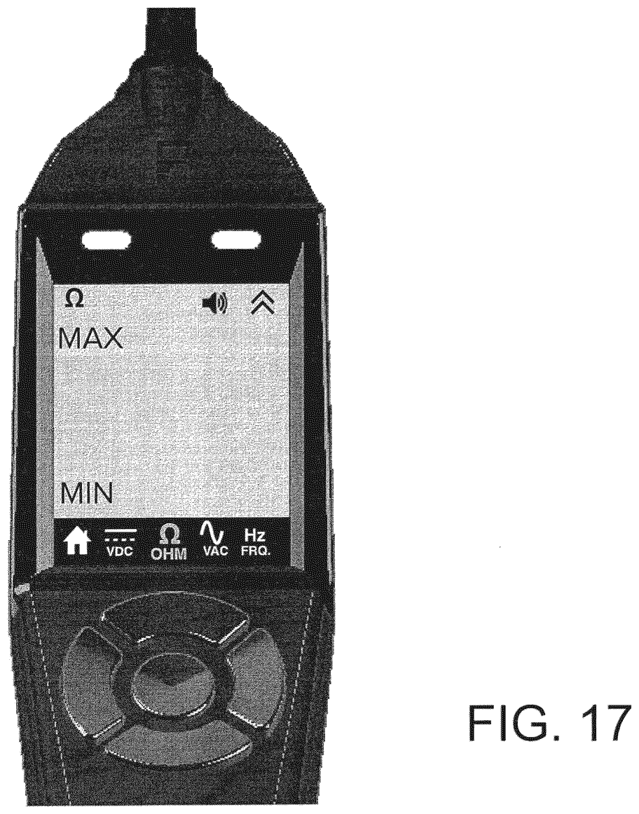

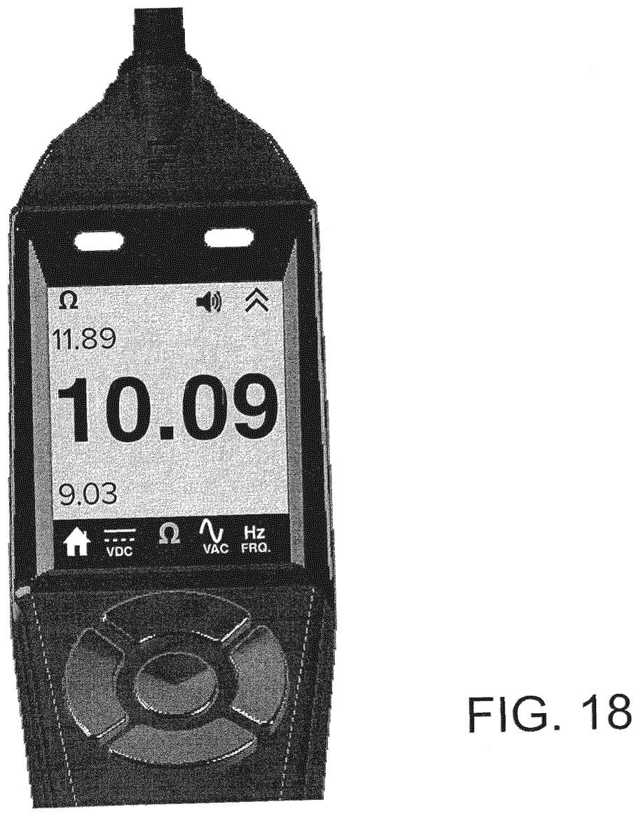

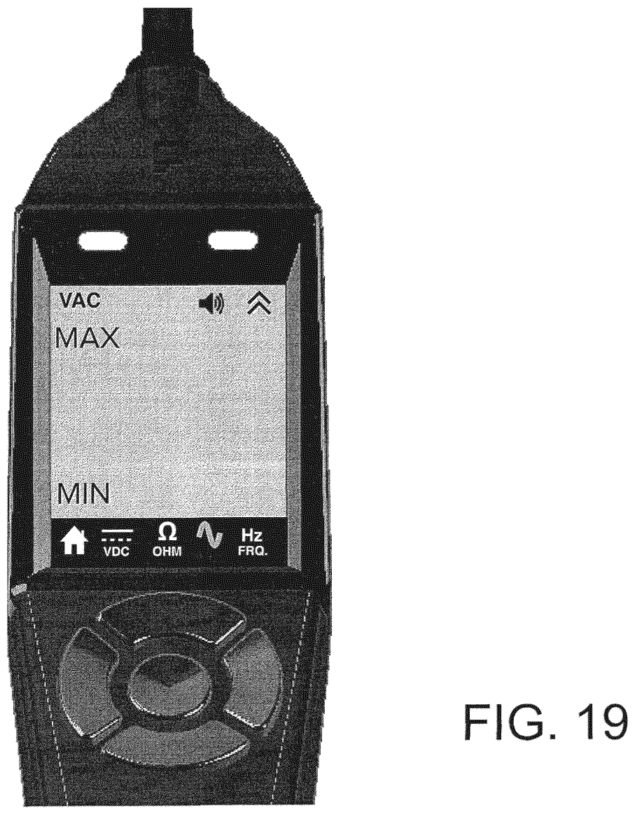

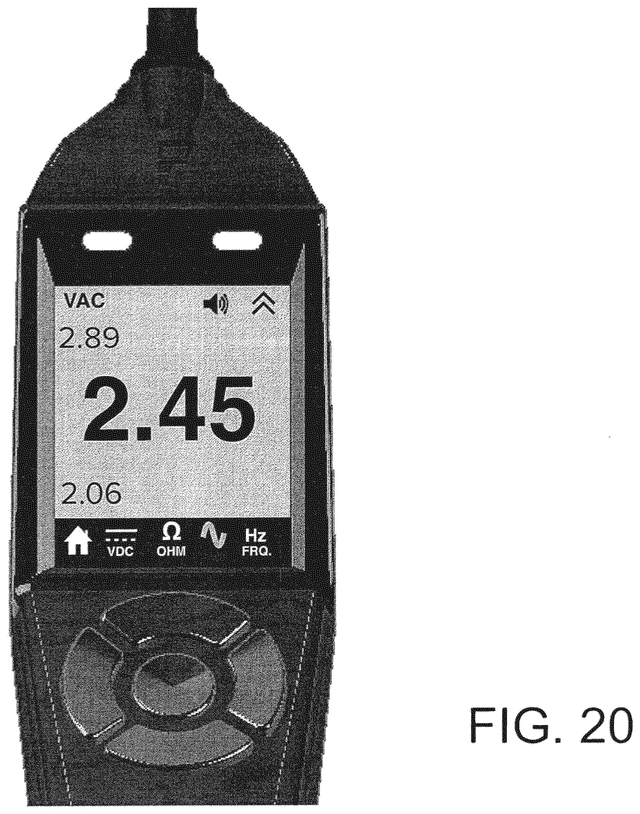

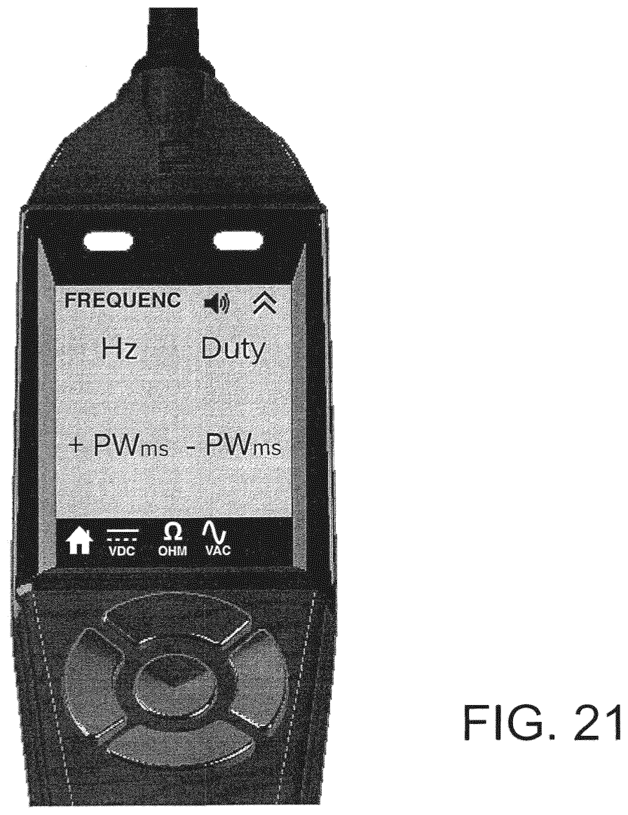

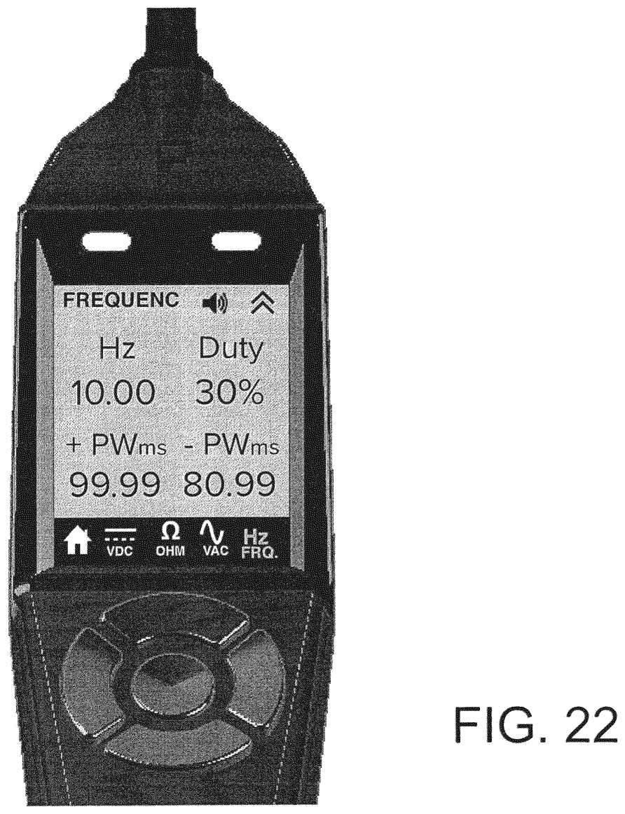

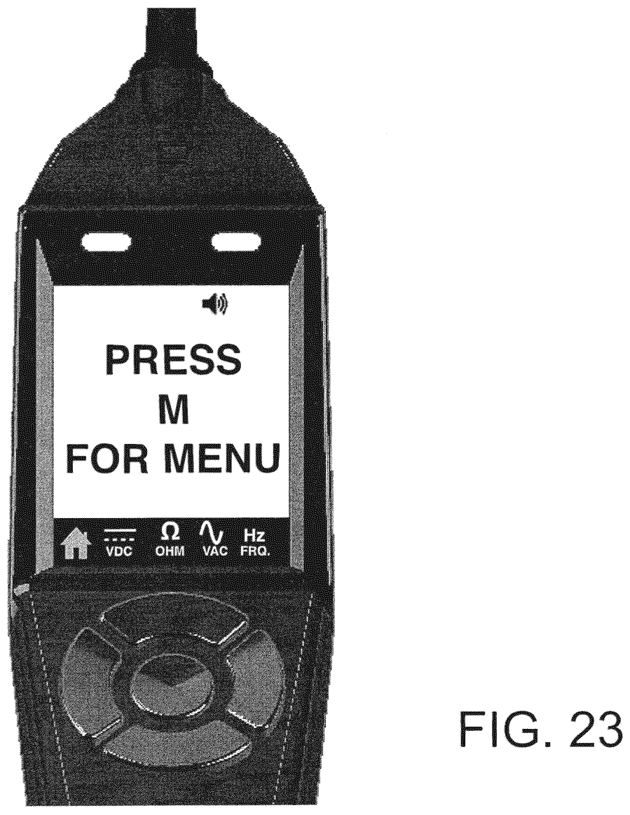

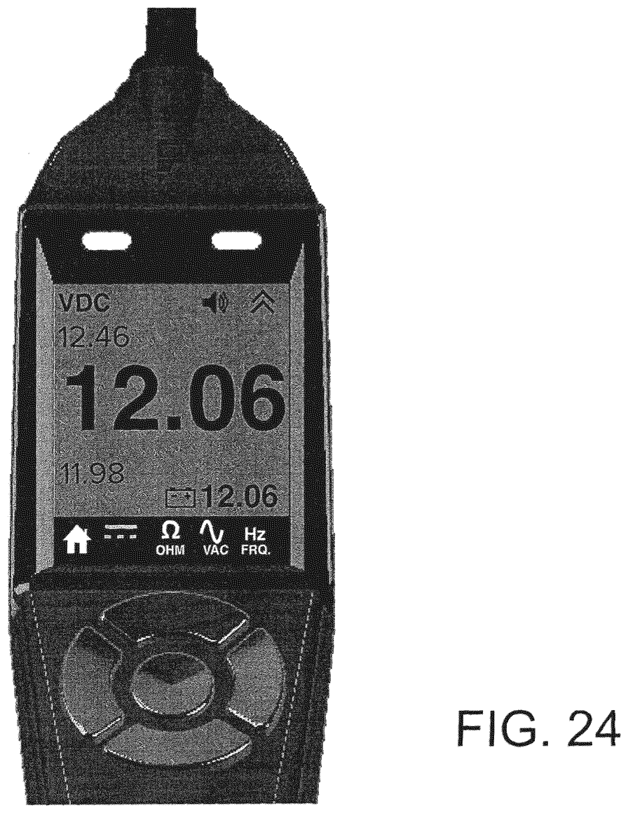

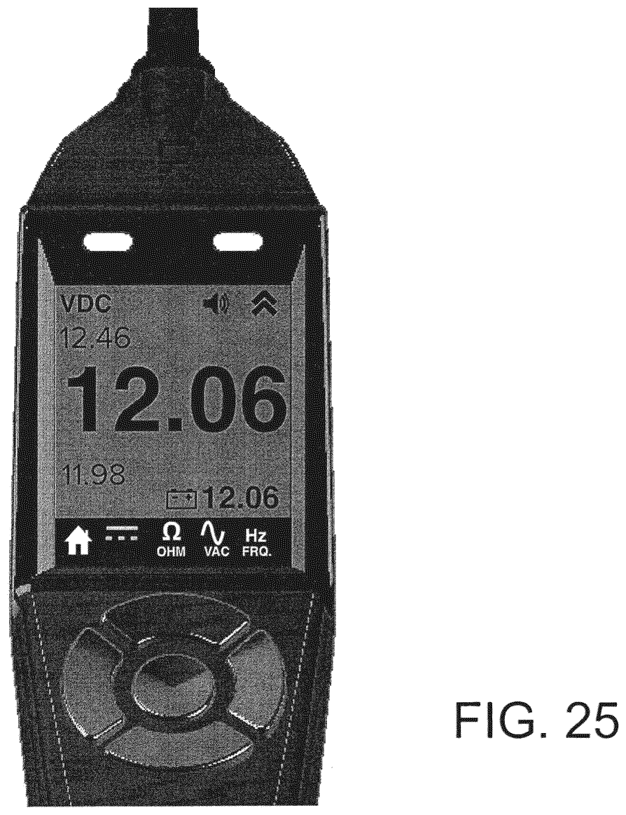

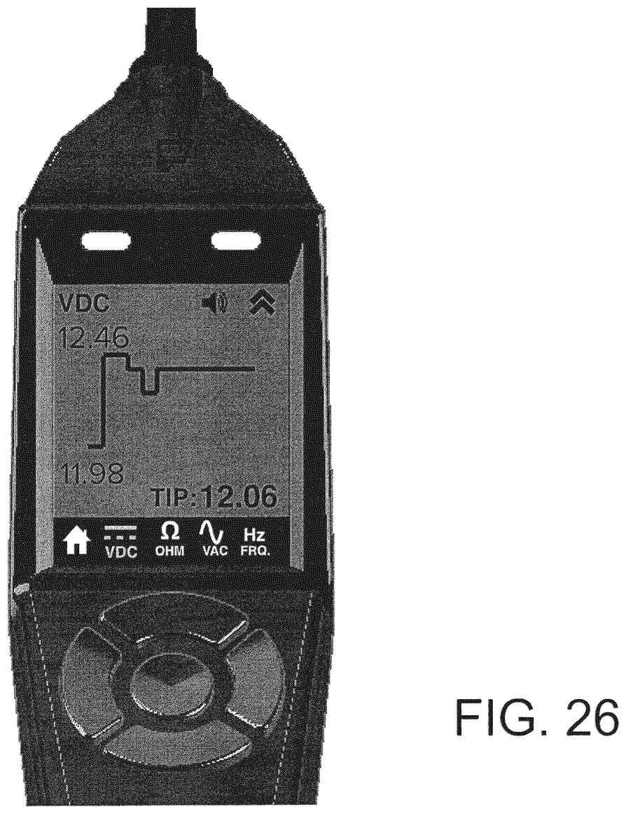

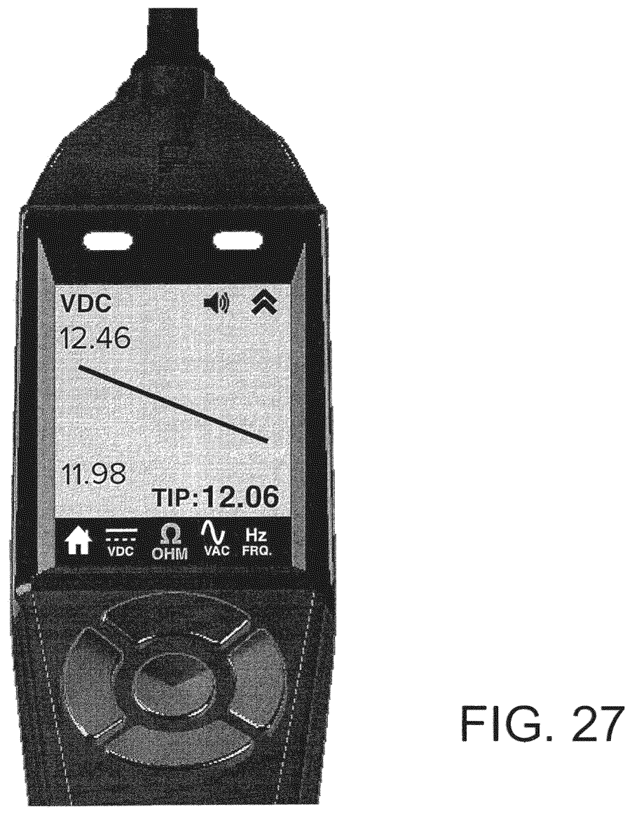

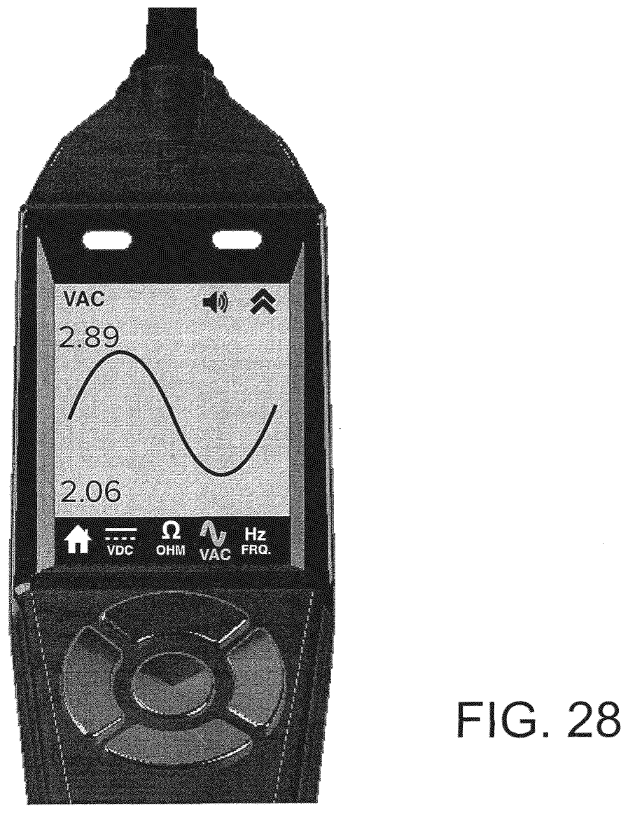

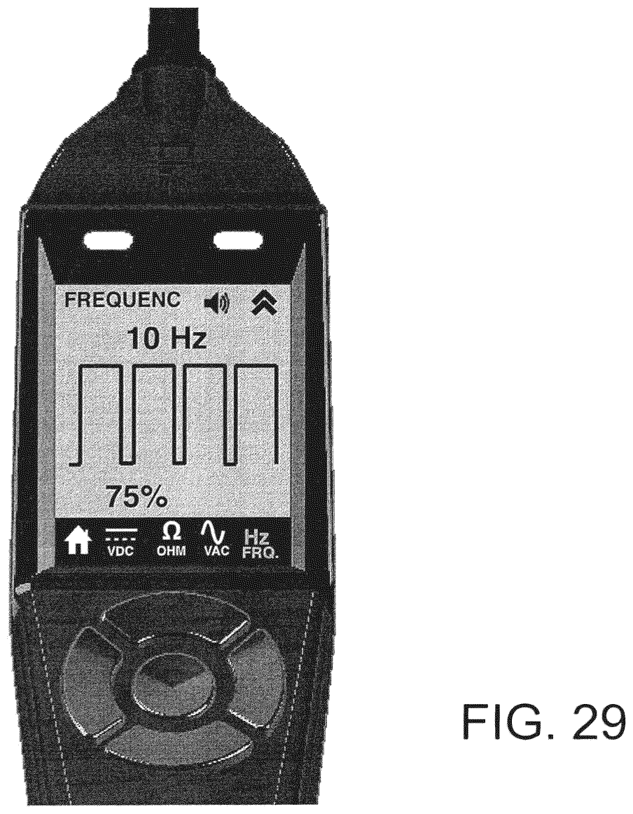

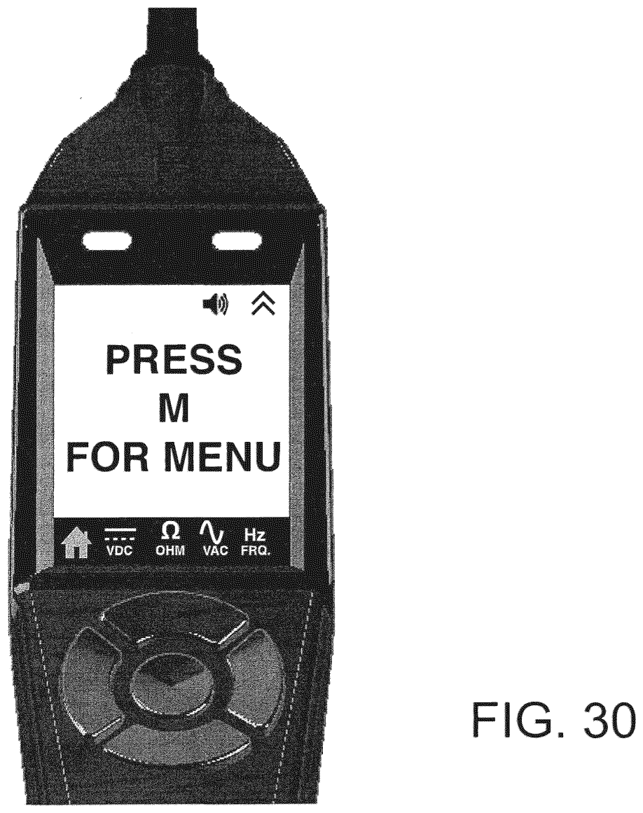

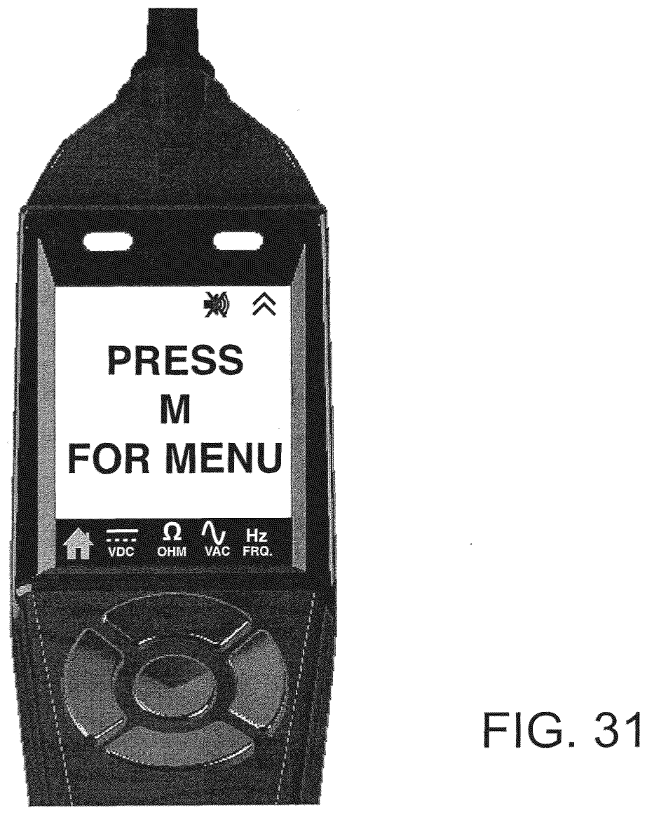

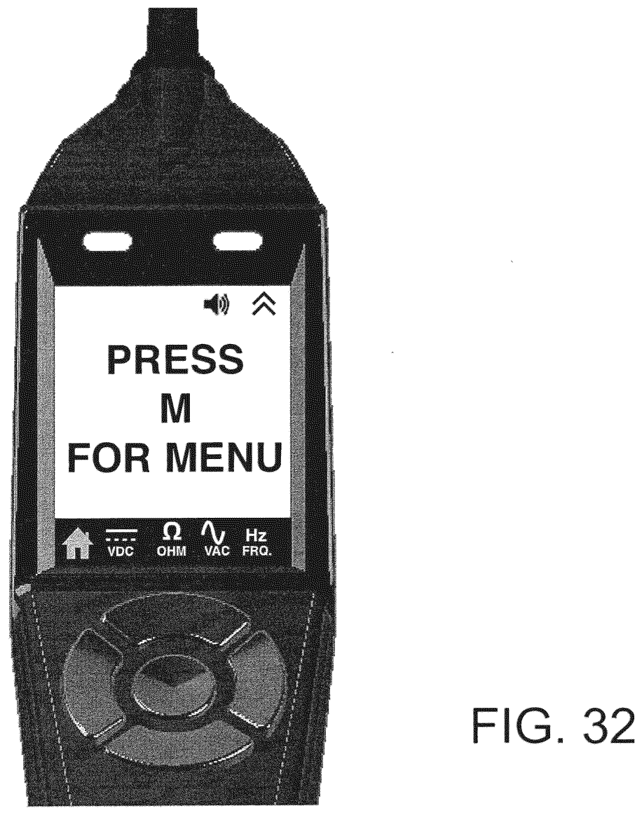

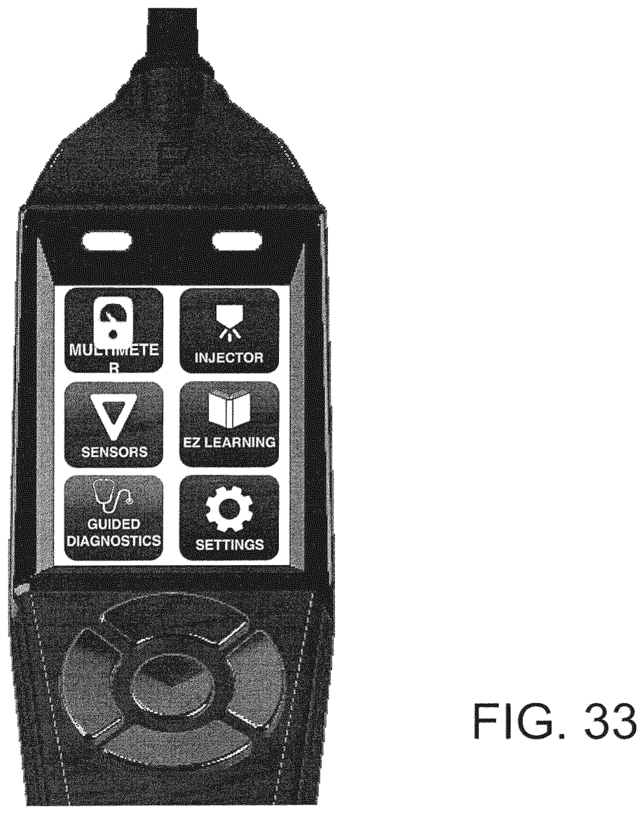

FIGS. 14-33 illustrate an exemplary embodiment of a guided multimeter functionality of the intelligent diagnostic probe 100 of FIGS. 1-5 that is accessible by selecting a Multimeter icon shown in FIG. 14. The guided multimeter functionality facilitates measuring DC voltage and AC voltage, as well as electrical resistance in Ohms and electrical frequencies in Hertz (Hz). The intelligent diagnostic probe 100 is configured, in some embodiments, to divide the multimeter functionality into a series of guided segments, wherein each measured value is shown in relation to suitable minimum and maximum values. Further, the probe 100 may provide feedback and suggestions regarding the readings.

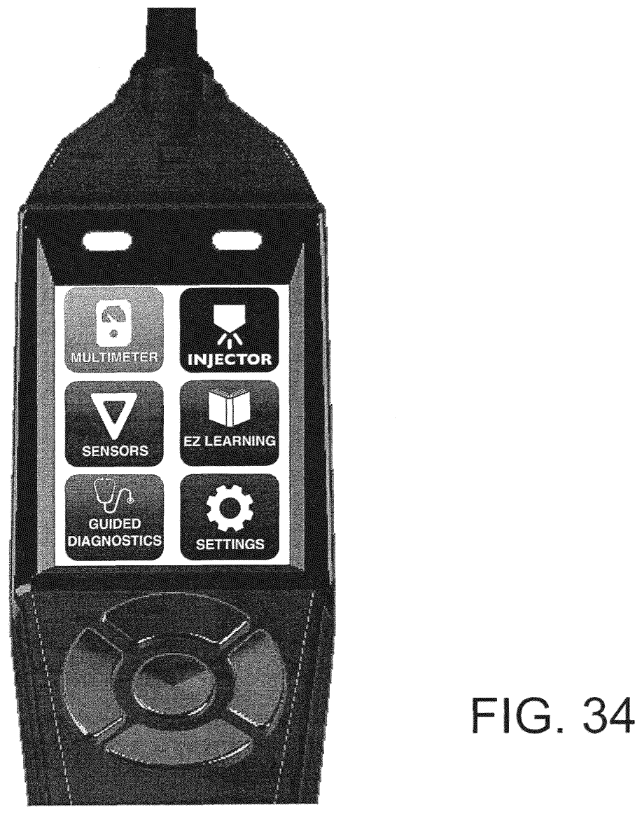

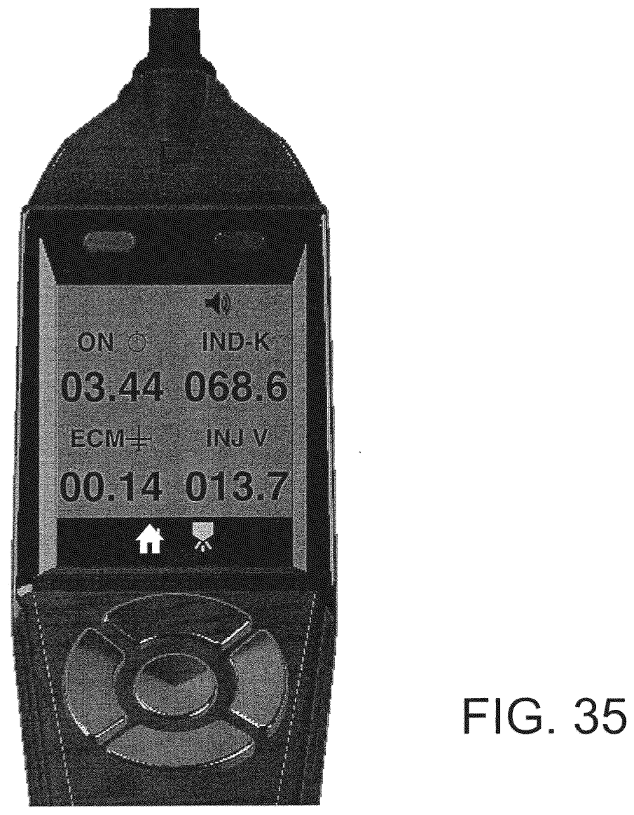

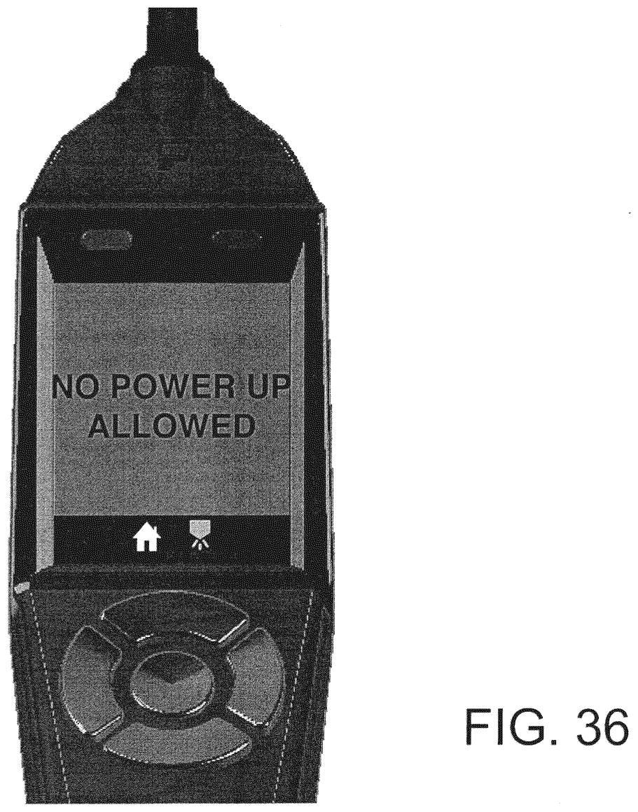

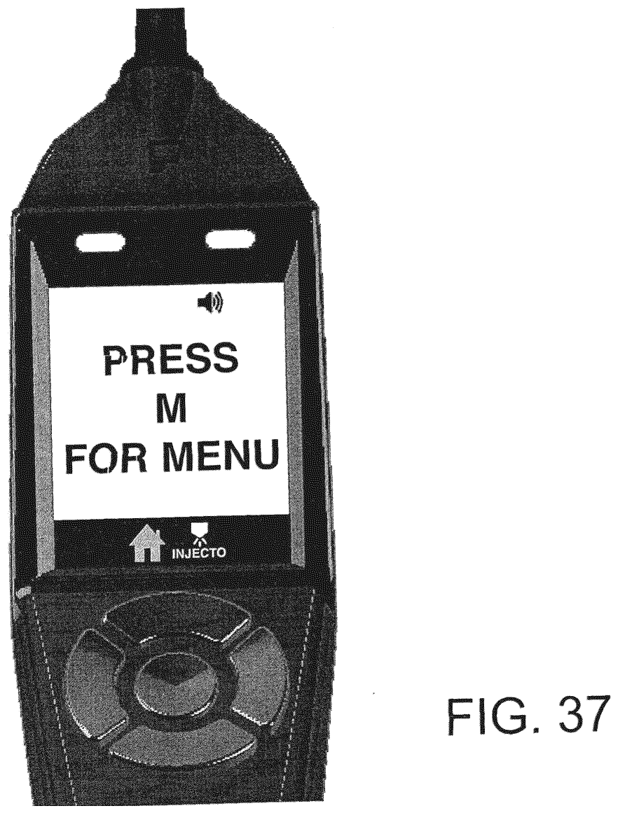

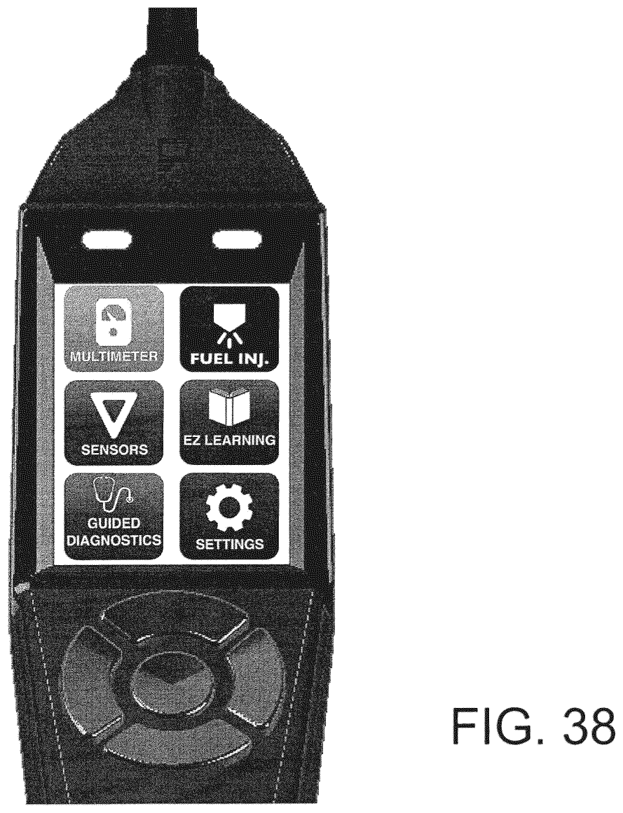

FIGS. 34-38 illustrate an exemplary embodiment of a guided fuel injector analysis functionality of the intelligent diagnostic probe 100 of FIGS. 1-5 that is accessible by selecting an Injector icon shown in FIG. 34. It is contemplated that the probe 100 is configured, in some embodiments, to guide the practitioner through a series of steps comprising the fuel injector analysis. The probe 100 may provide troubleshooting based on measured readings.

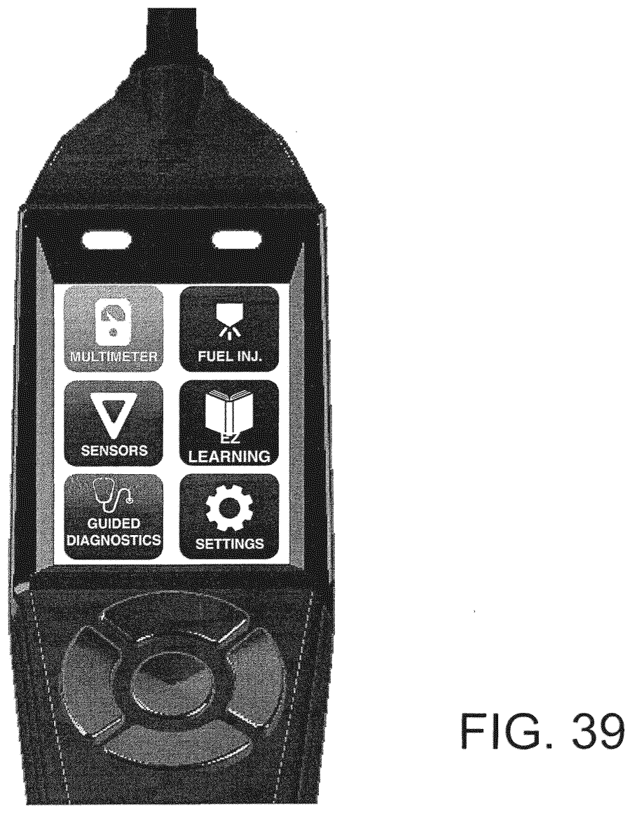

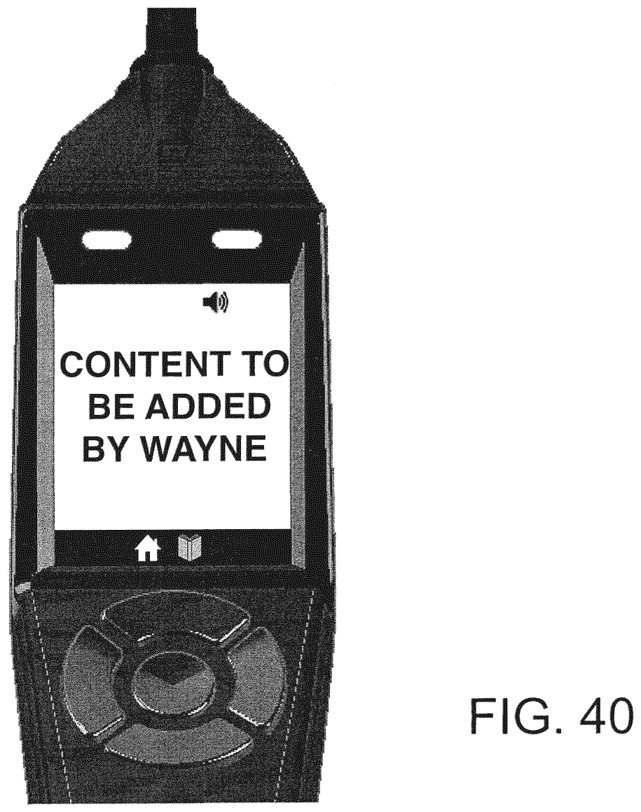

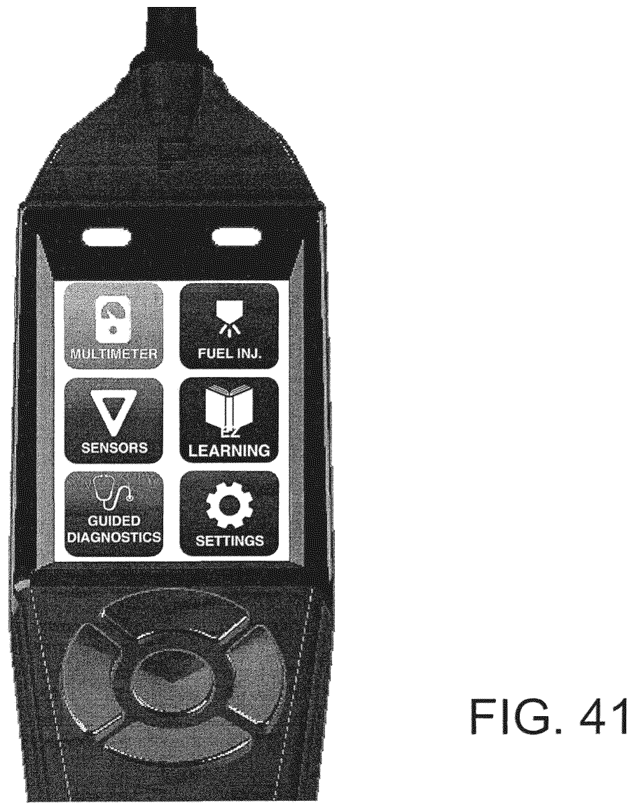

FIGS. 39-41 illustrate an exemplary embodiment of an educational reference functionality of the intelligent diagnostic probe 100 of FIGS. 1-5 that is accessible by selecting an EZ-Learning icon shown in FIG. 39. In some embodiments, the information stored in the database server may be provided to the practitioner by way of the educational reference functionality of the probe 100.

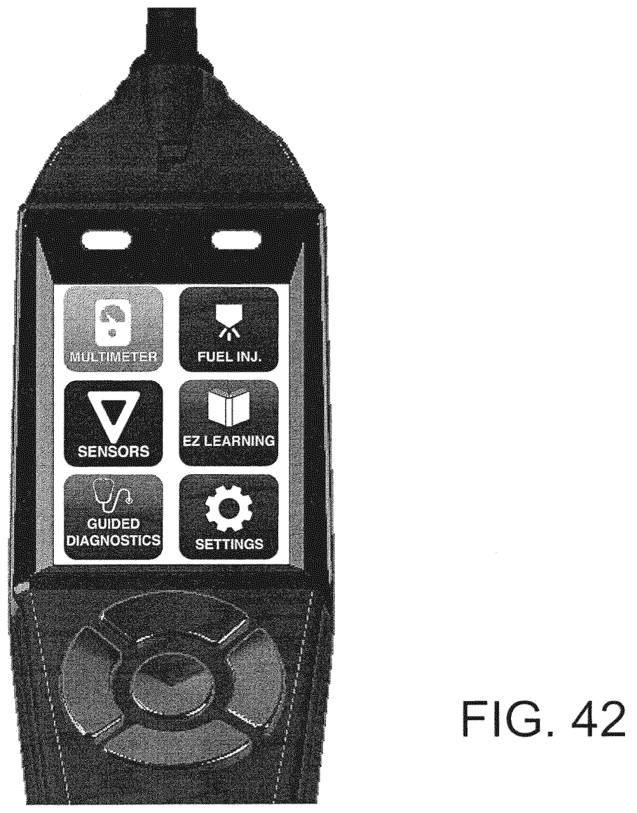

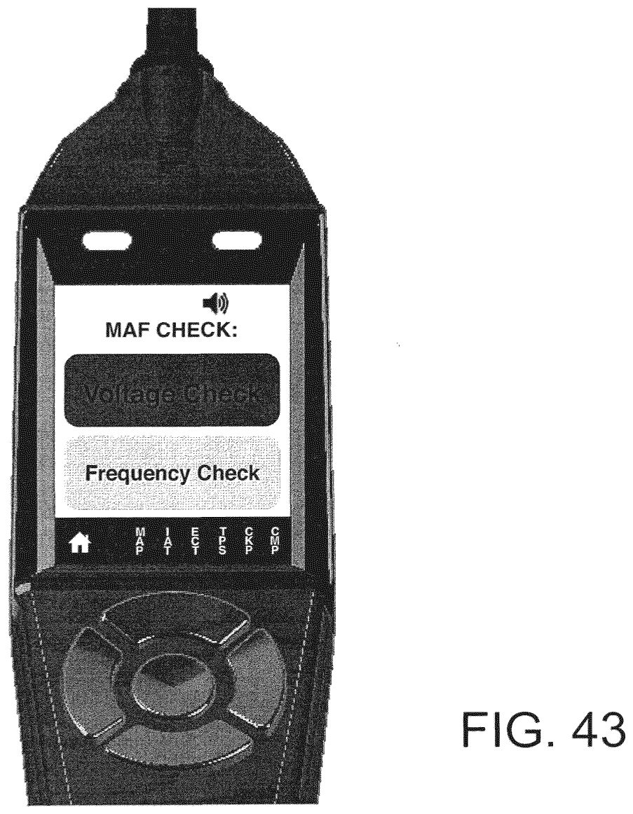

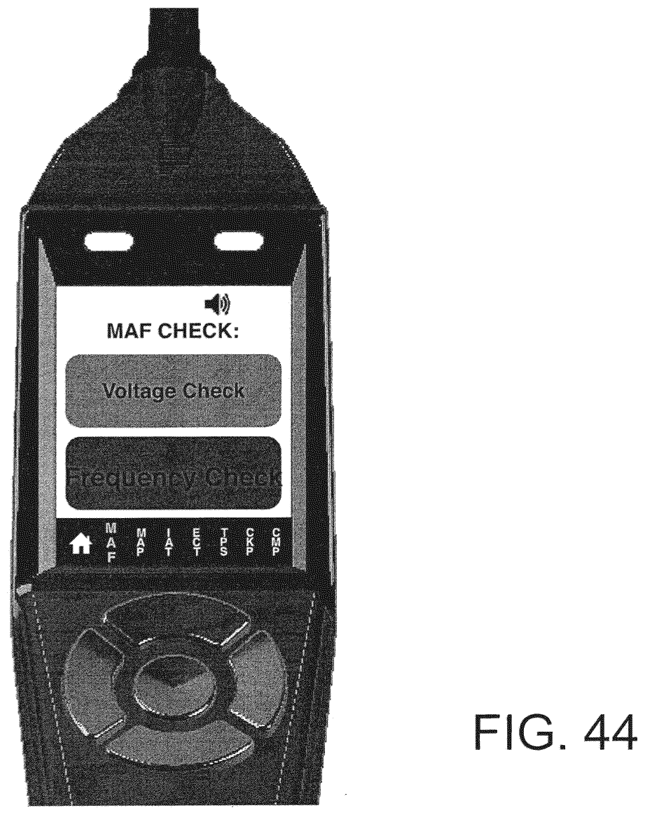

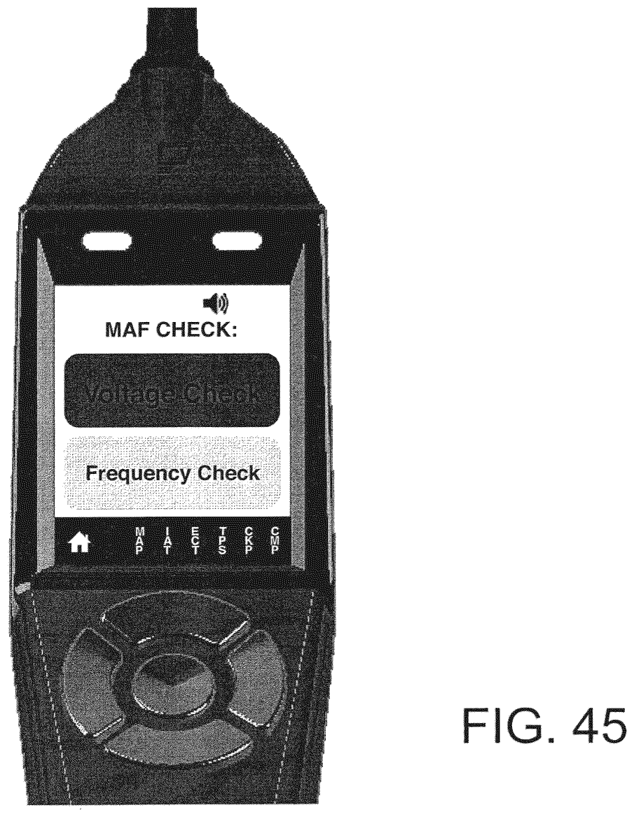

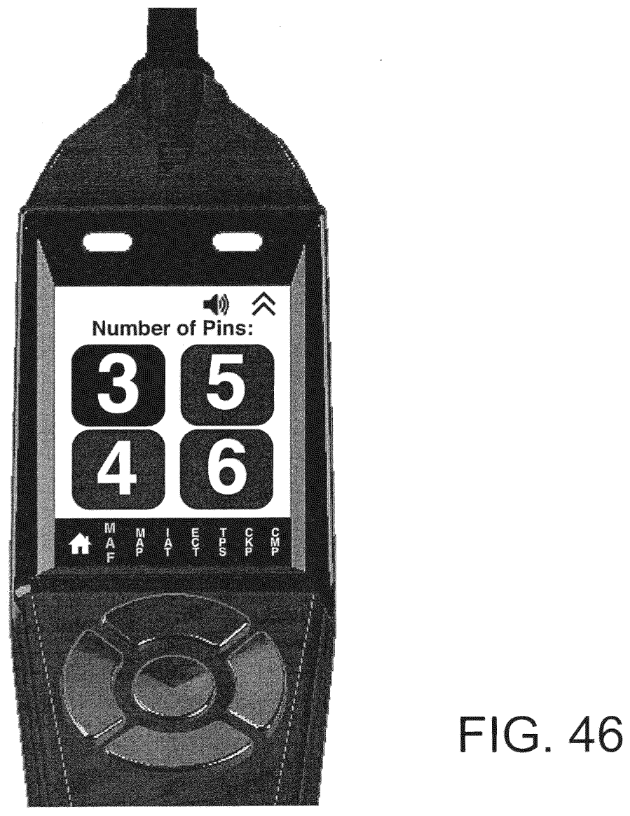

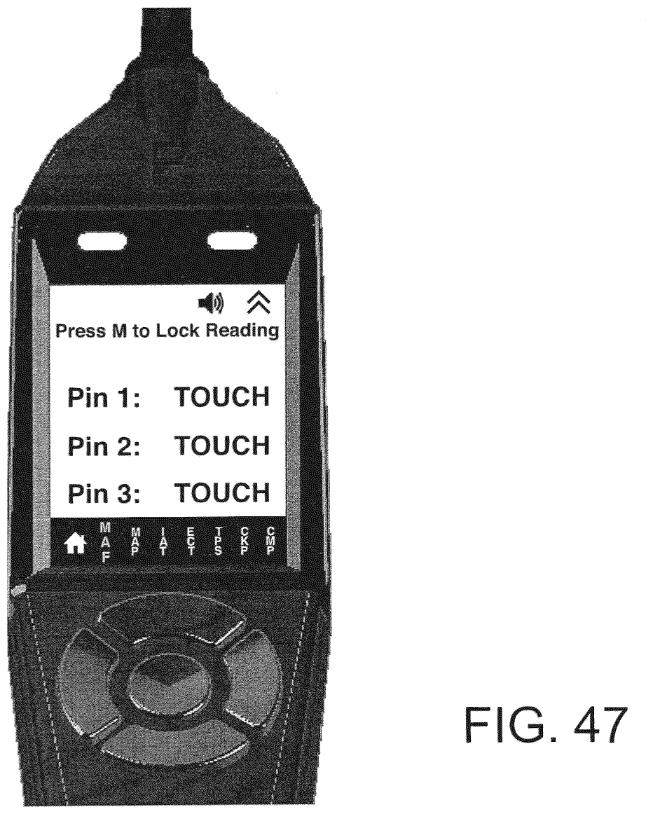

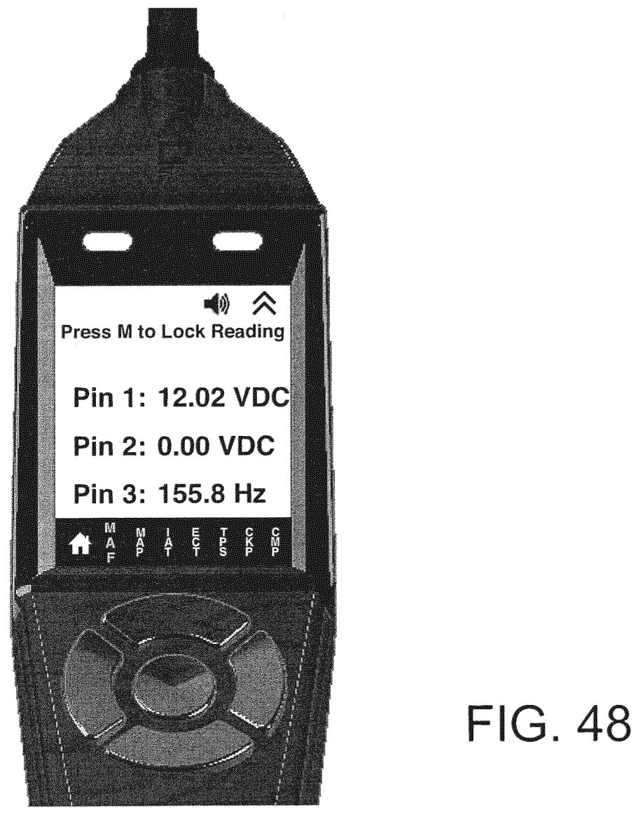

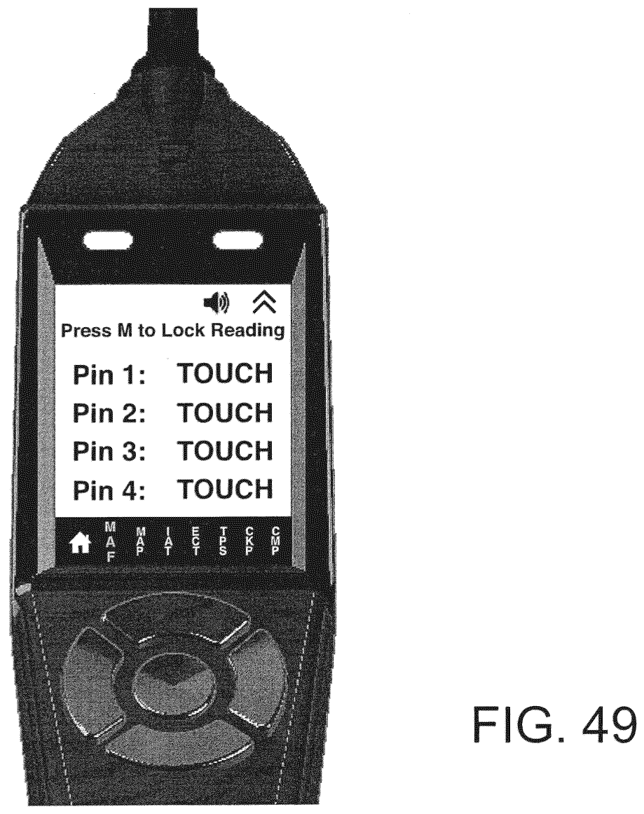

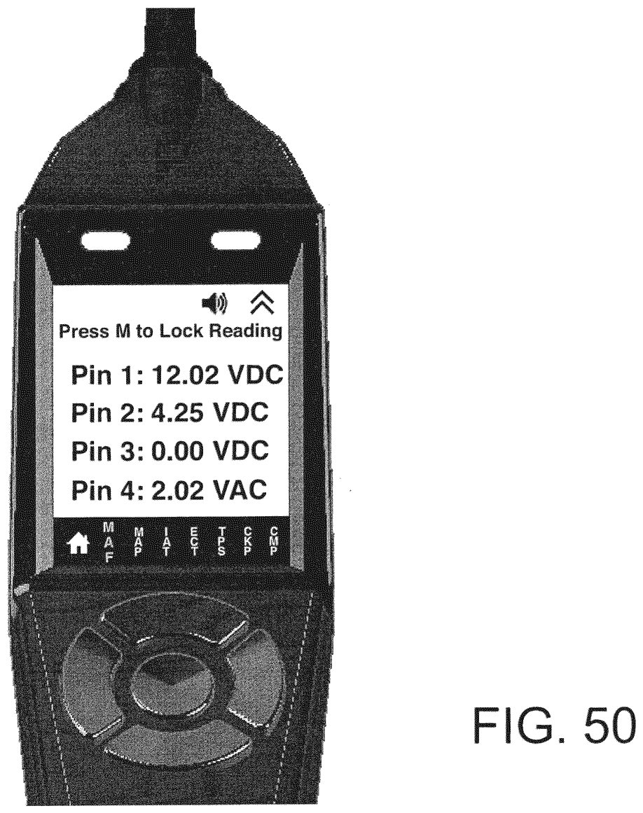

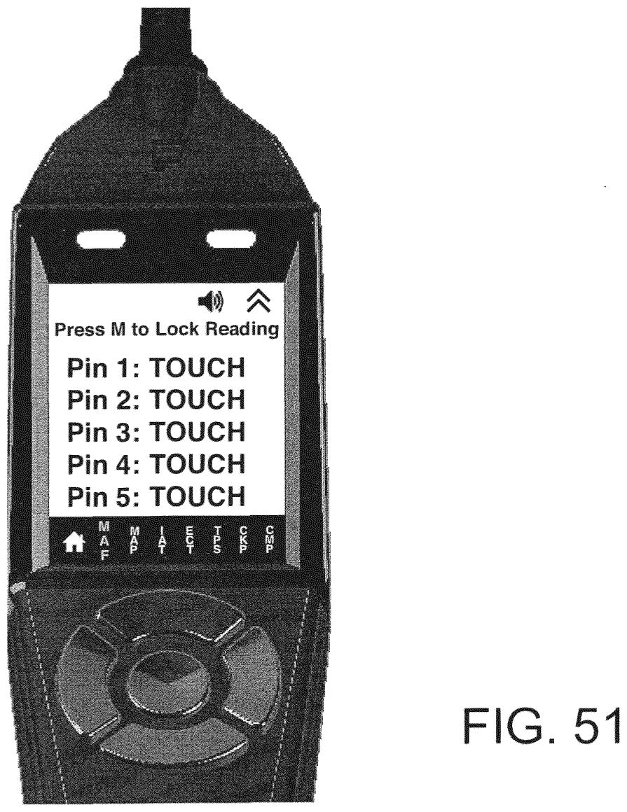

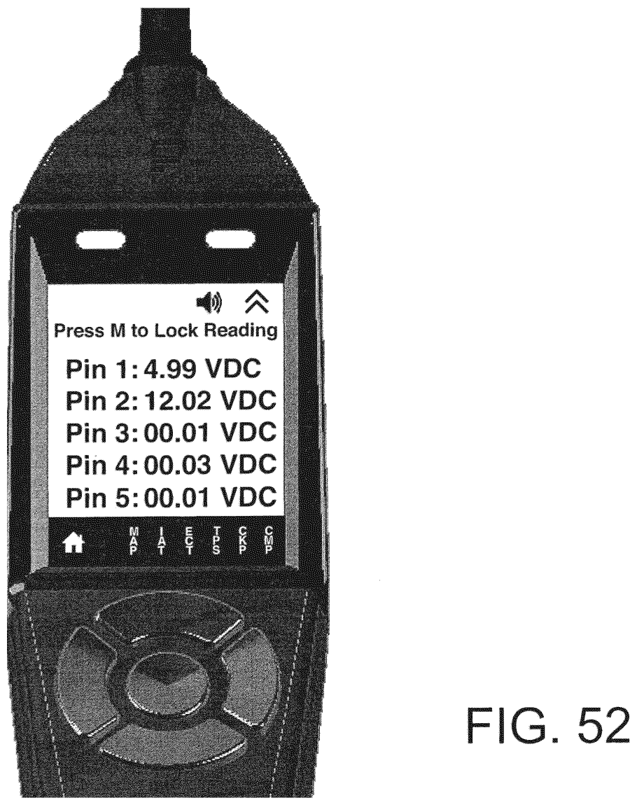

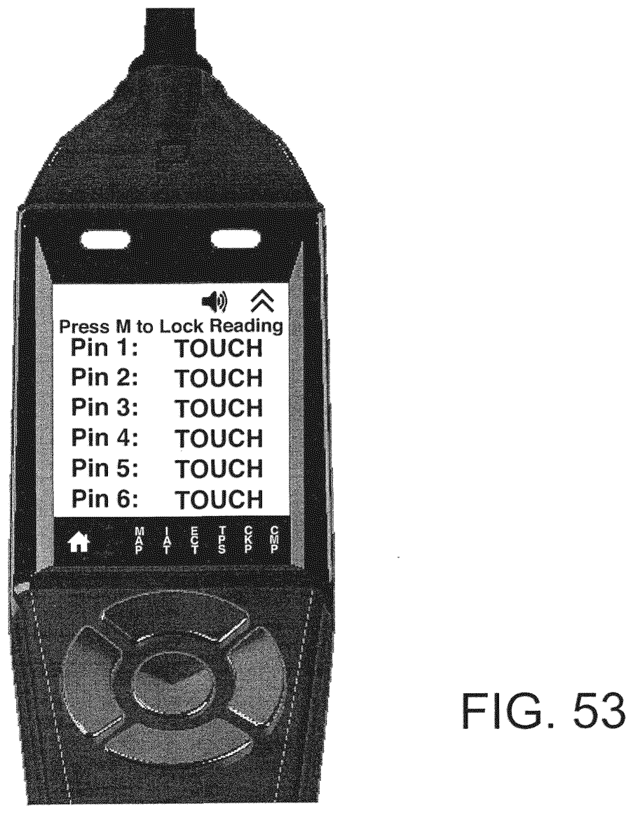

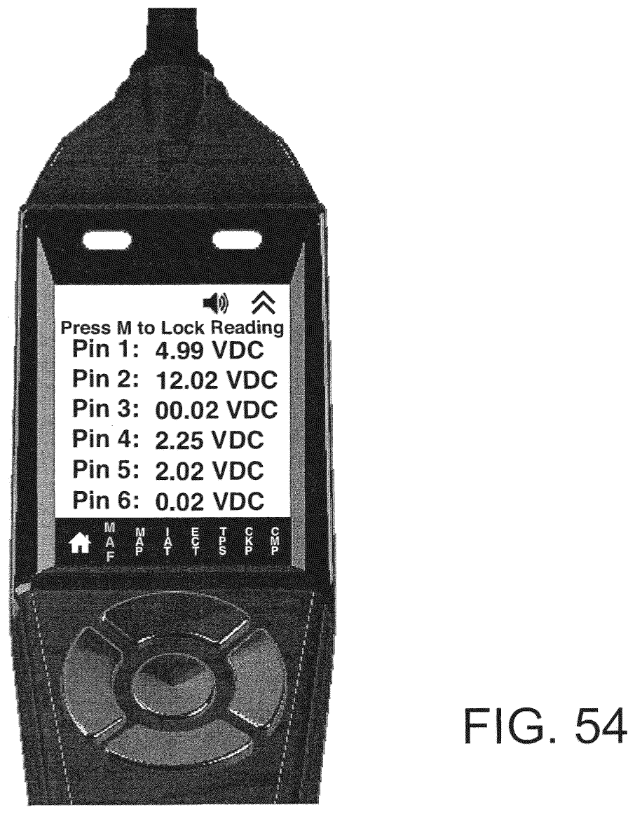

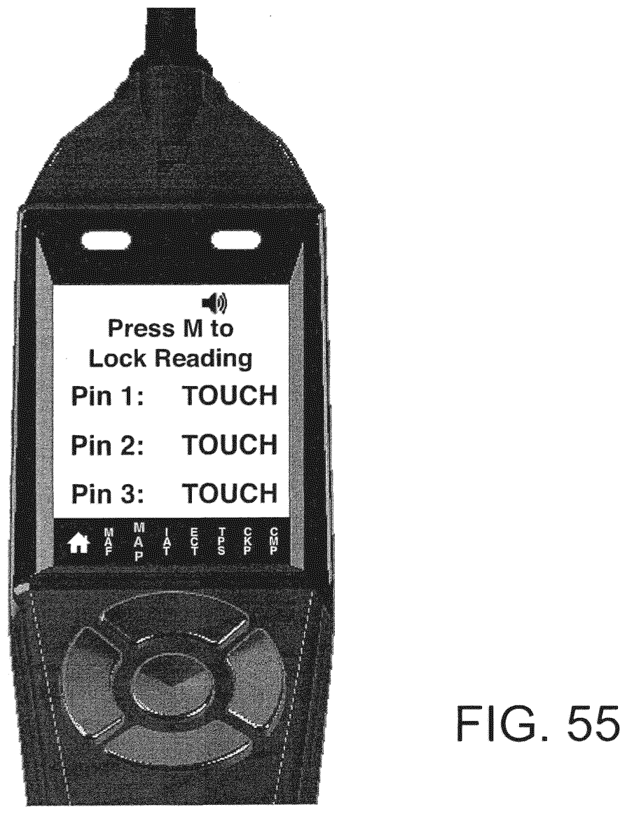

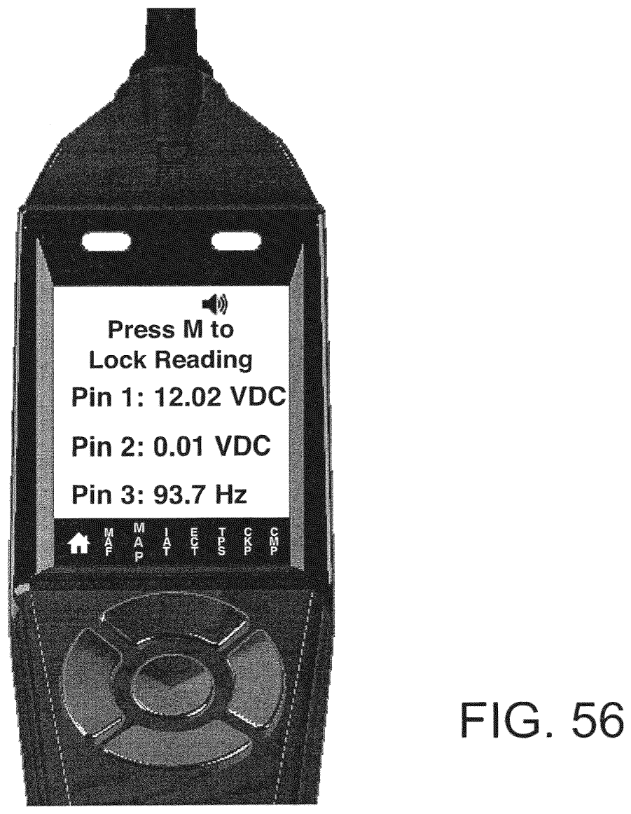

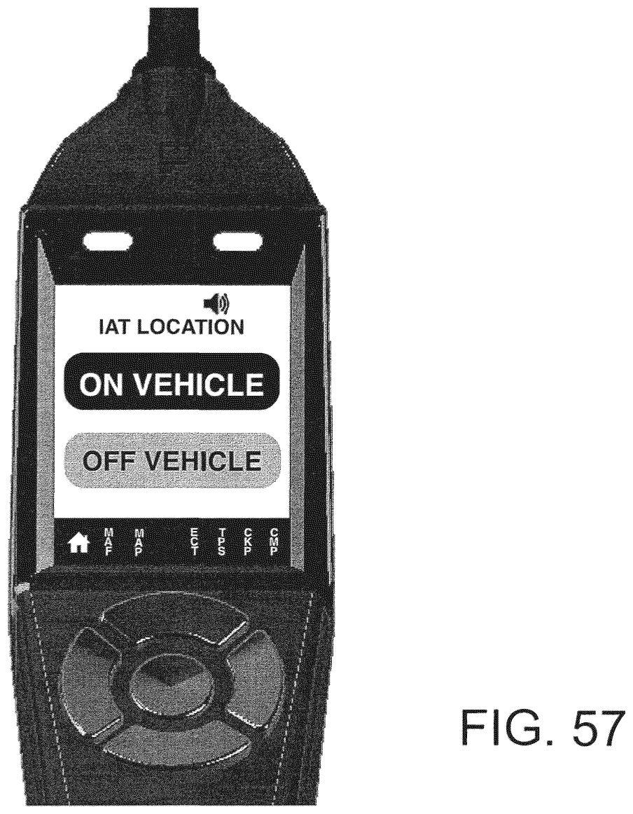

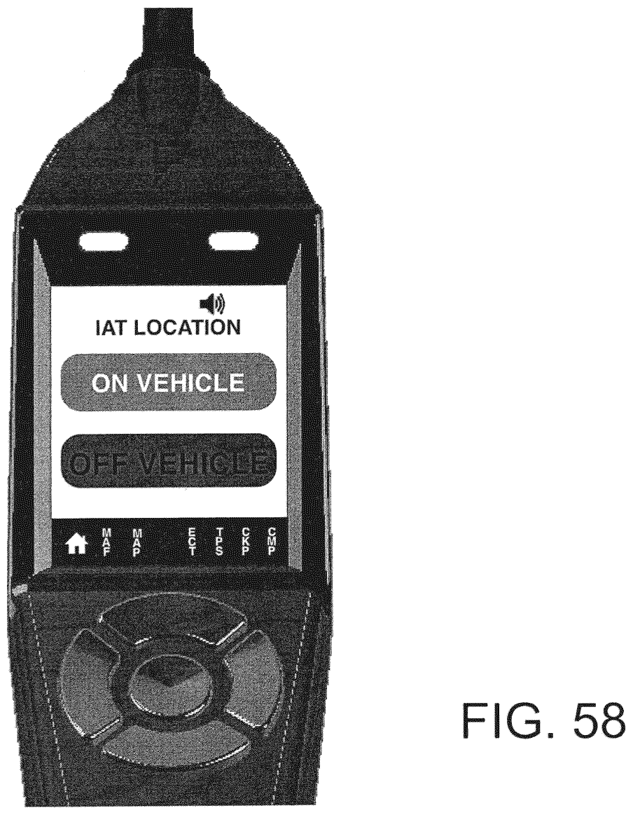

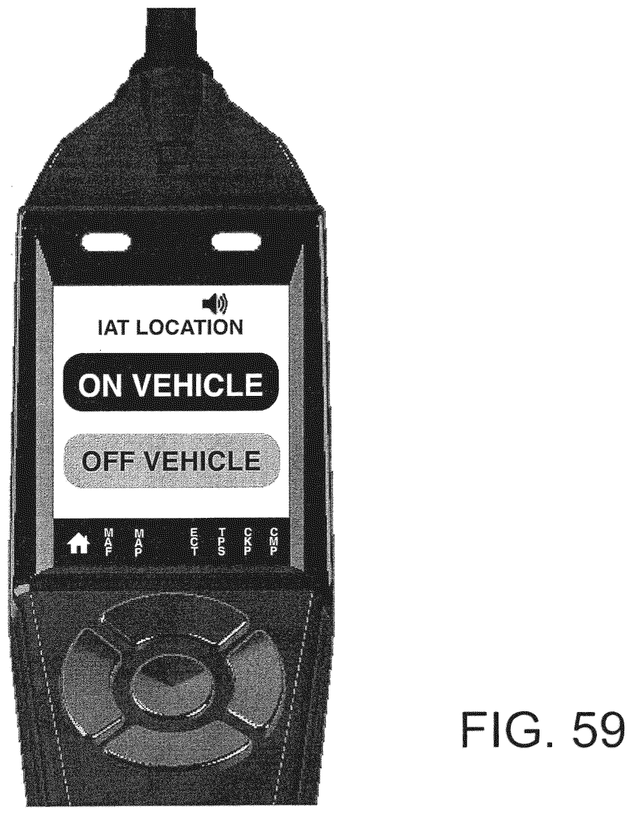

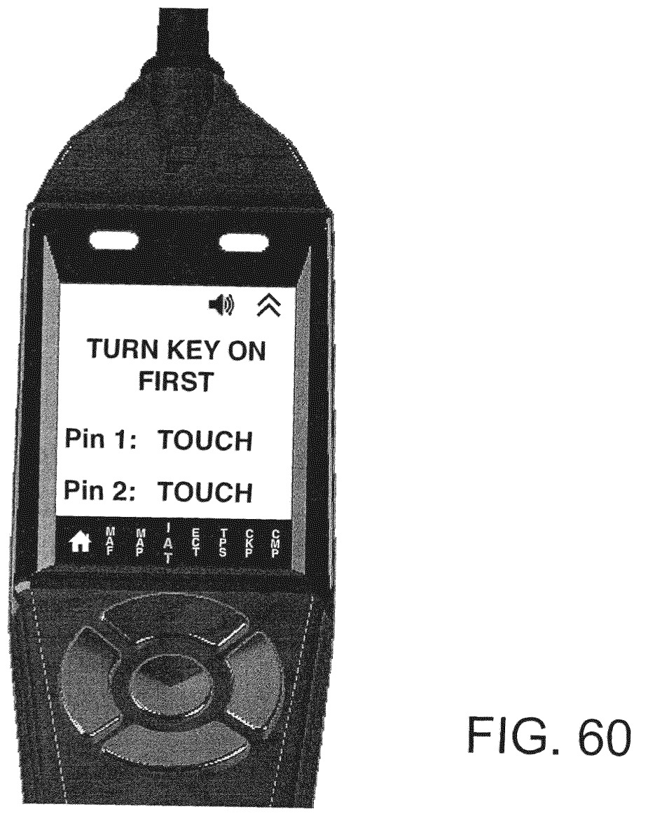

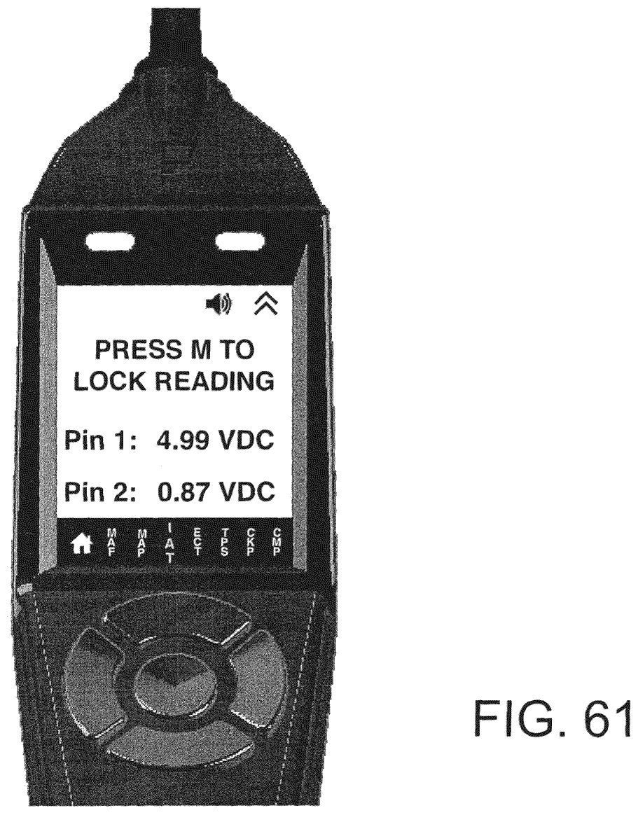

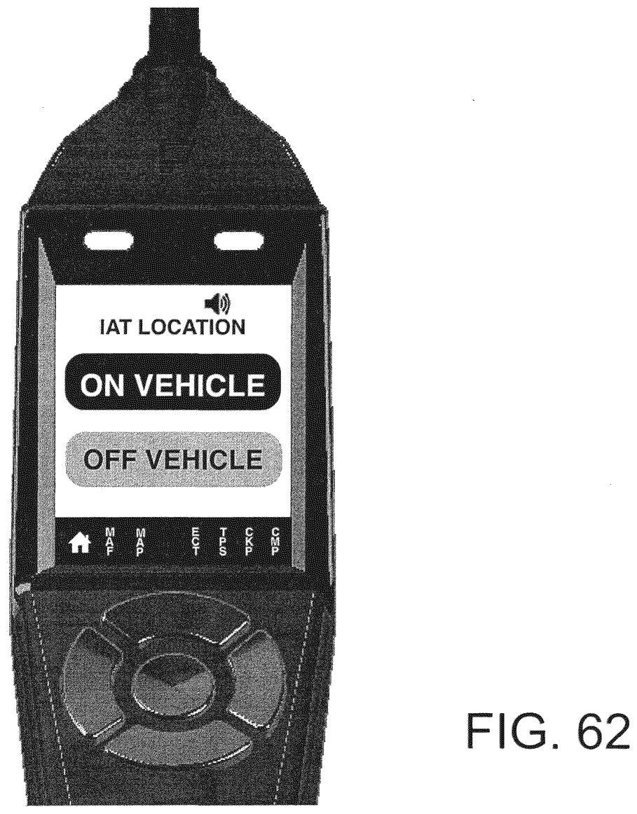

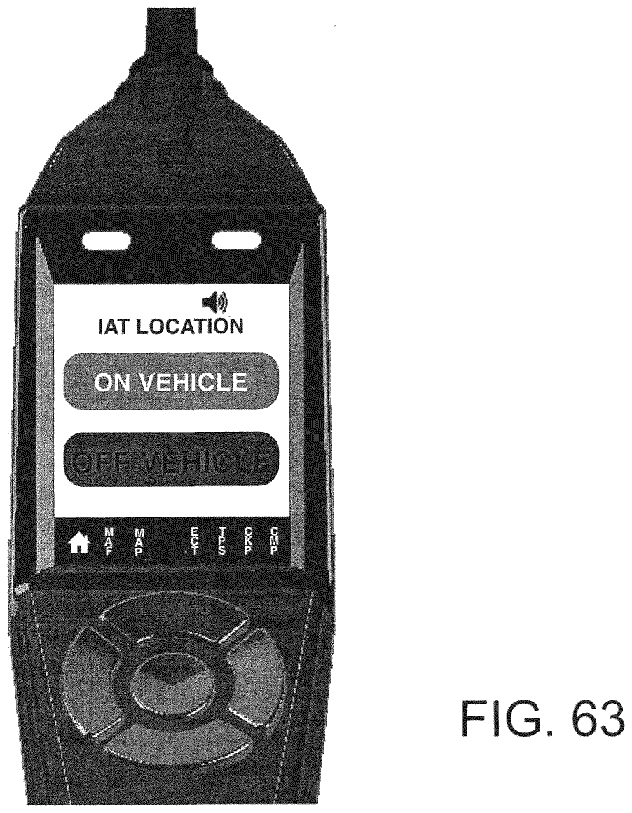

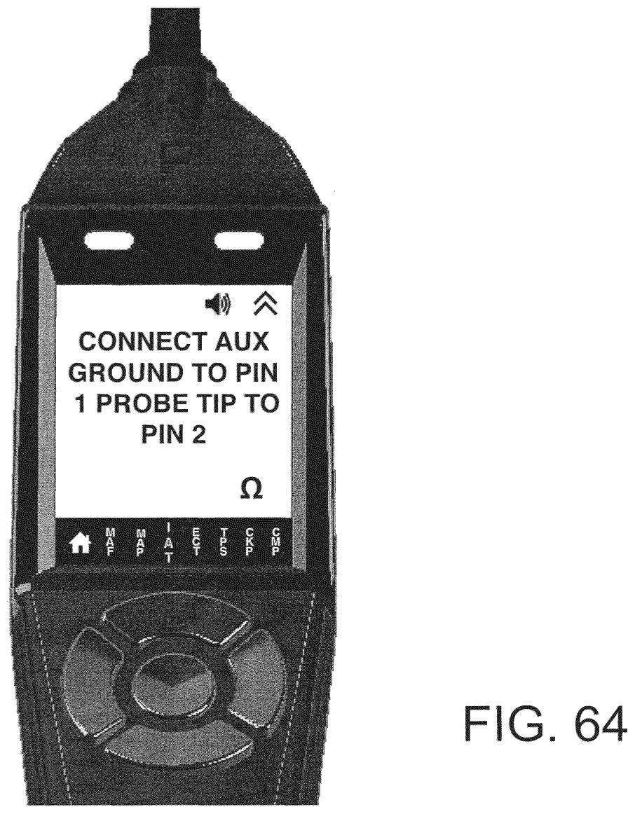

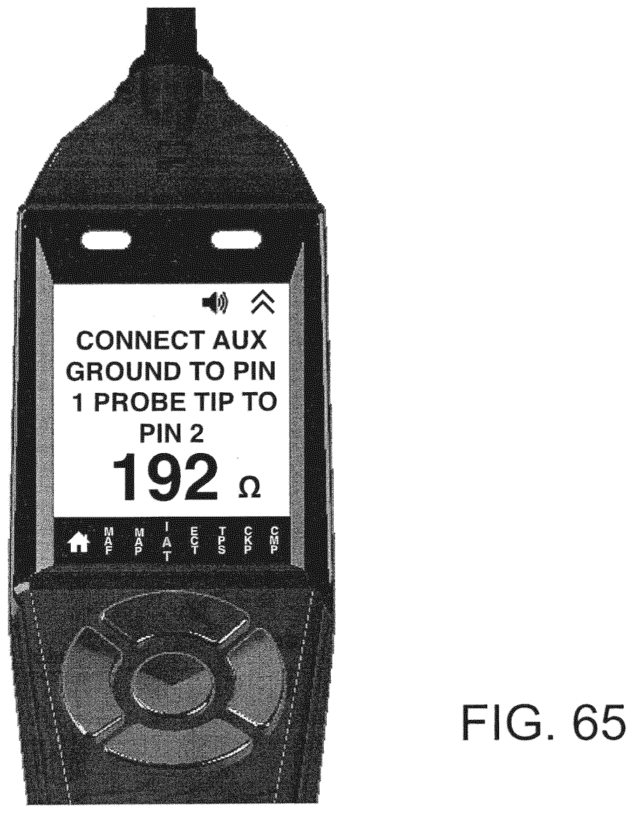

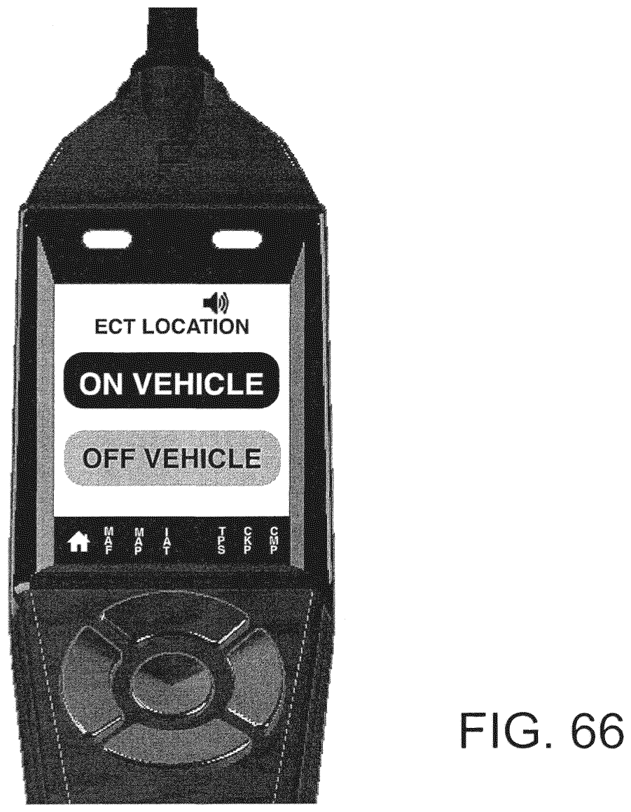

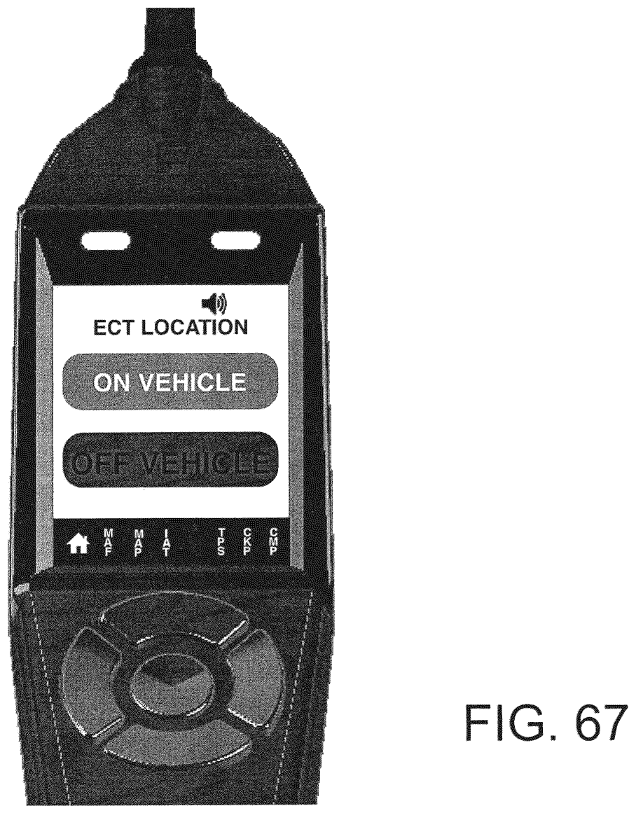

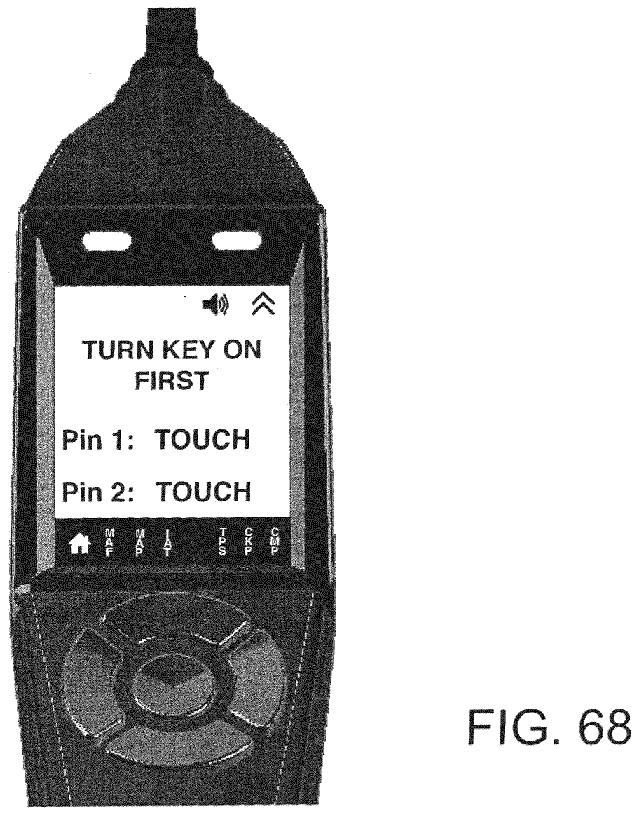

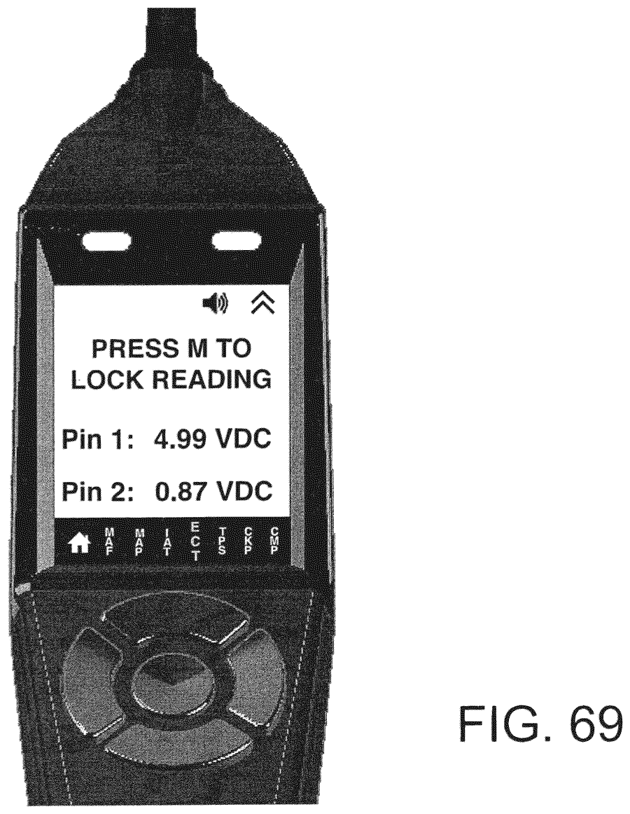

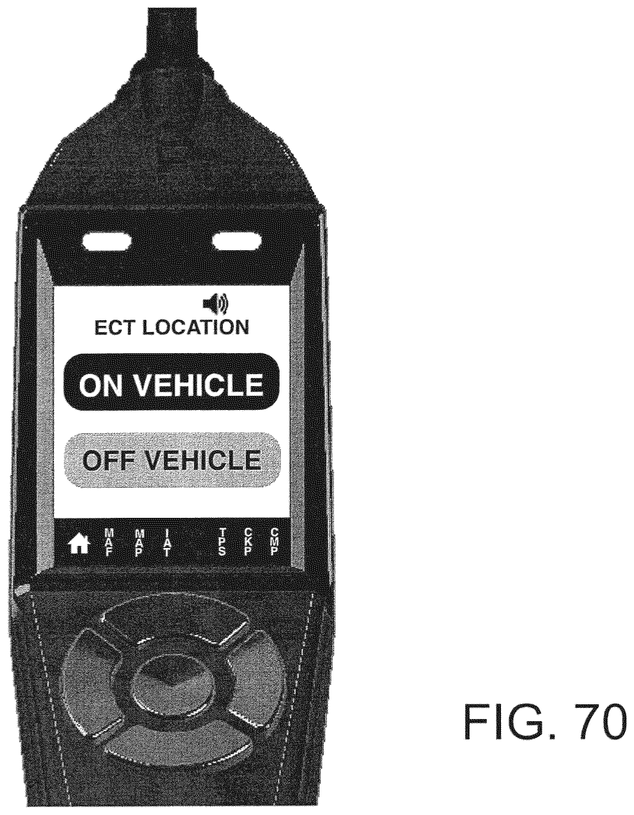

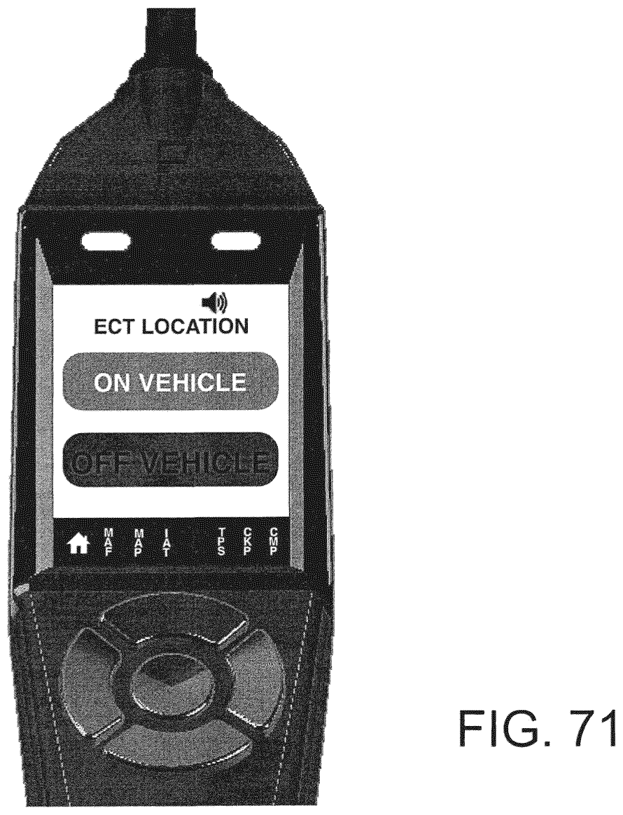

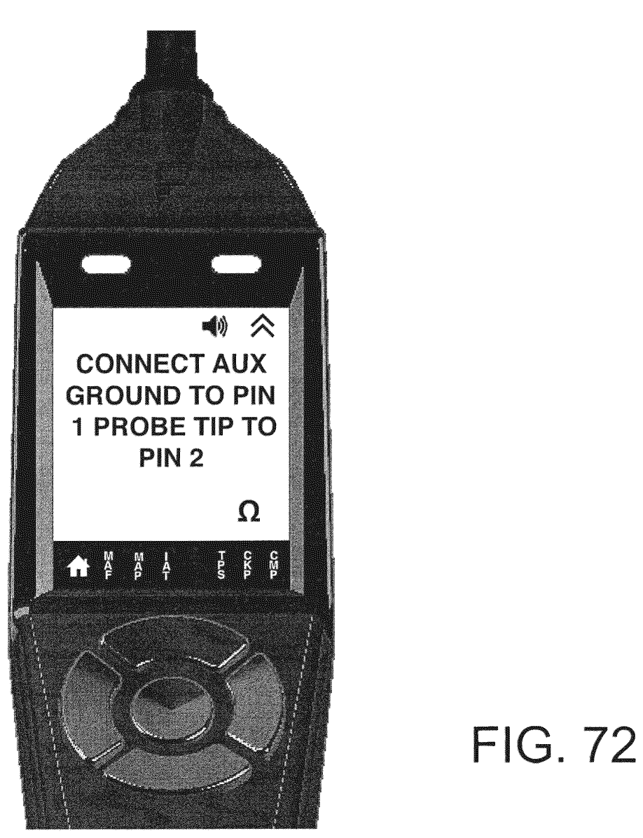

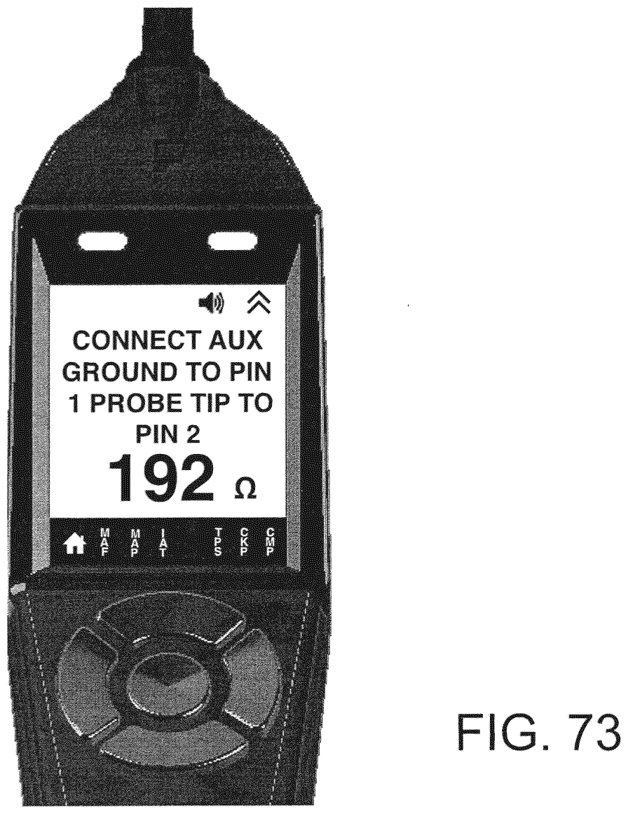

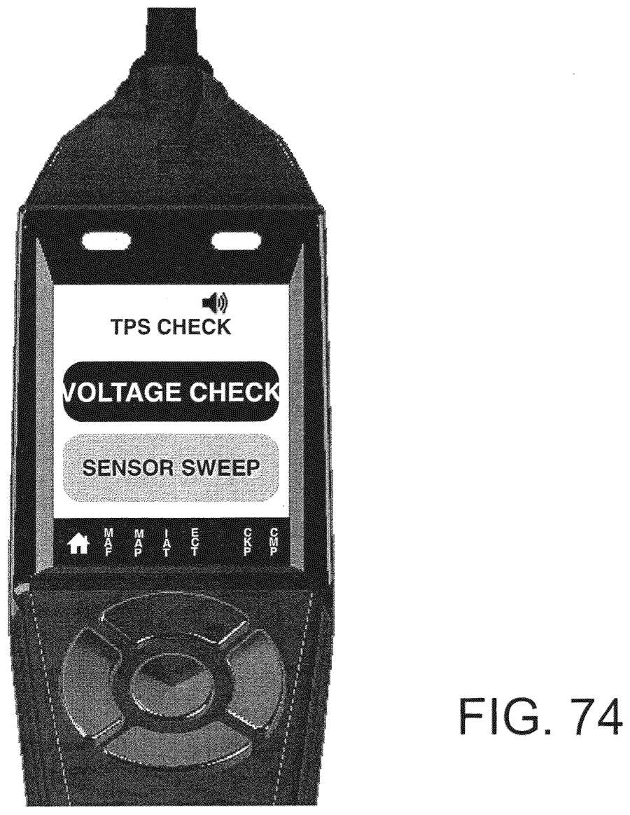

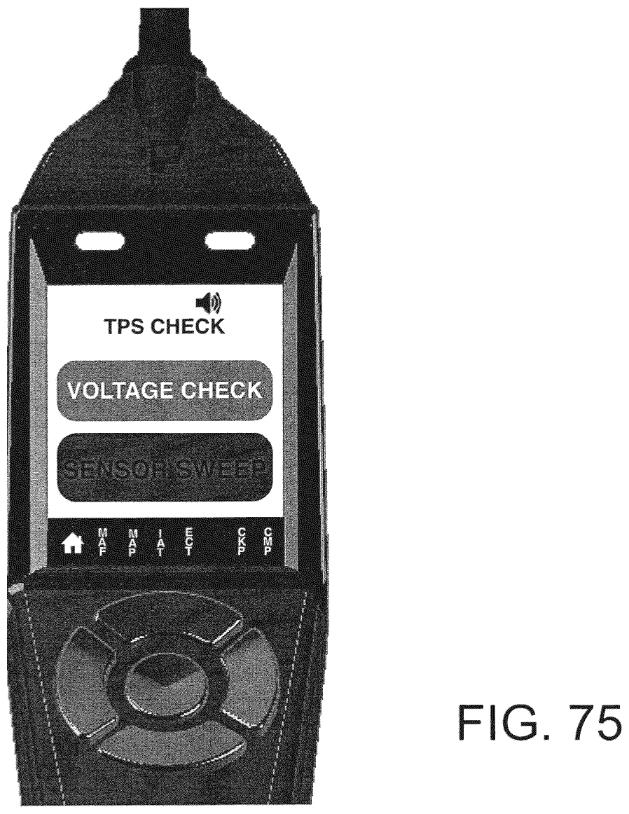

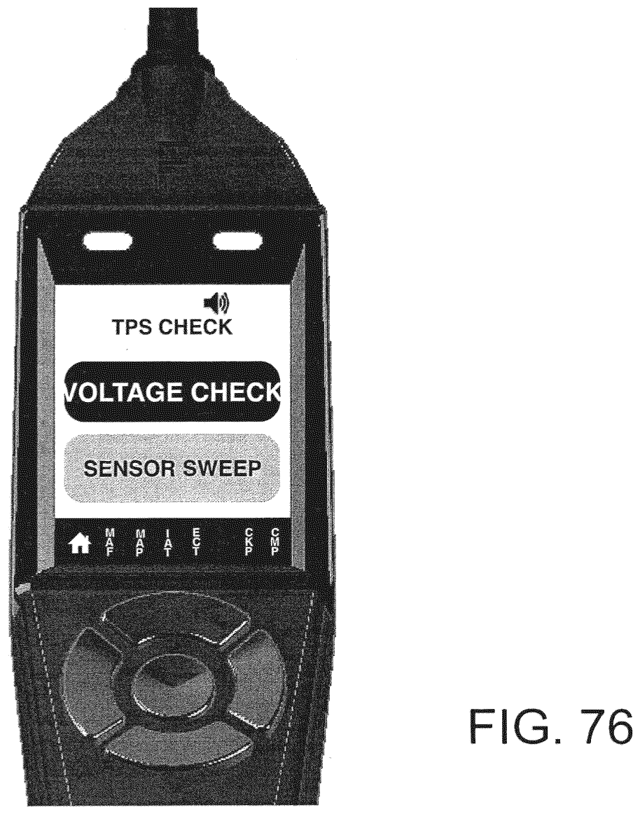

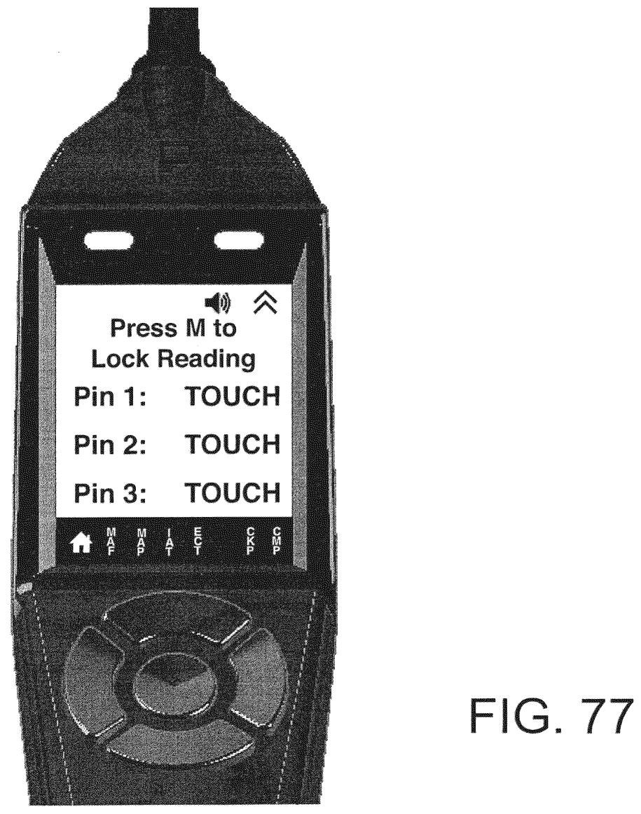

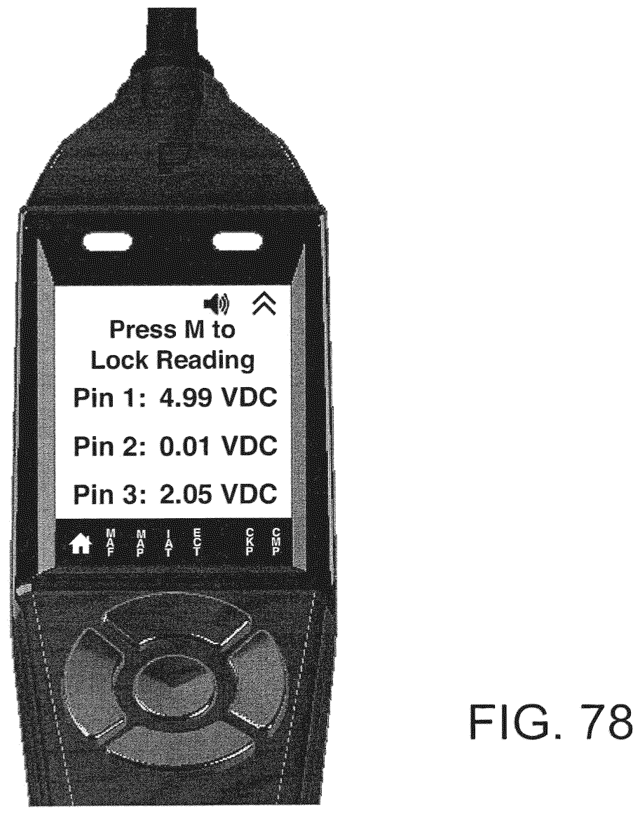

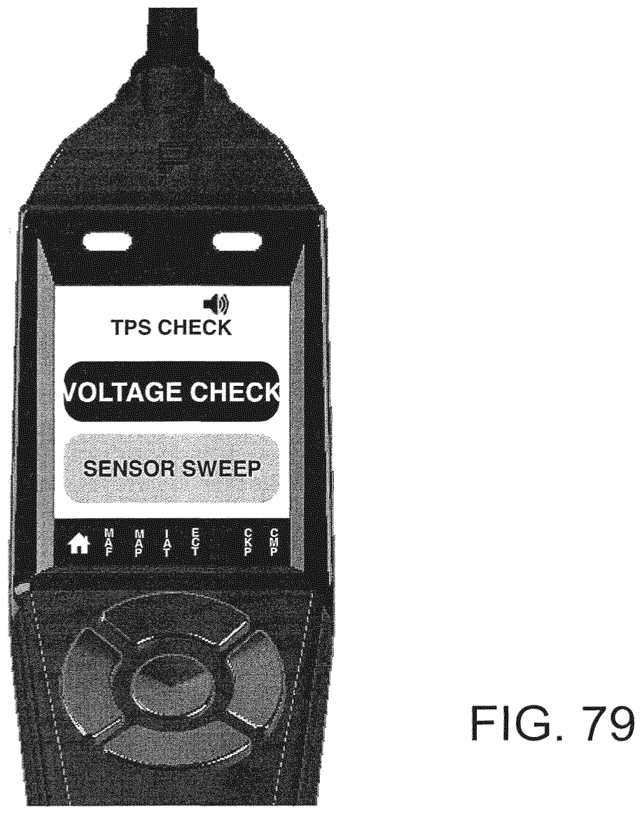

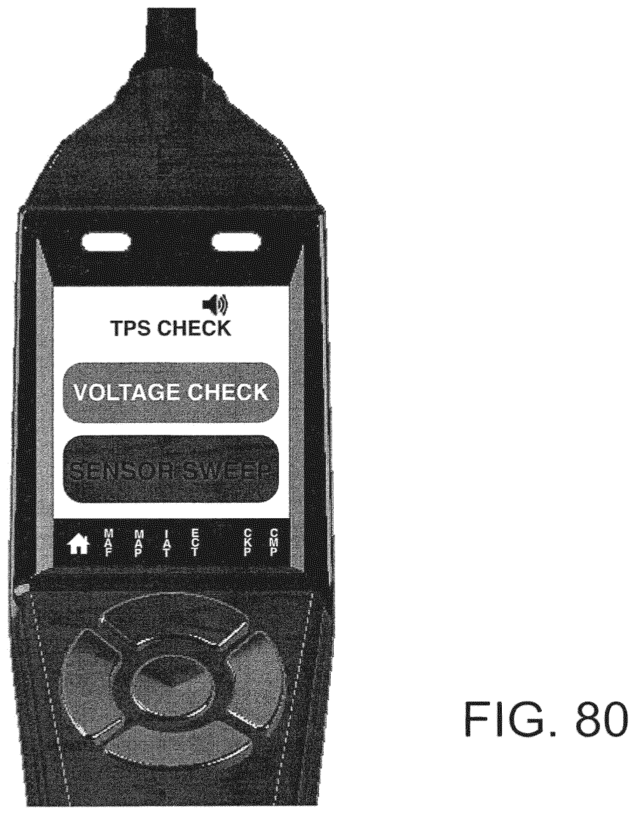

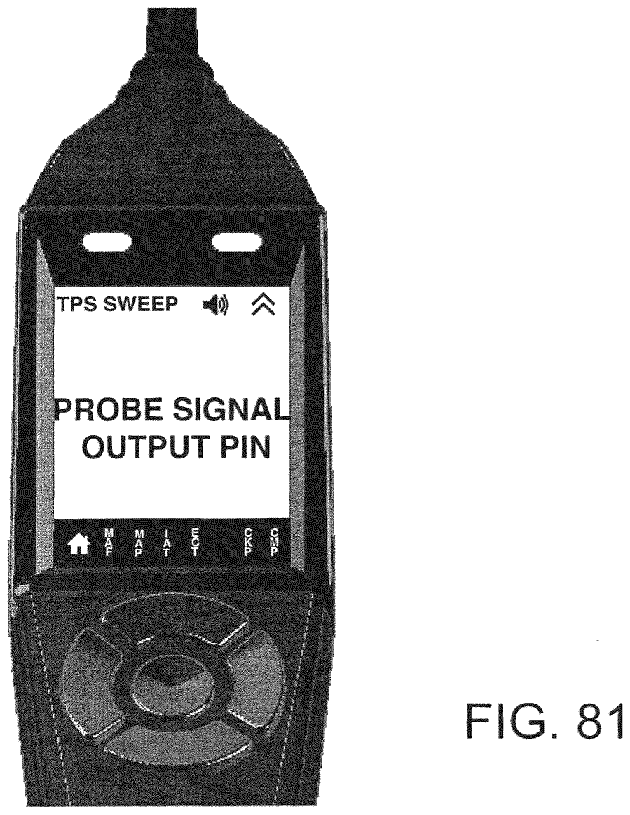

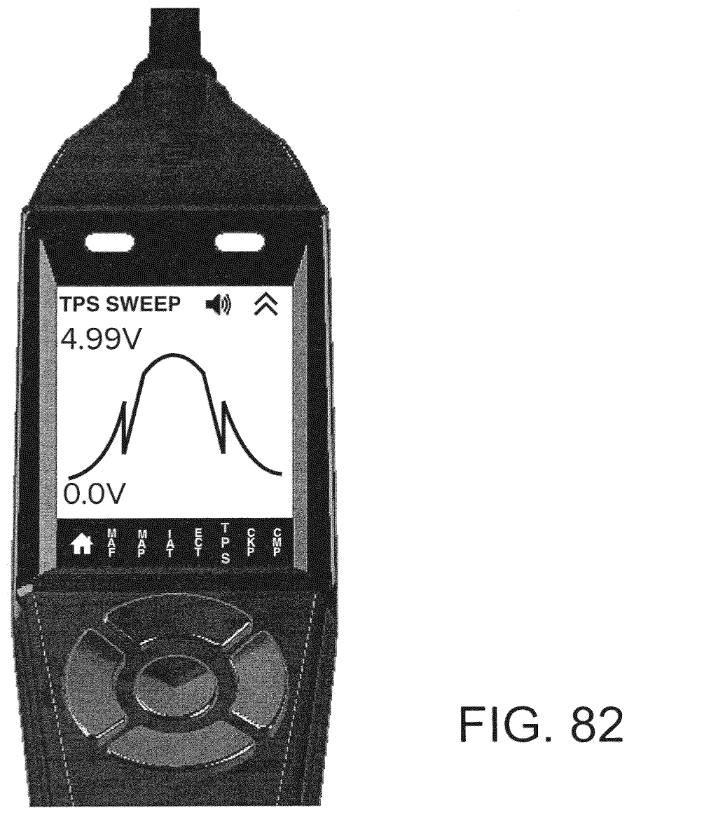

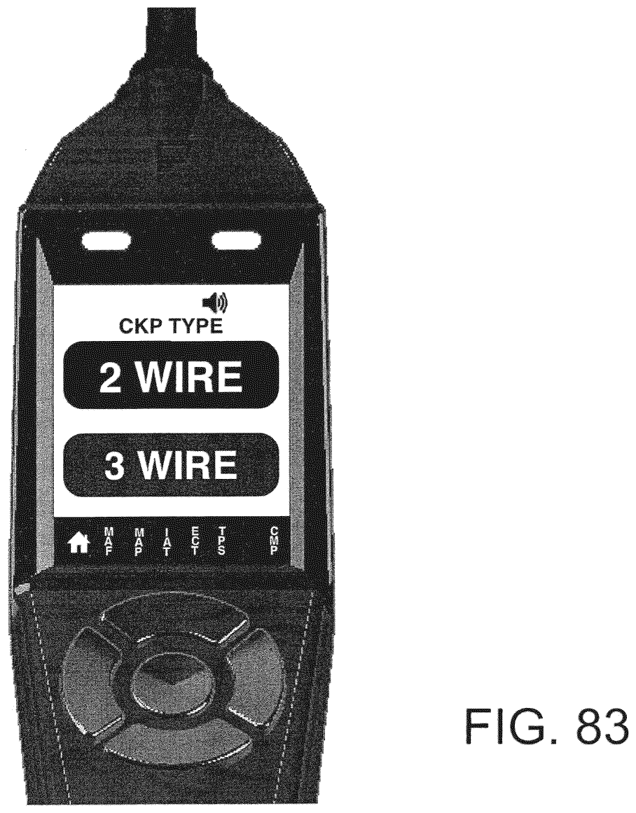

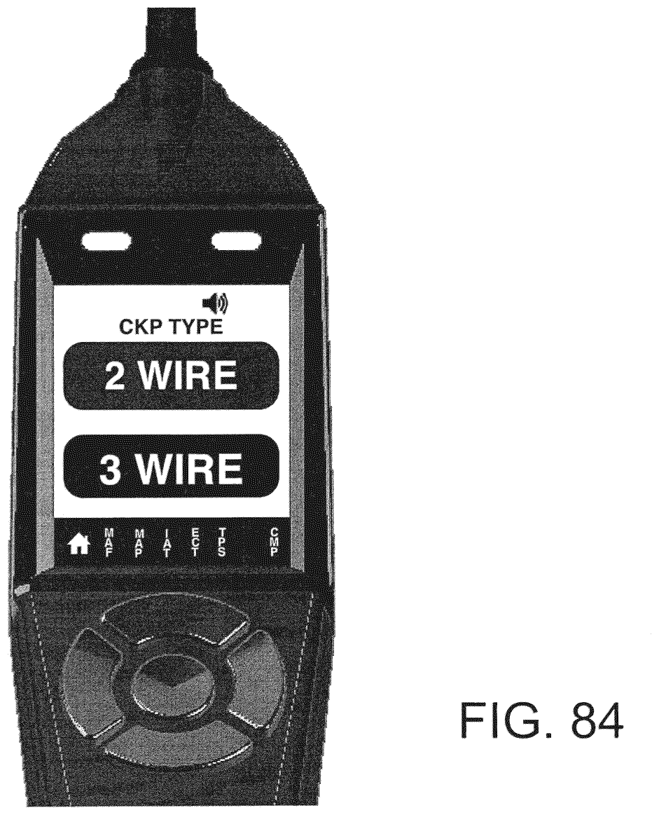

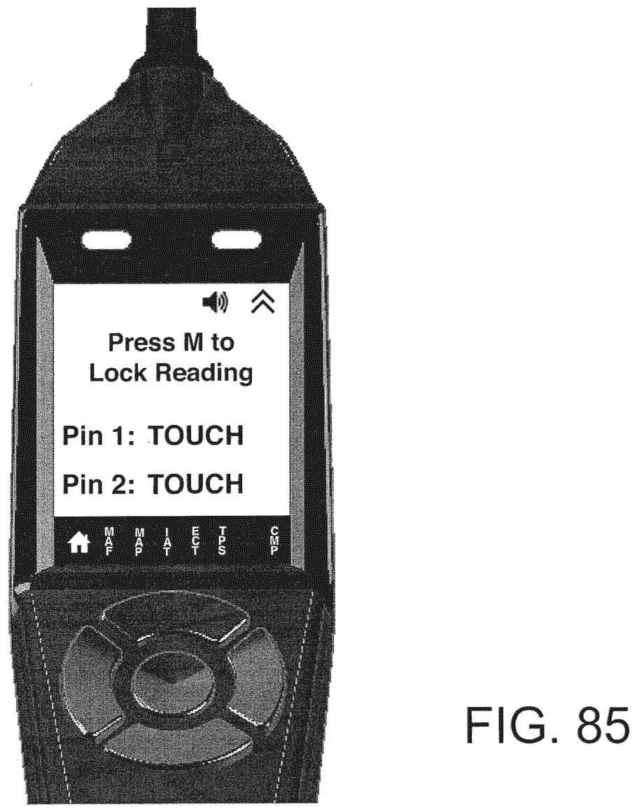

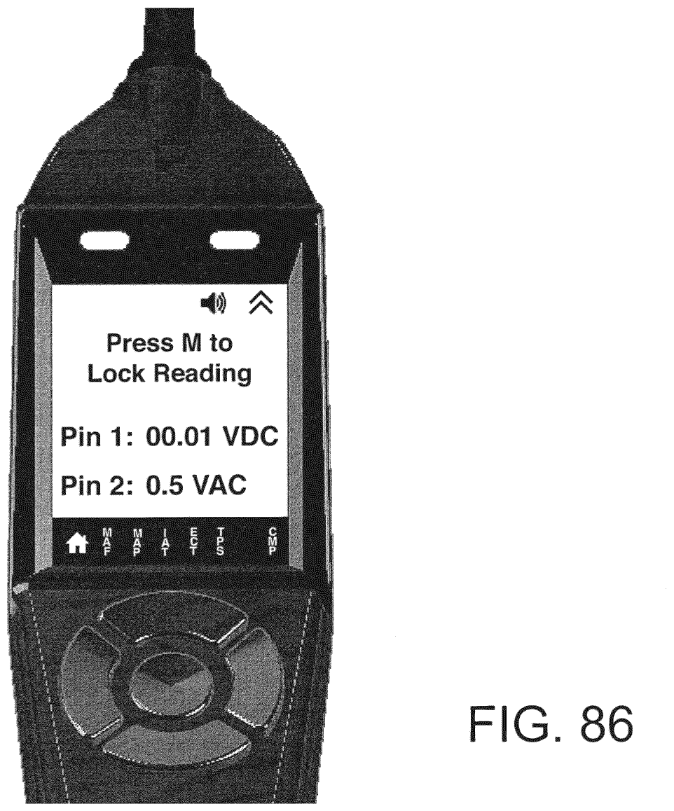

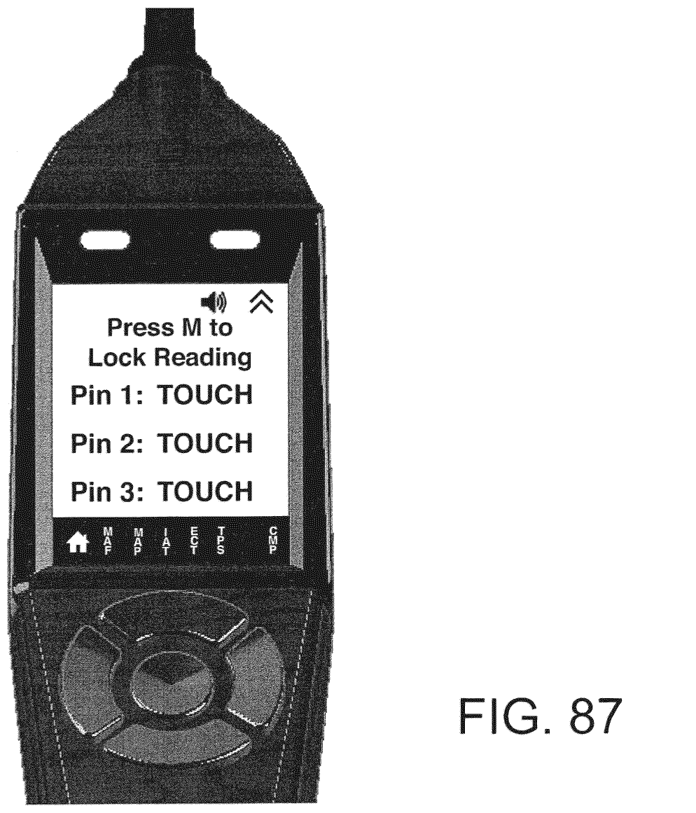

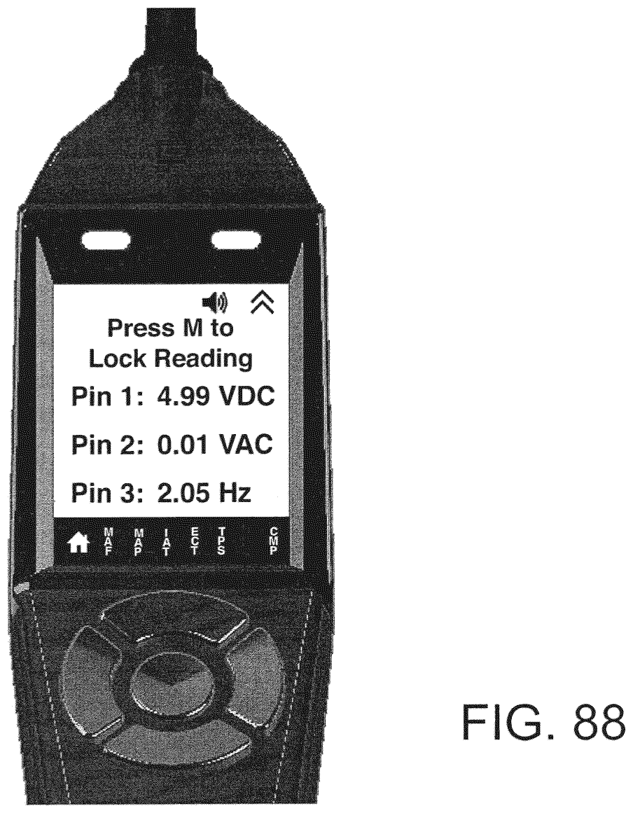

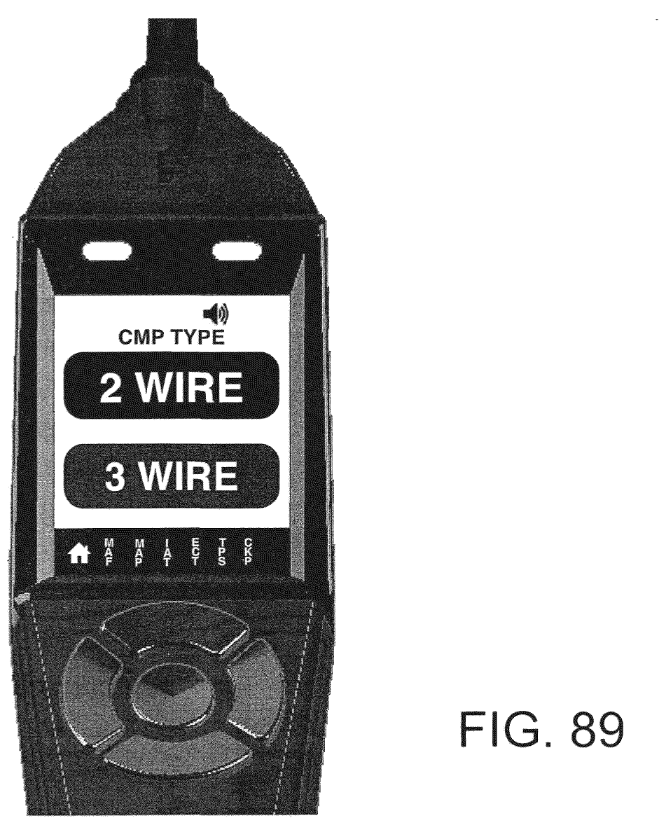

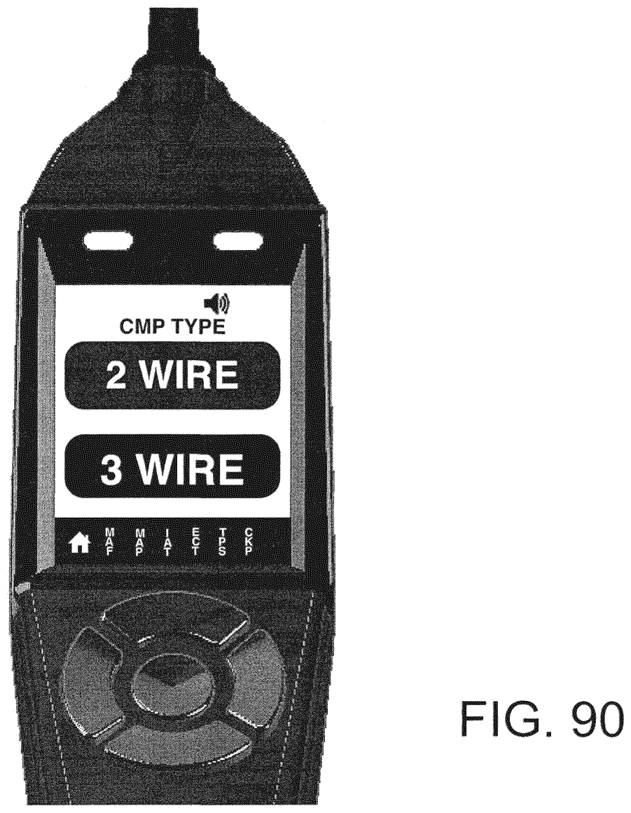

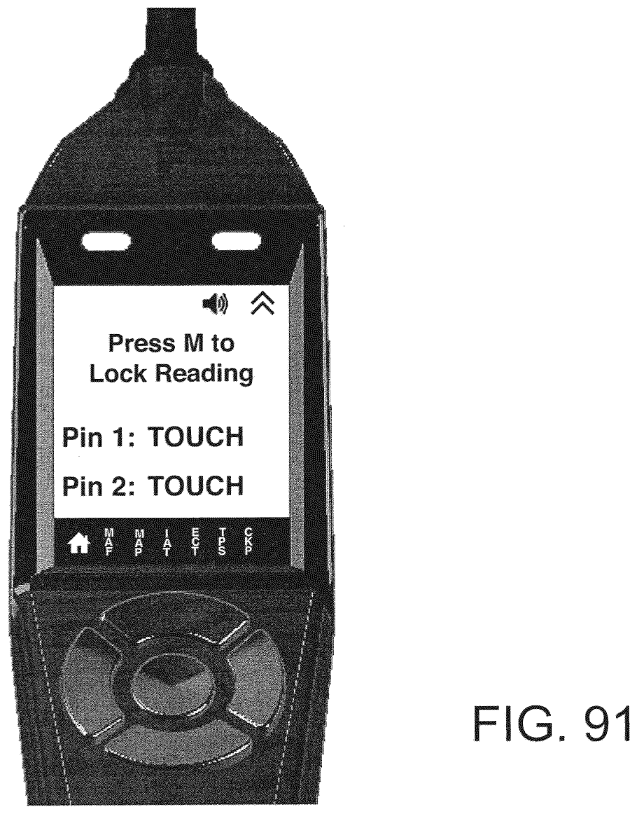

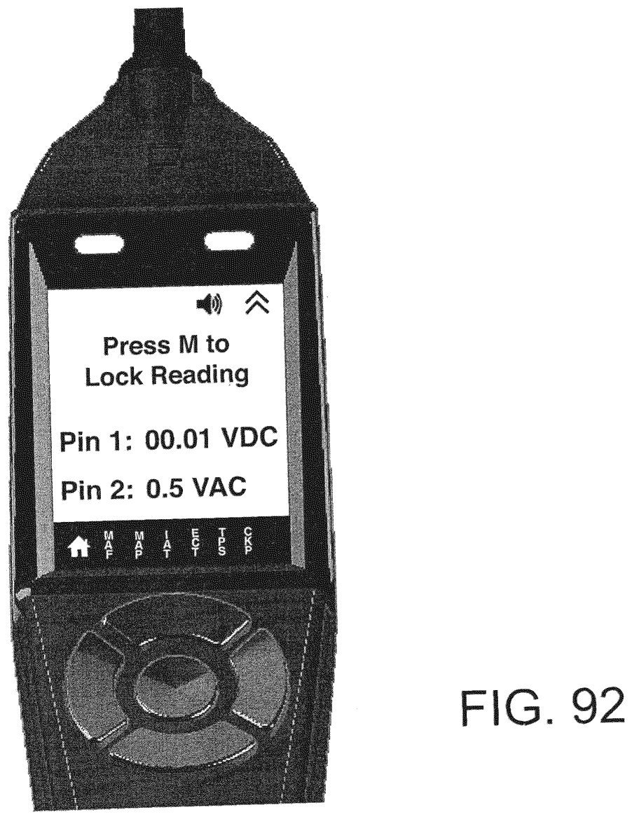

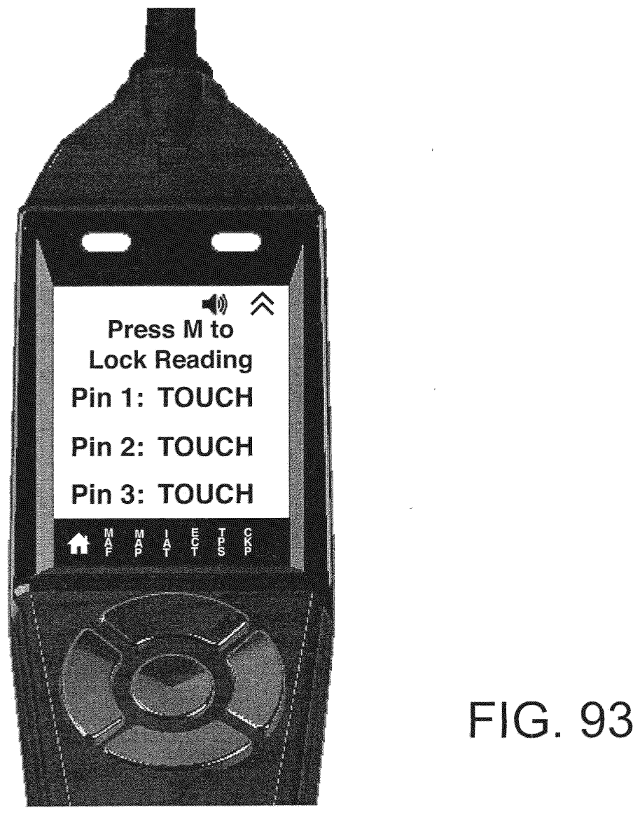

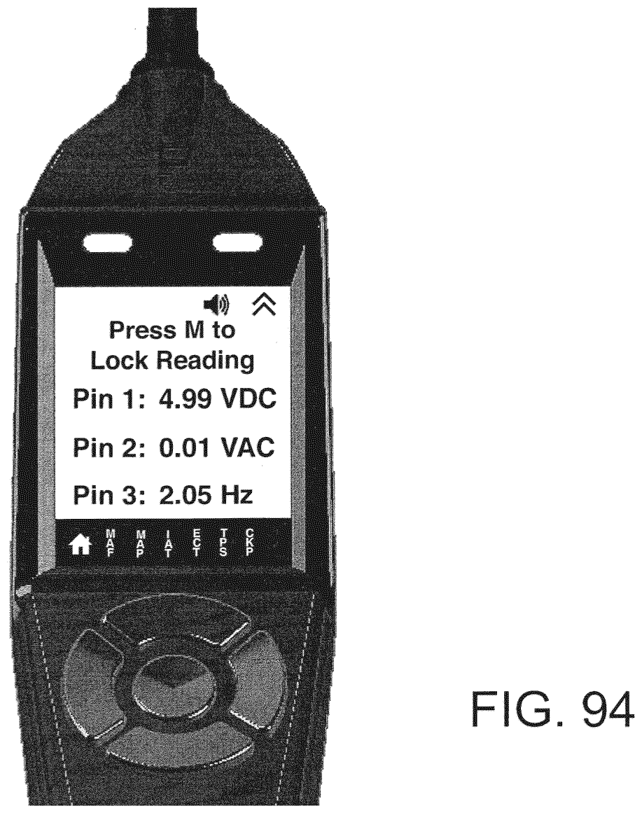

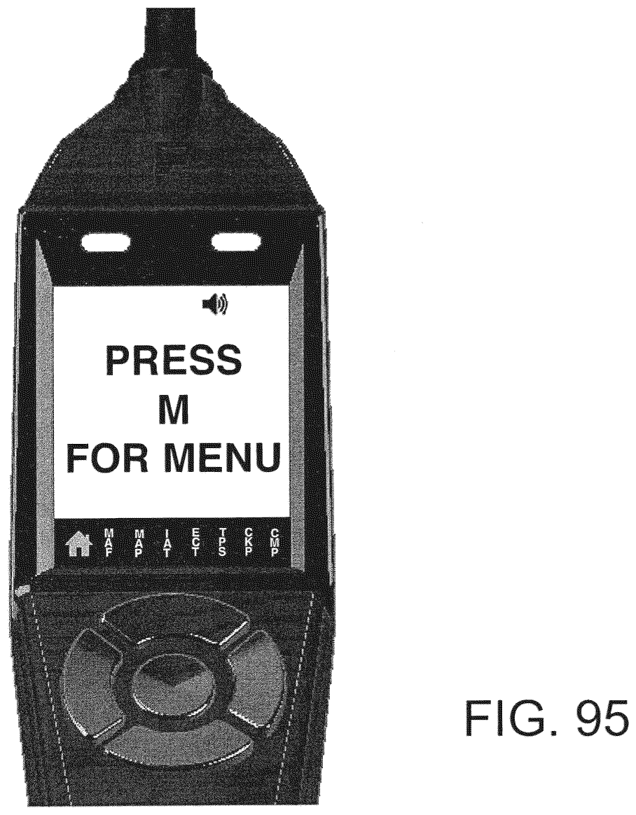

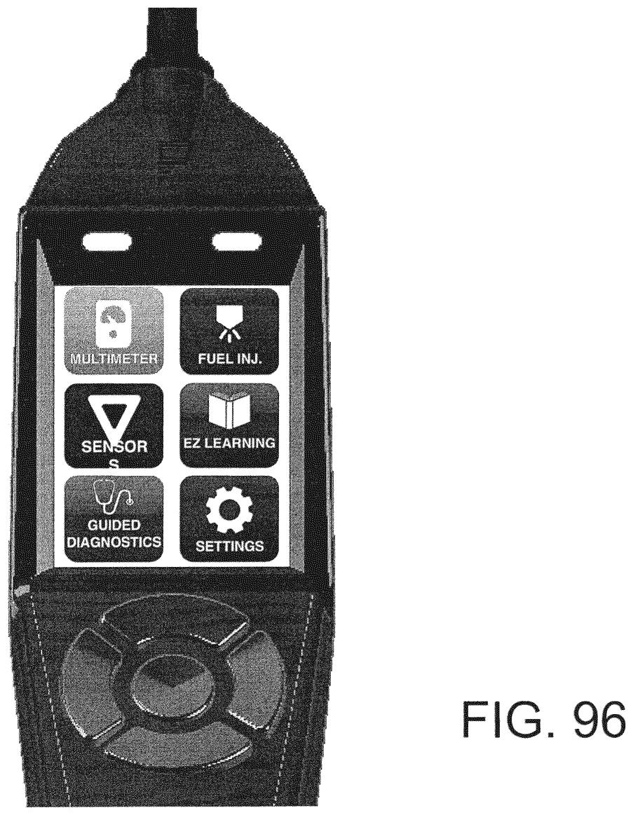

FIGS. 42-97 illustrate an exemplary embodiment of a sensor diagnosis functionality of the intelligent diagnostic probe 100 of FIGS. 1-5 that is accessible by selecting a Sensors icon shown in FIG. 42. The sensor diagnosis functionality is configured, in some embodiments, to facilitate diagnosing various sensors comprising vehicle fuel injection systems. The sensor diagnosis functionality is configured, in some embodiments, to guide the practitioner through a series of sensor analysis steps, as well as provide troubleshooting based on measured values.

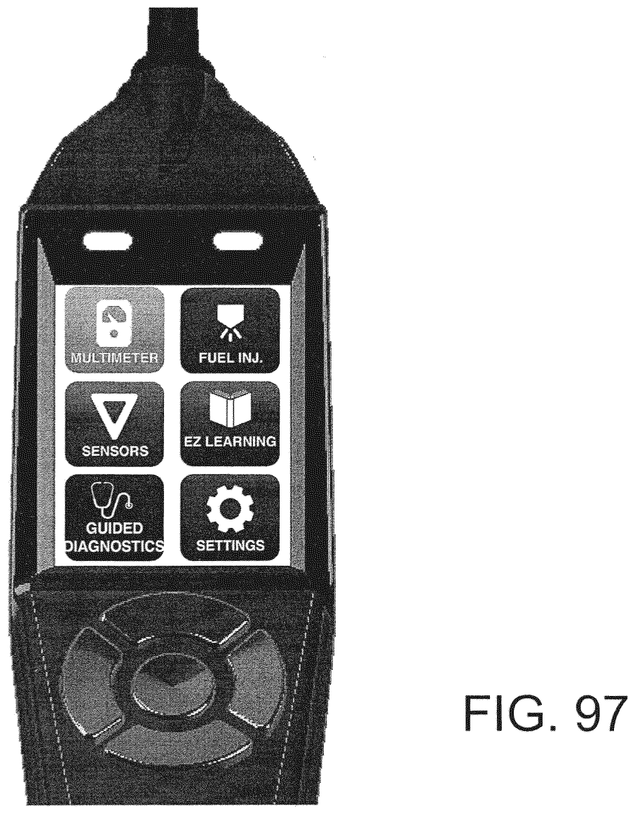

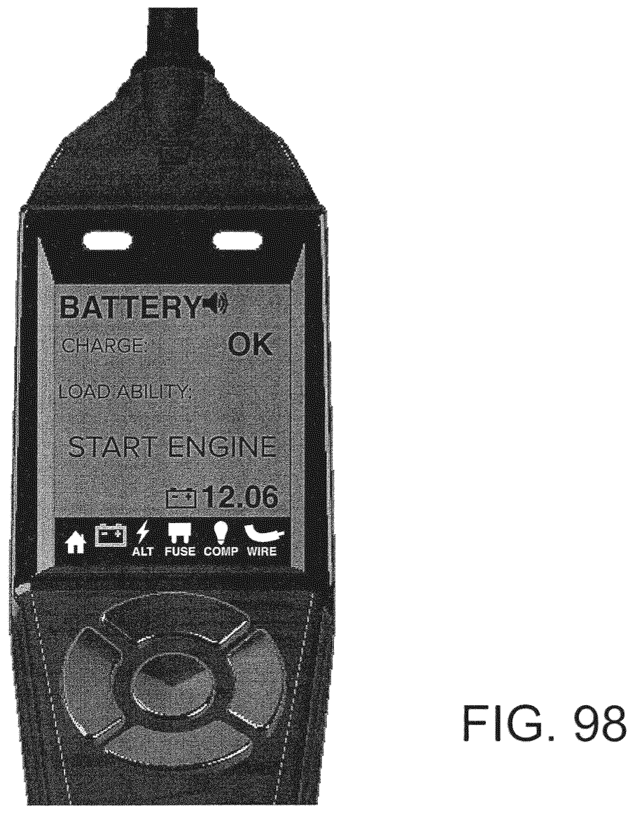

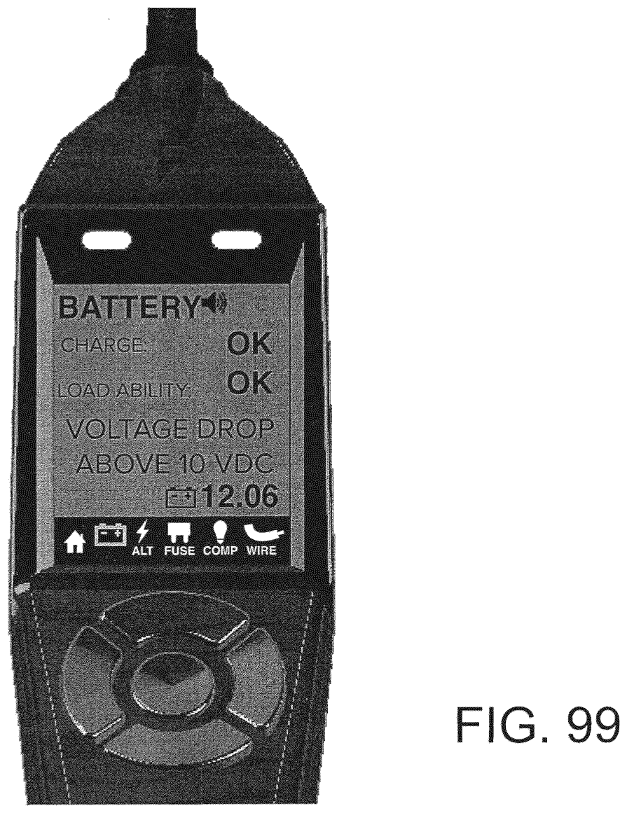

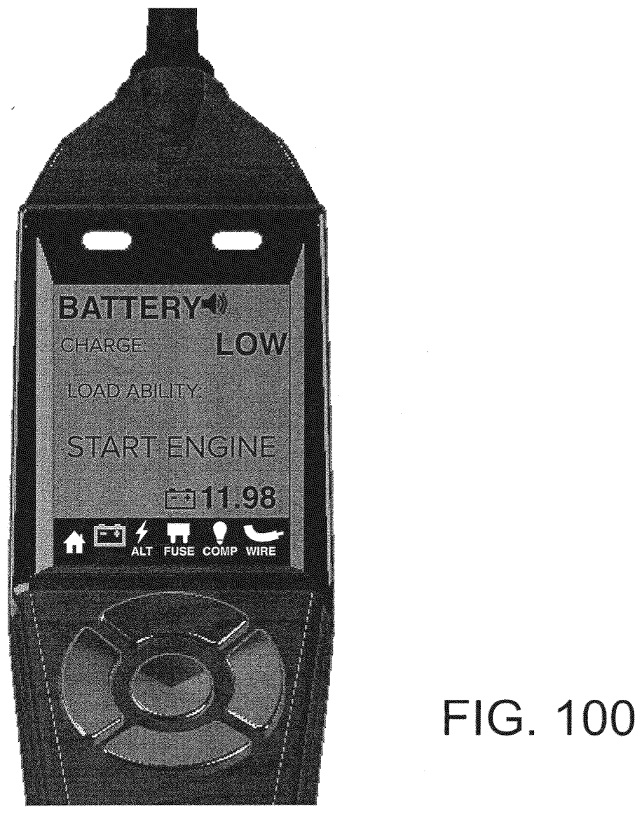

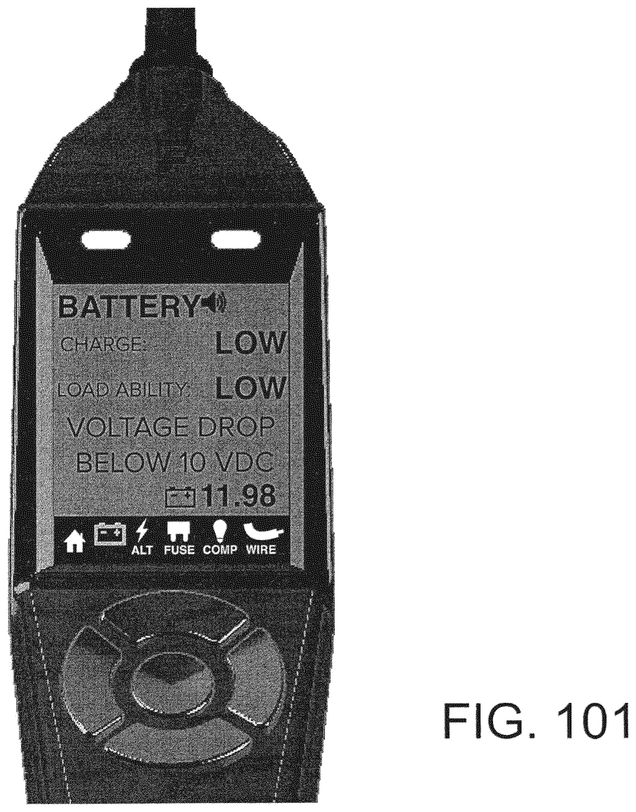

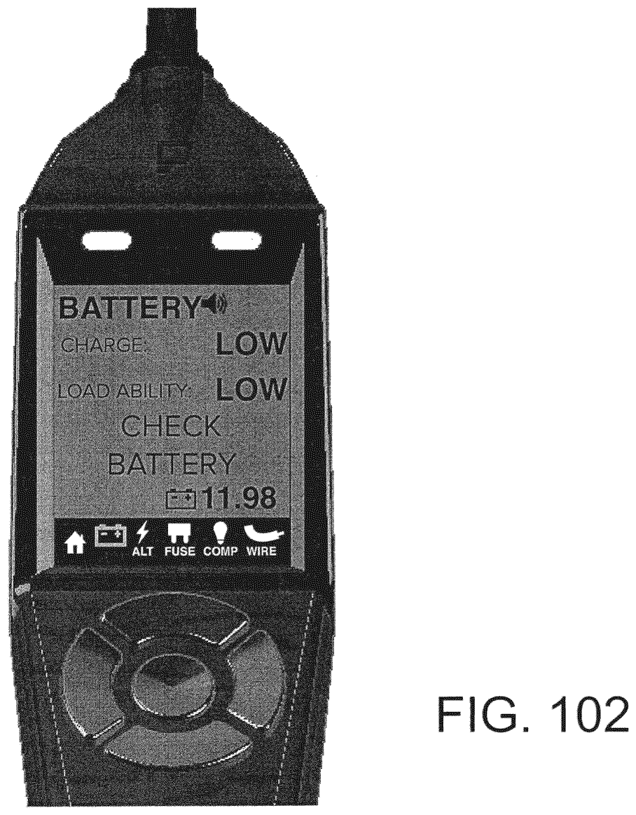

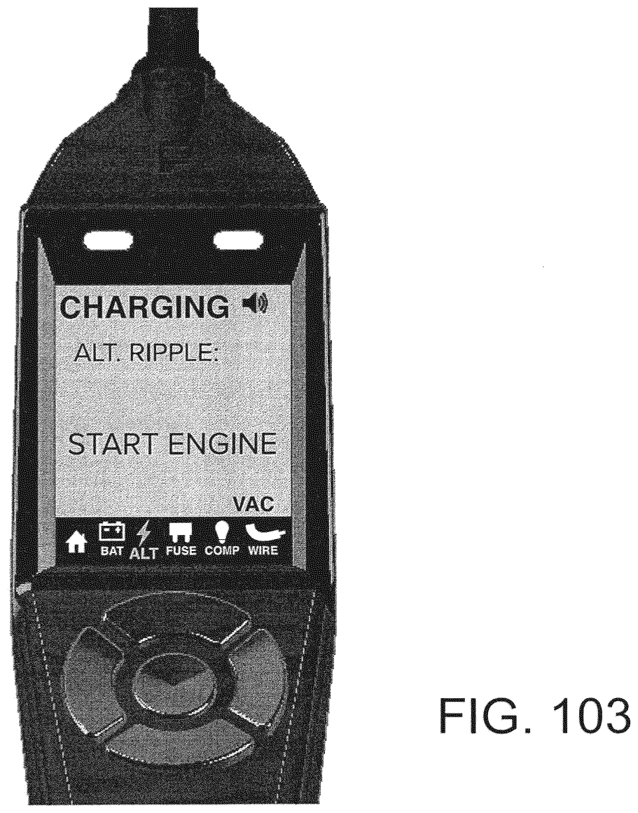

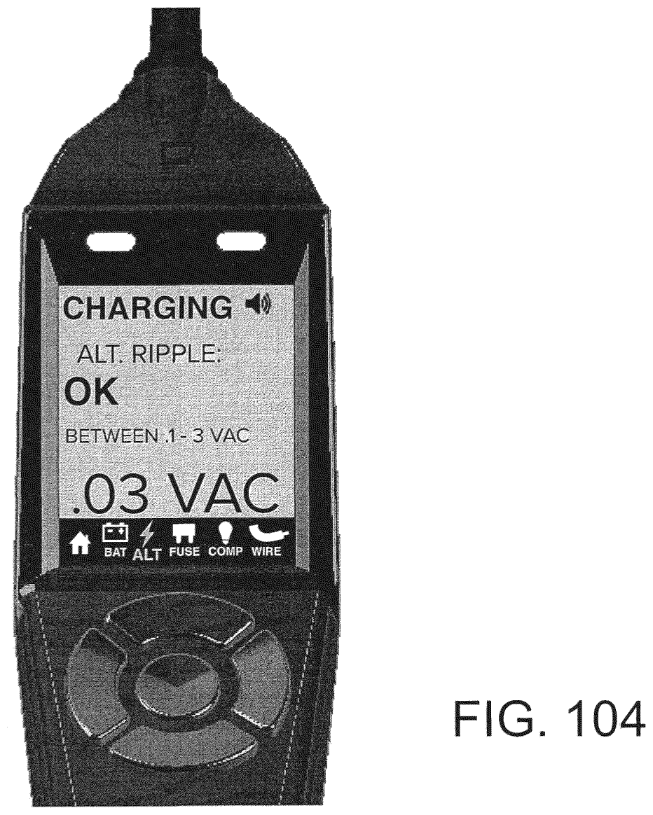

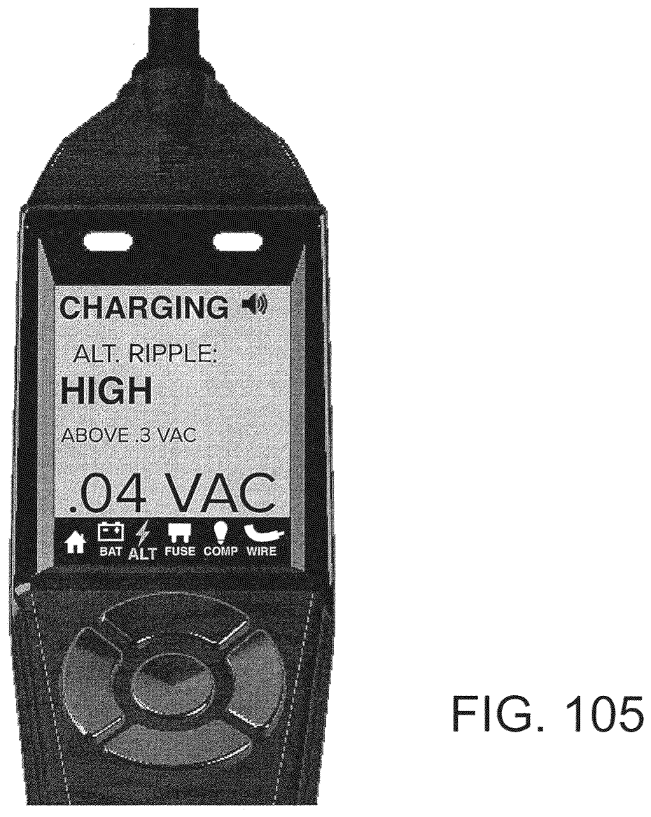

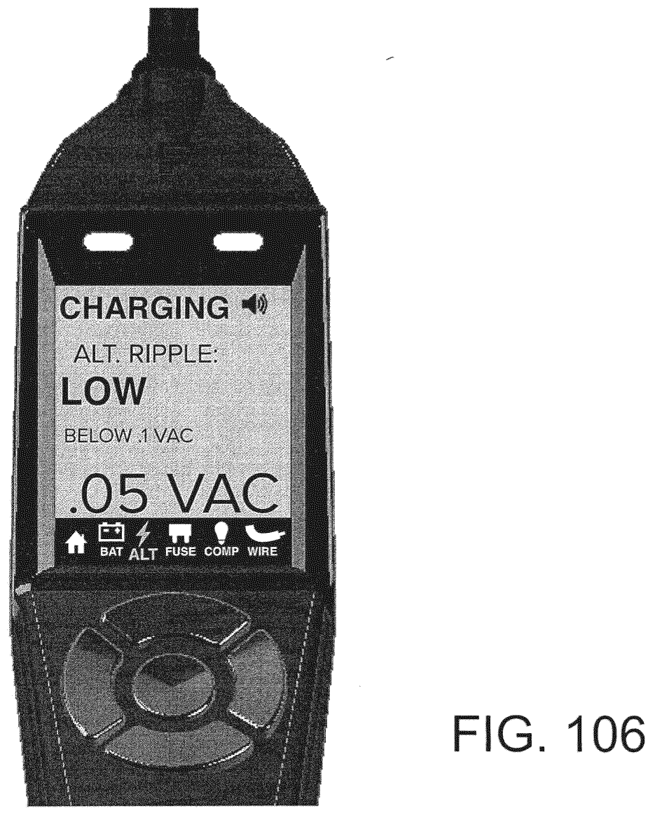

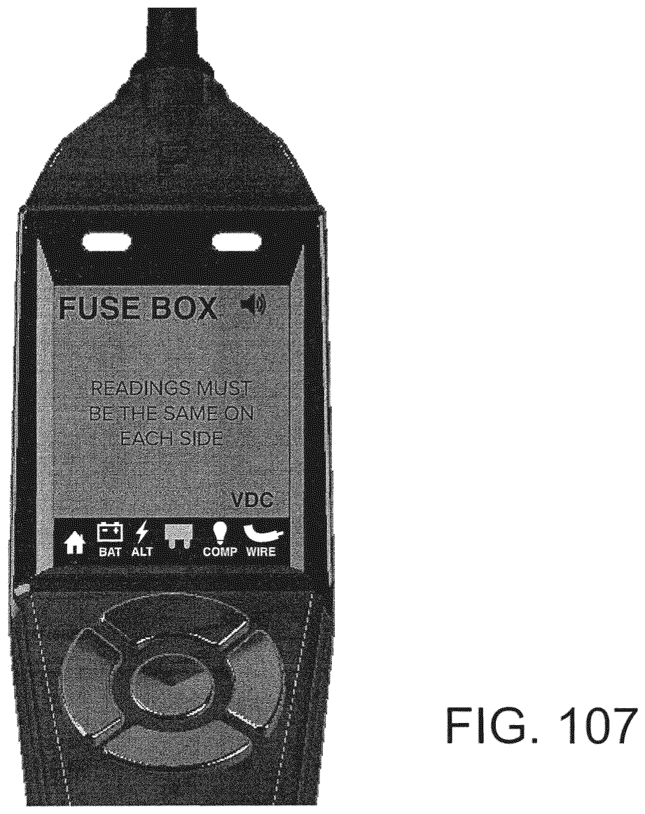

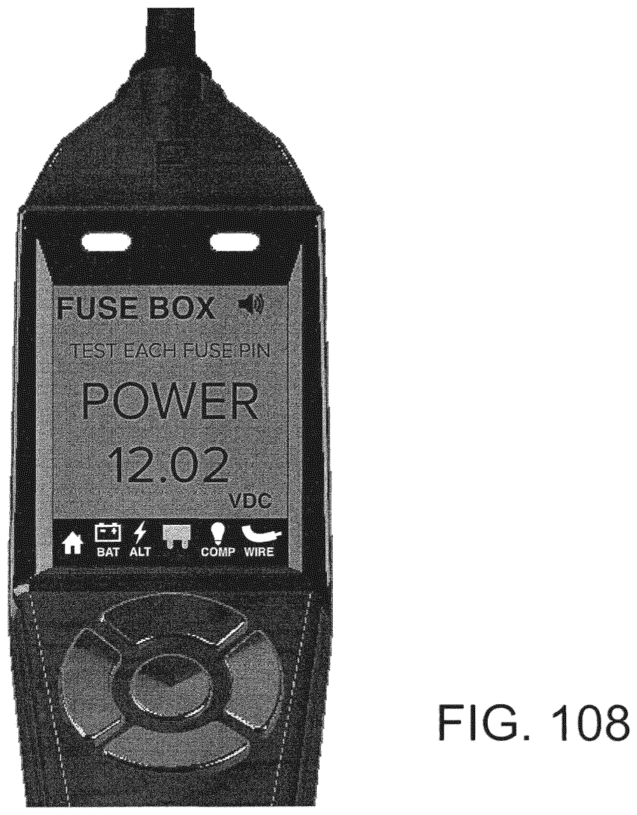

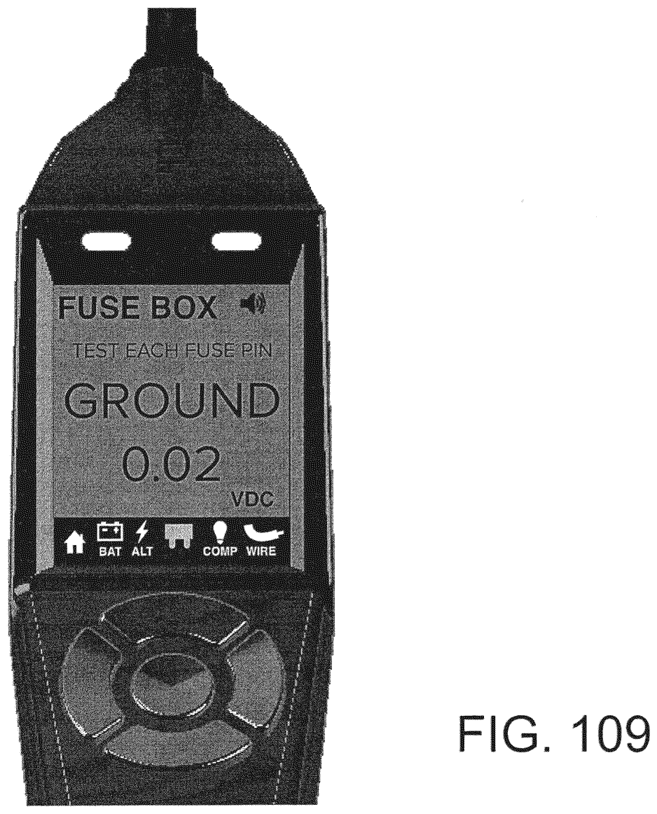

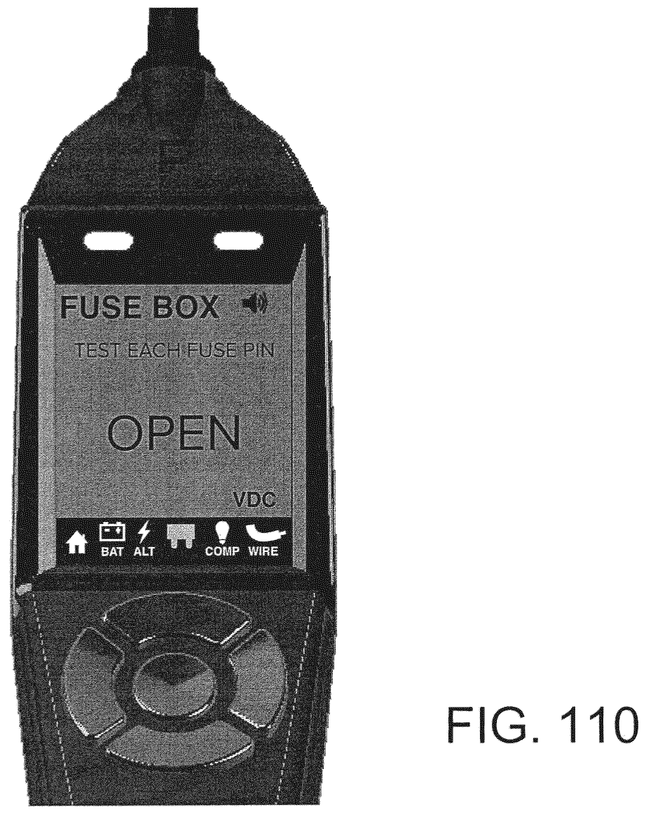

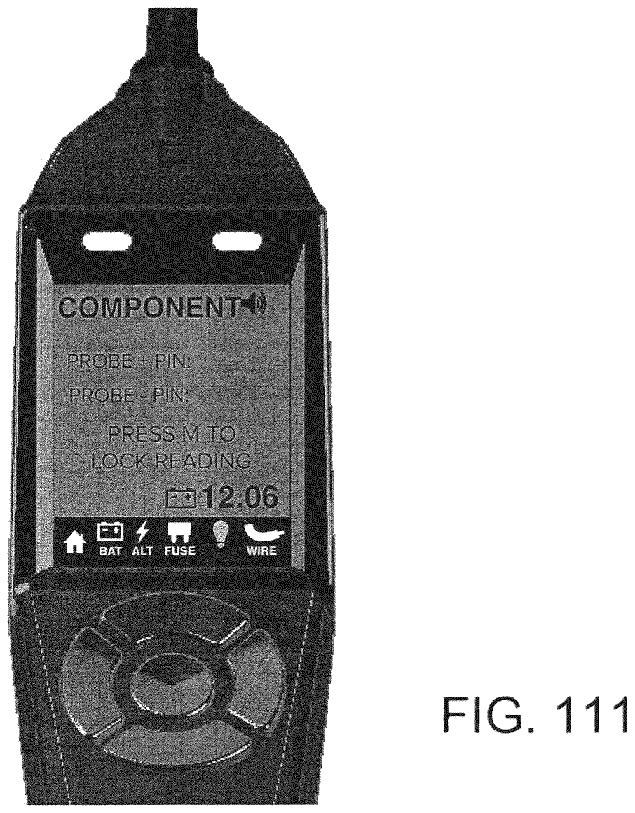

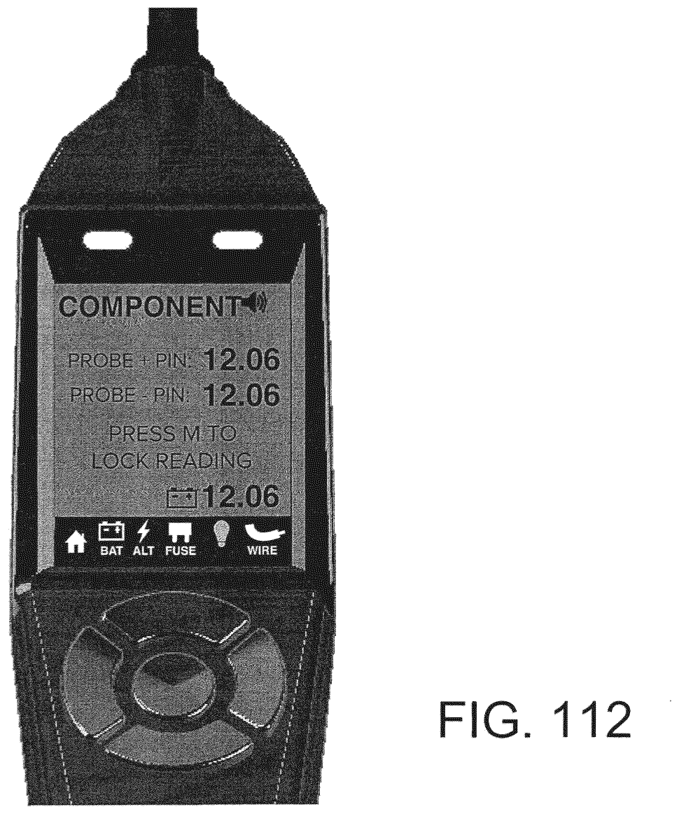

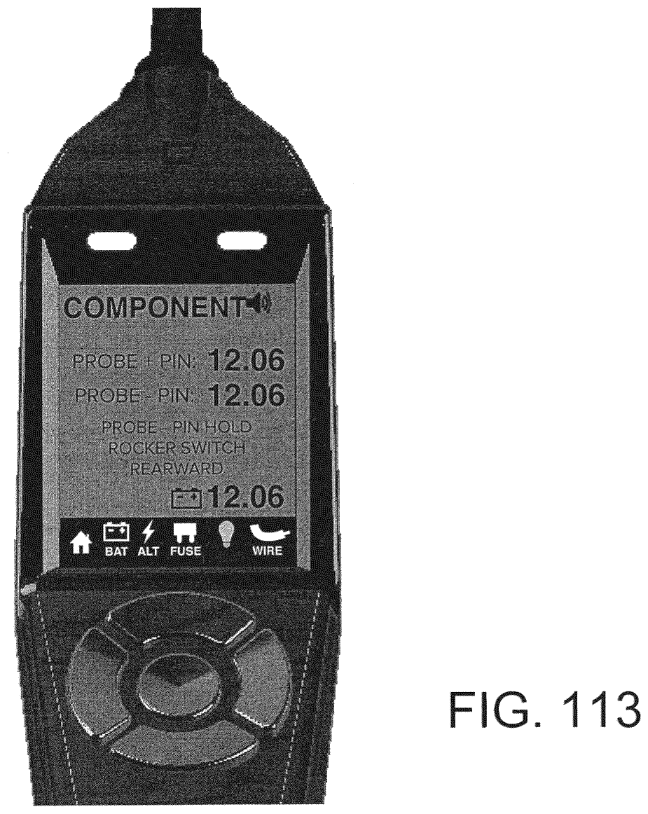

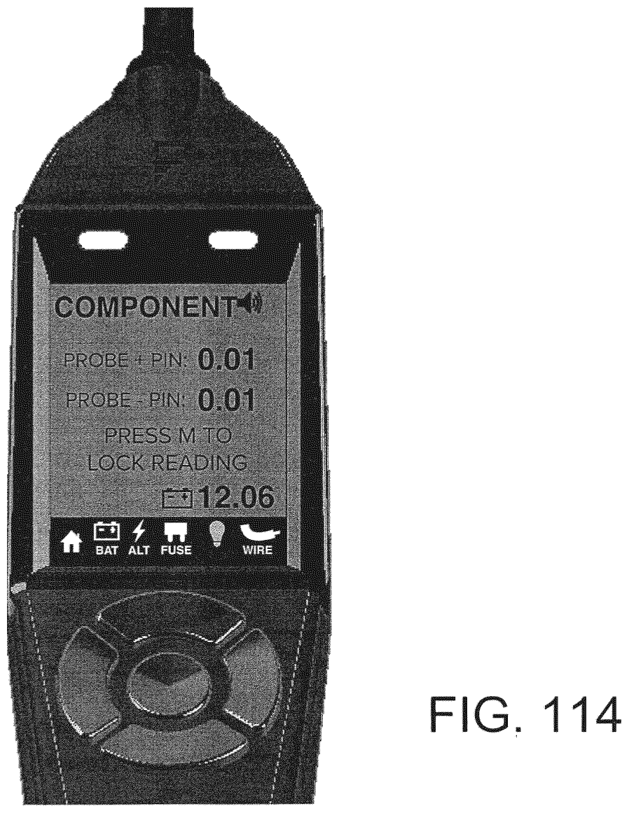

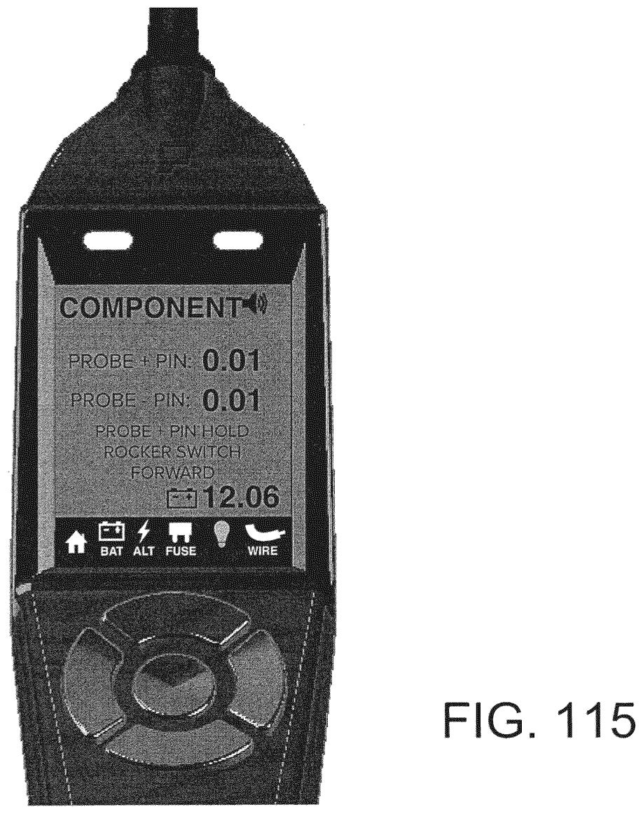

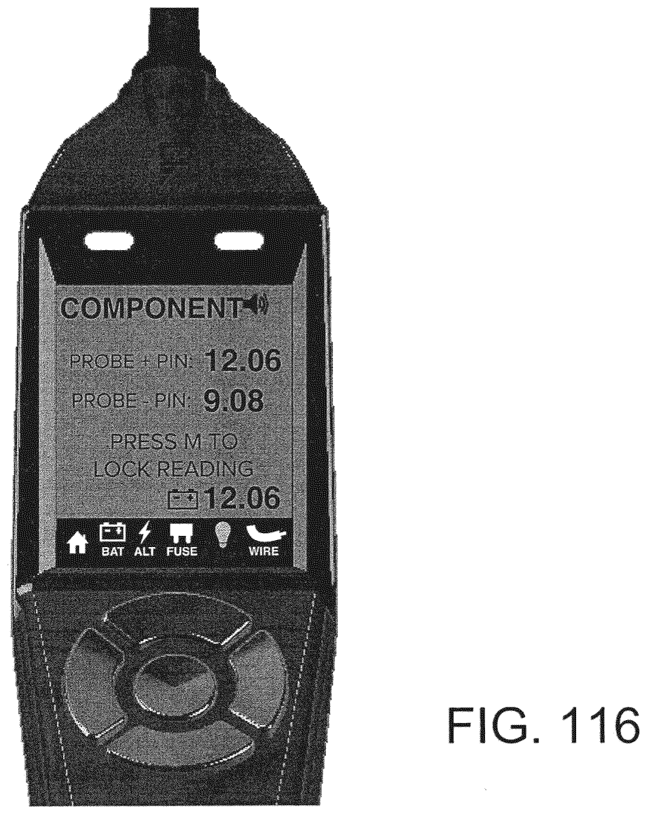

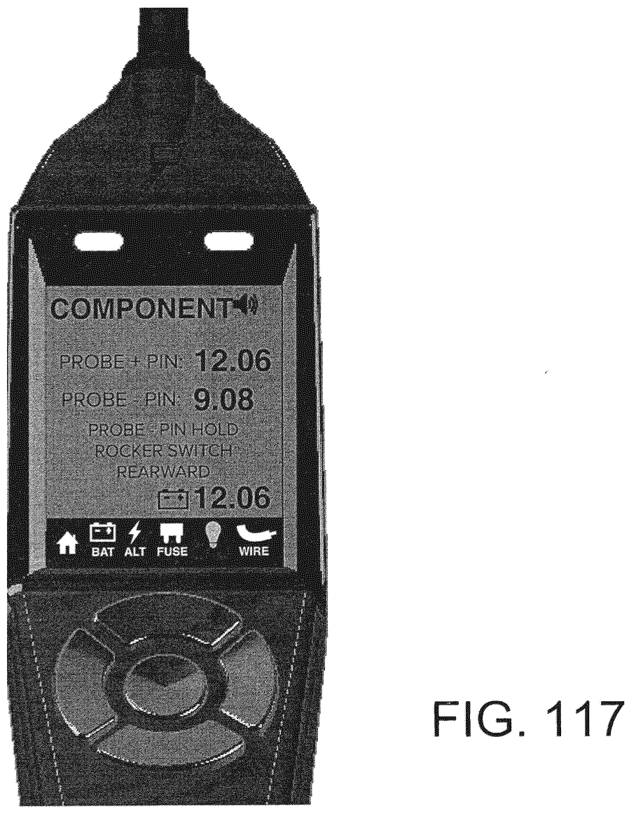

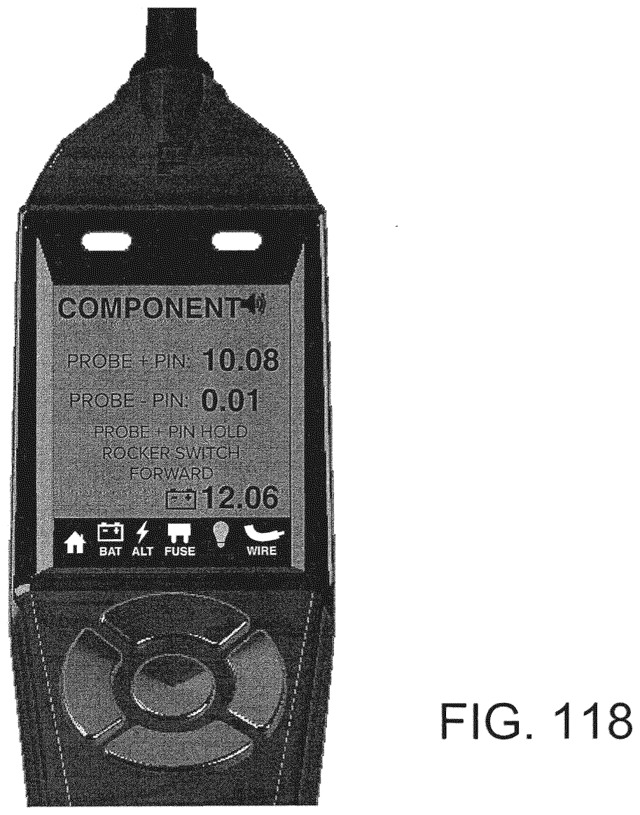

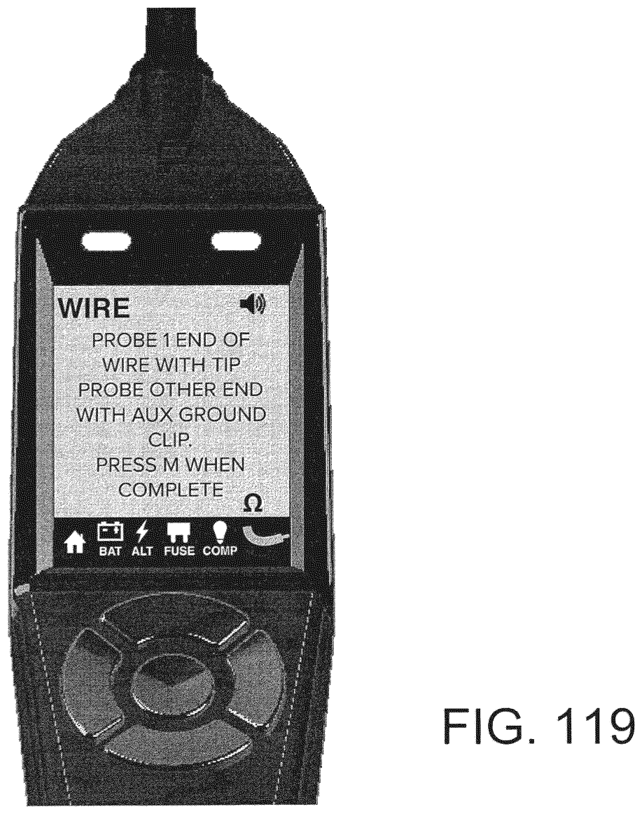

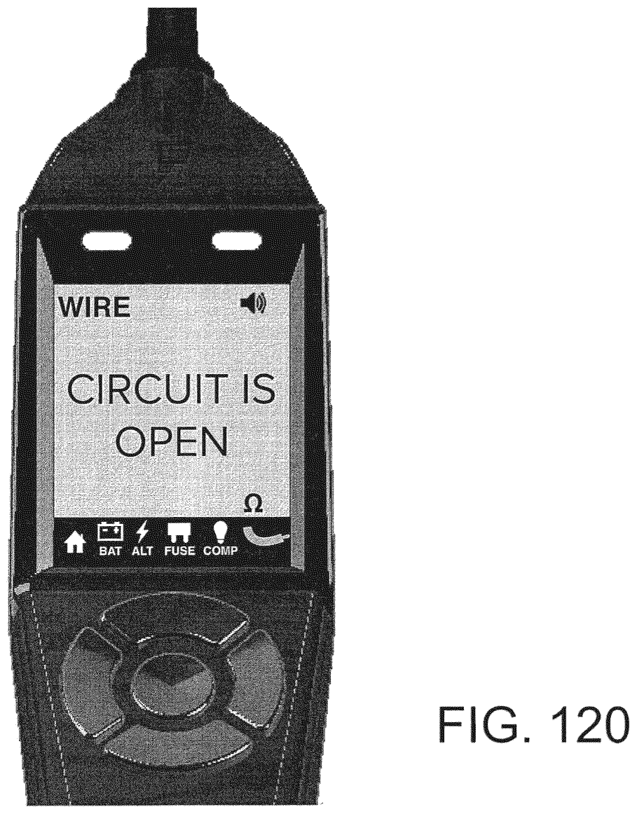

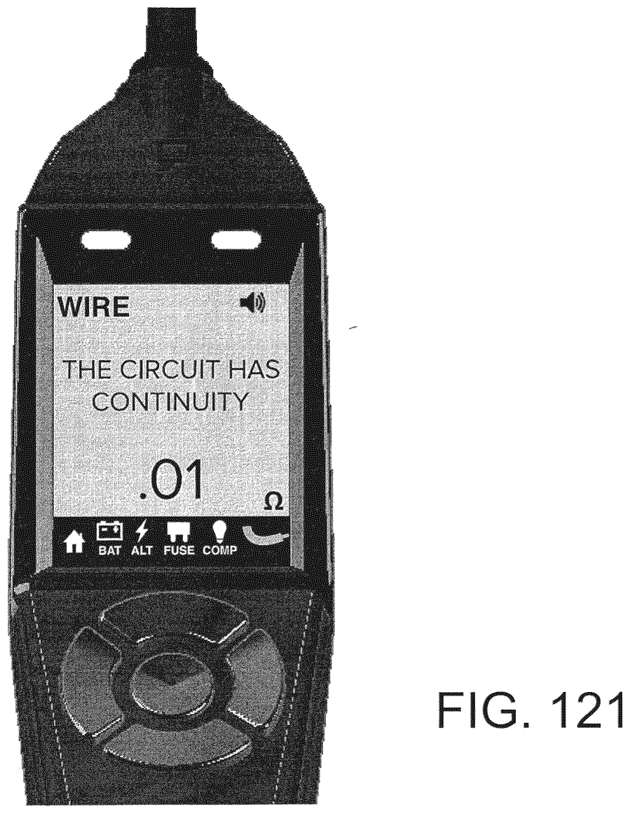

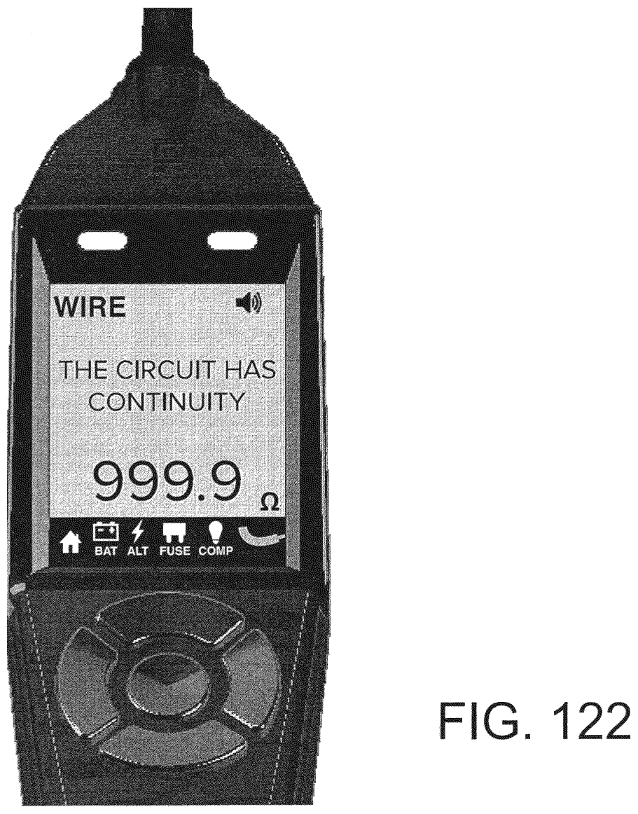

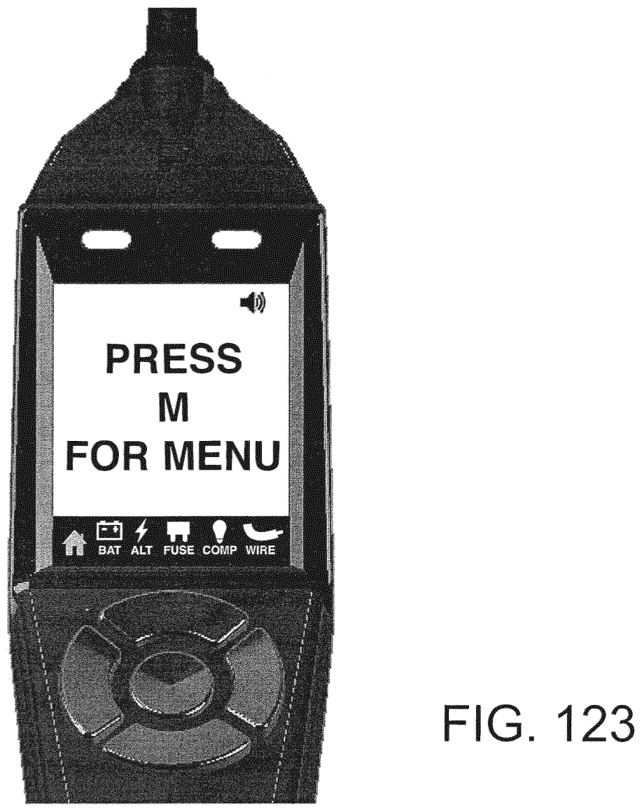

FIGS. 98-123 illustrate an exemplary embodiment of a guided diagnostic functionality of the intelligent diagnostic probe 100 of FIGS. 1-5 that is accessible by selecting a Guided Diagnostics icon shown in FIG. 97. The guided diagnostic functionality of the probe 100 is configured, in some embodiments, to guide the practitioner during measuring and diagnosing faults in various components comprising the vehicle electrical system. In an embodiment, the components include vehicle batteries, alternators, fuses, wires, and any other component that may be locally powered by applying electrical power by way of the probe 100.

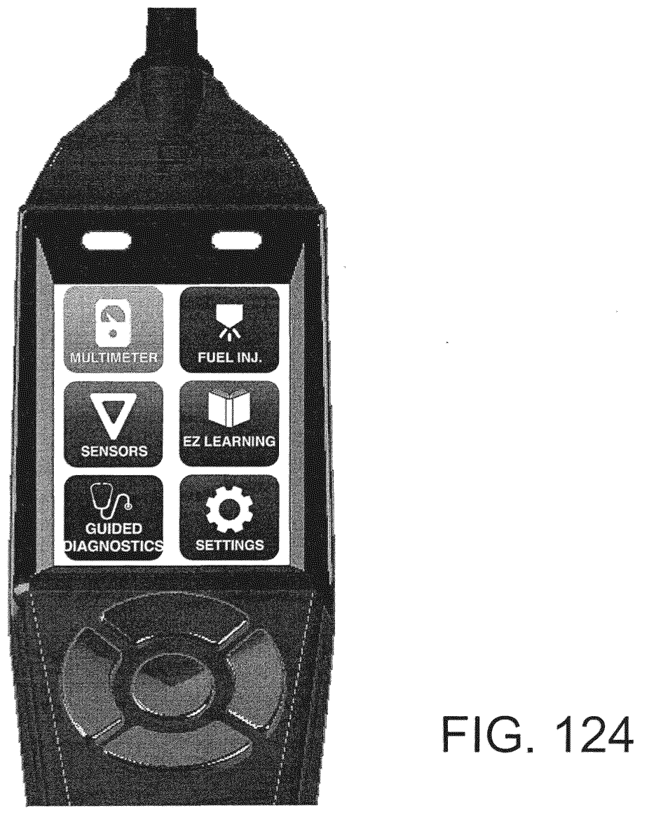

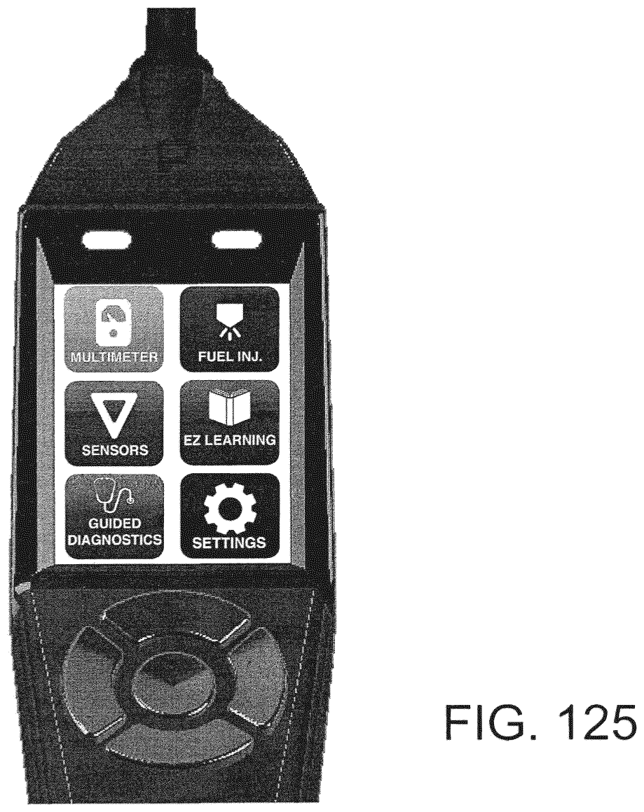

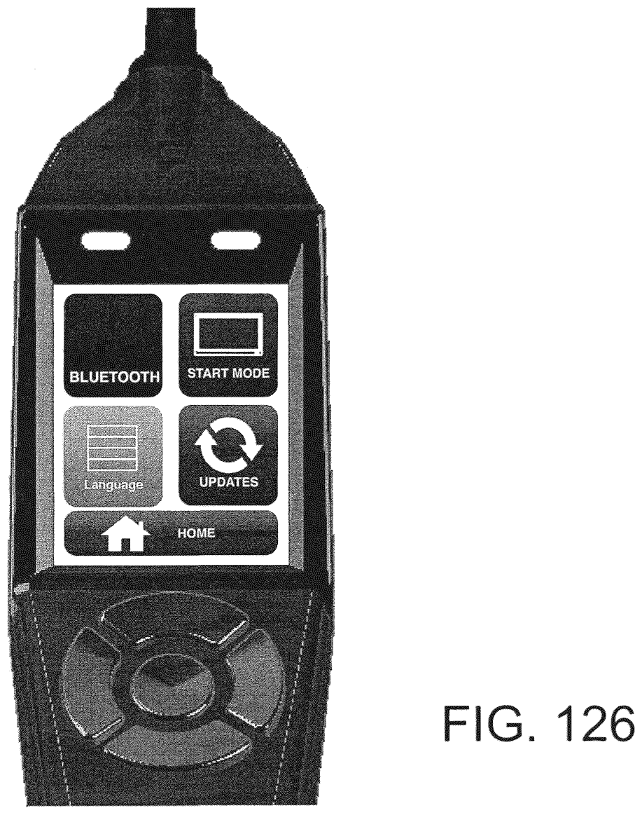

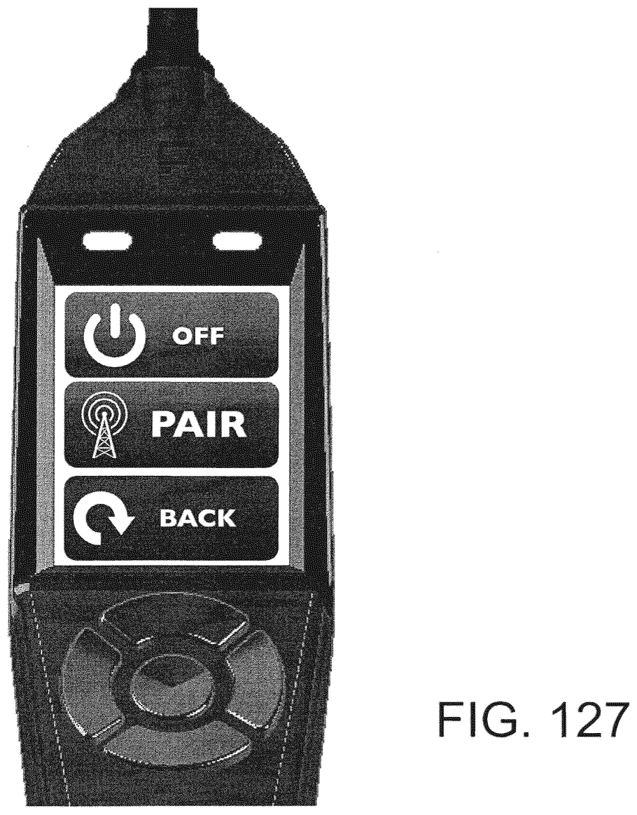

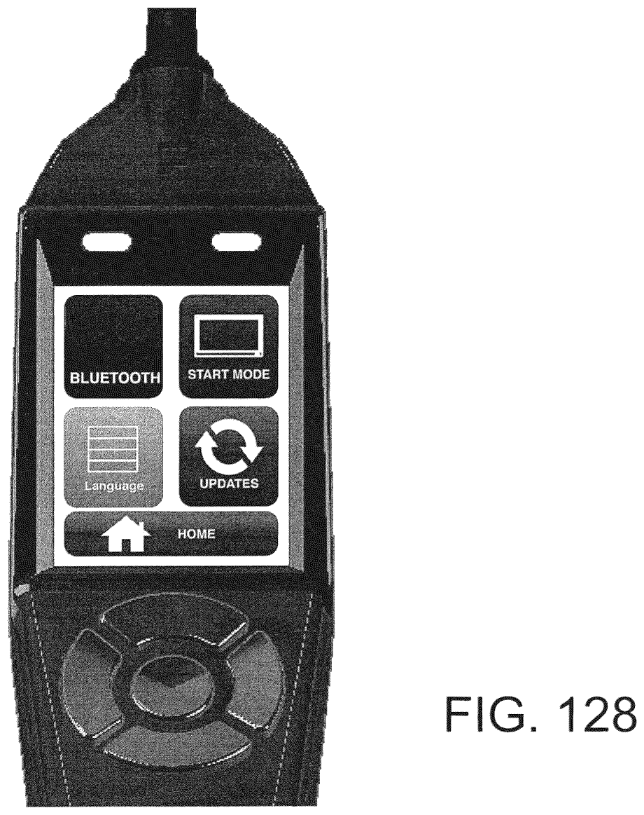

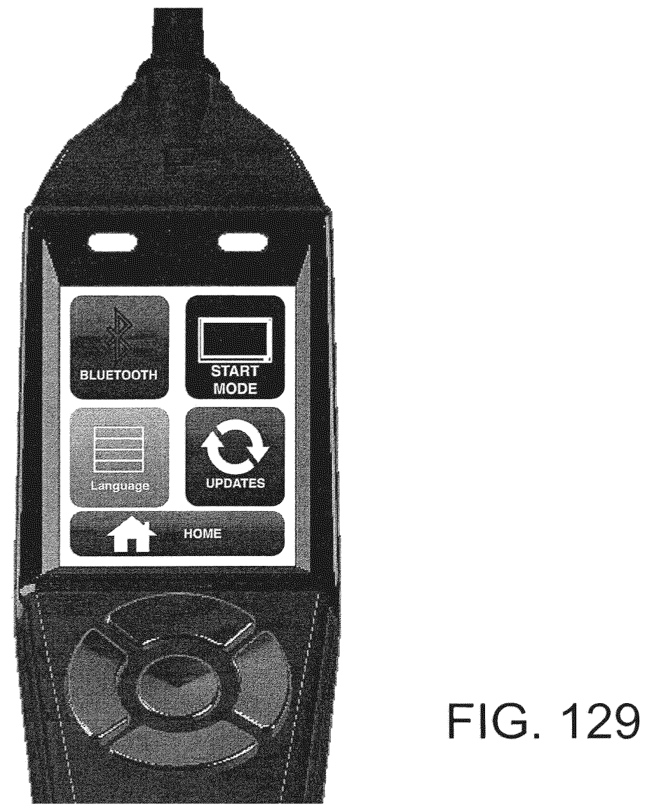

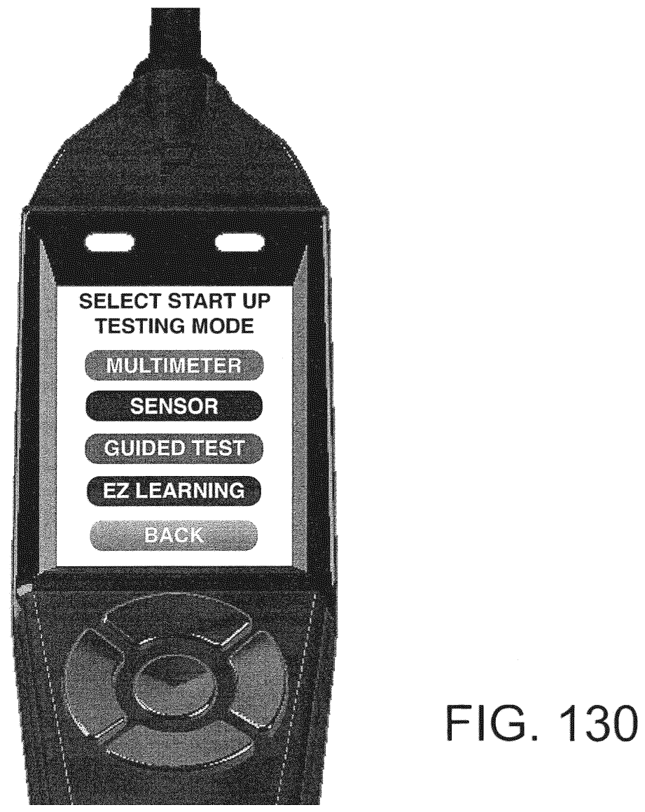

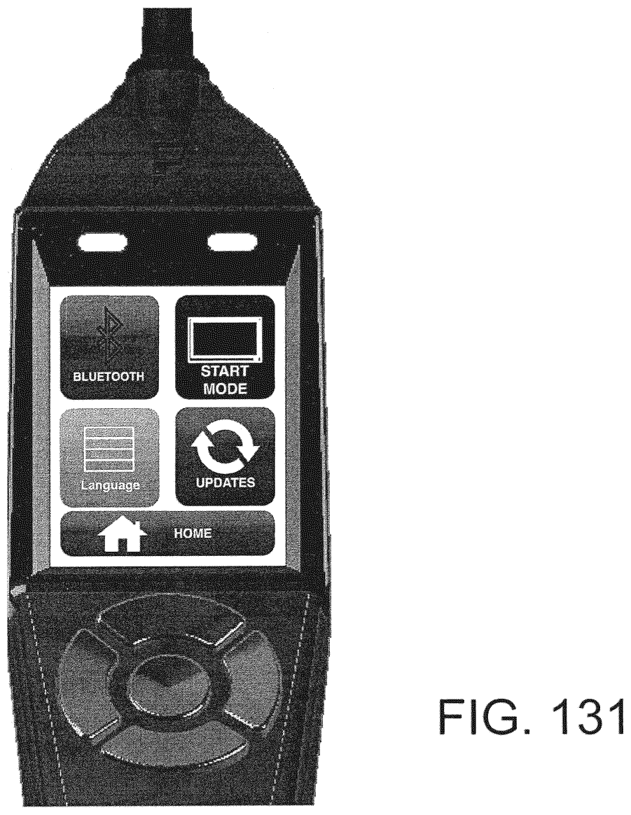

FIGS. 124-125 illustrate an exemplary embodiment of a Settings icon that may be selected to access a multiplicity of settings that affect the operation of the intelligent diagnostic probe 100 of FIGS. 1-5. FIGS. 126-128 illustrate a multiplicity of settings that affect the operation of an exemplary embodiment of a wireless connectivity functionality of the intelligent diagnostic probe 100 of FIGS. 1-5 that is accessible by selecting a Bluetooth icon shown in FIG. 126. FIGS. 129-131 illustrate a multiplicity of settings that affect a start mode of the intelligent diagnostic probe 100 of FIGS. 1-5 that is accessible by selecting a Start Mode icon shown in FIG. 129.

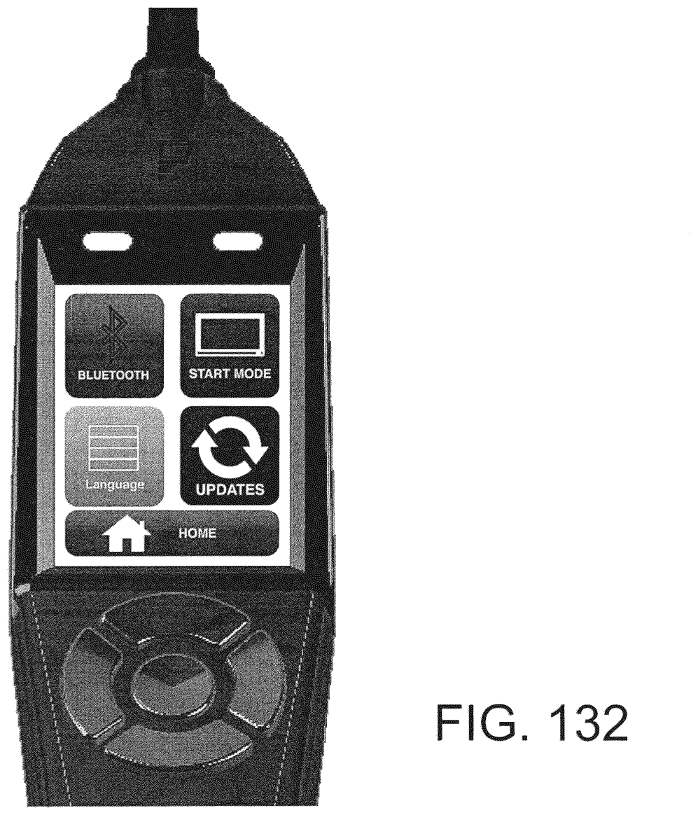

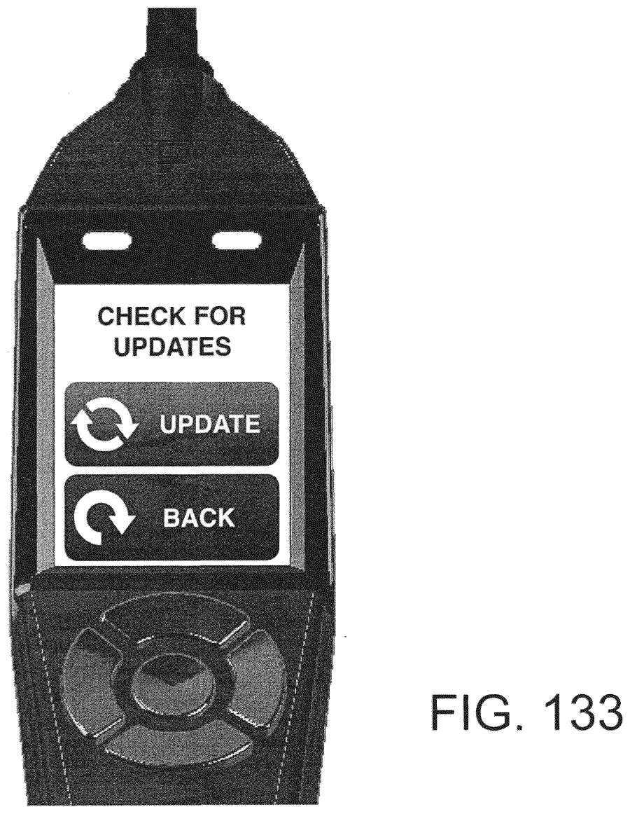

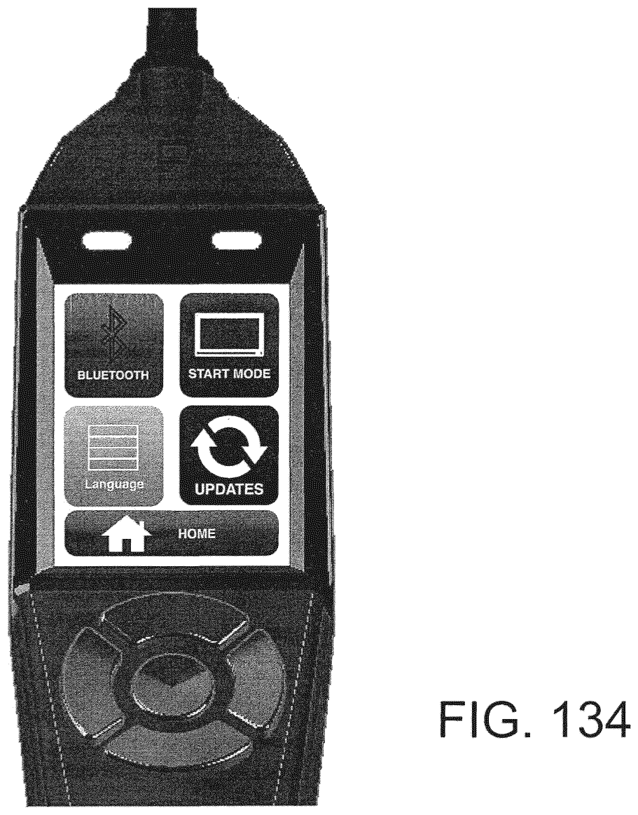

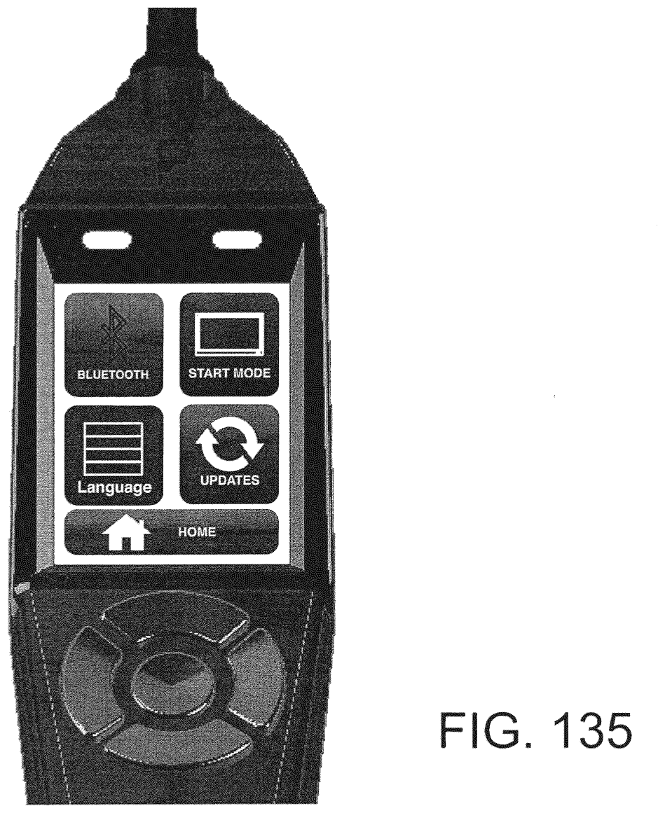

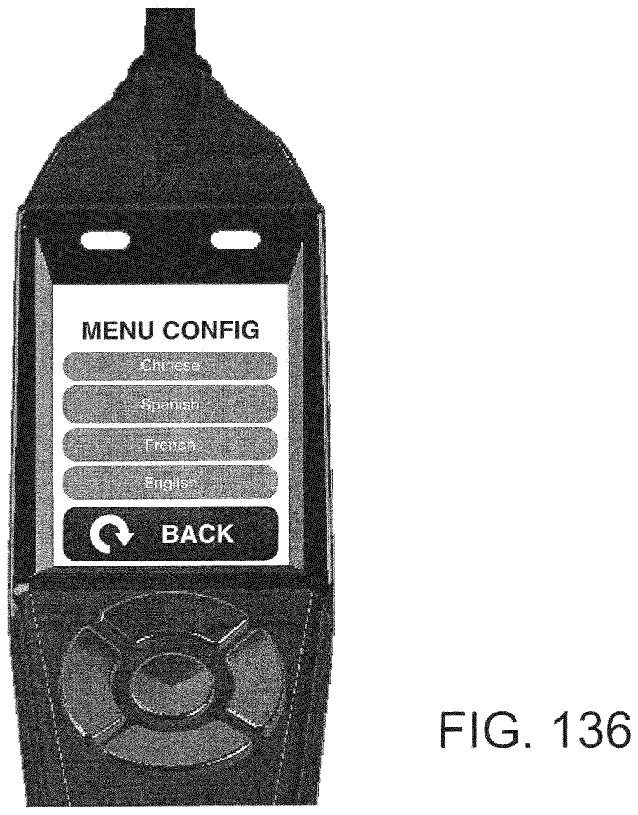

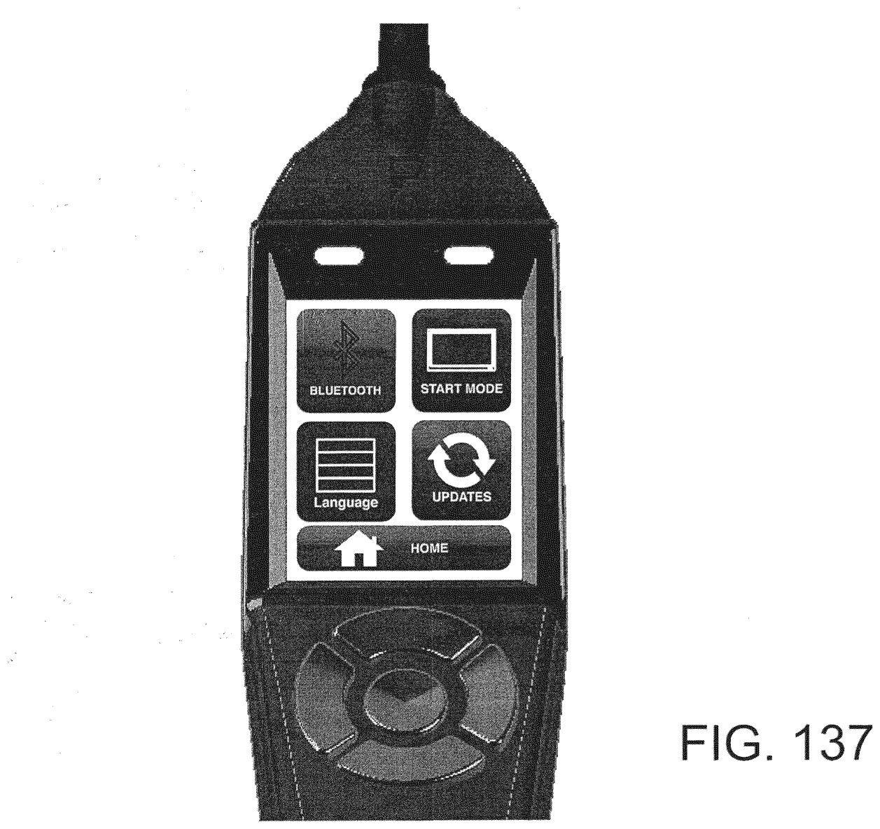

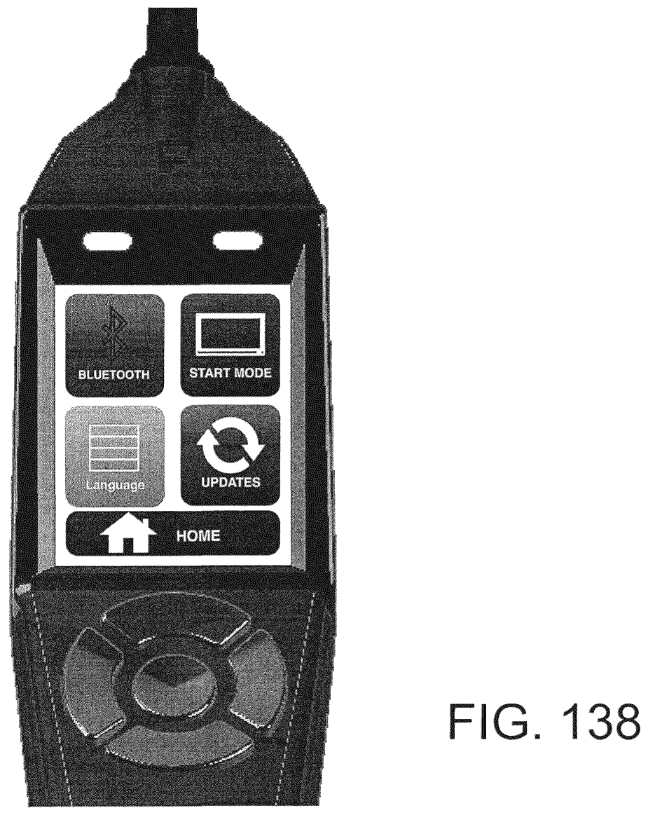

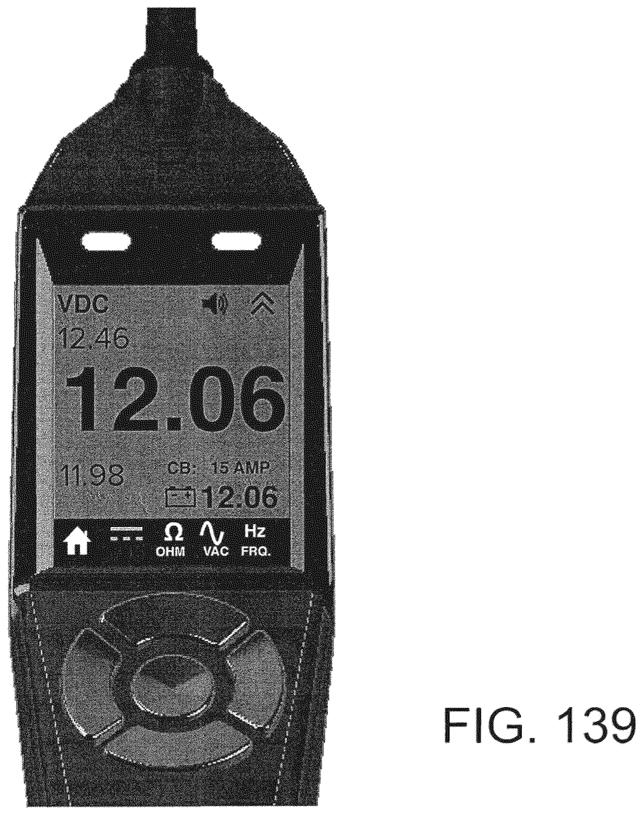

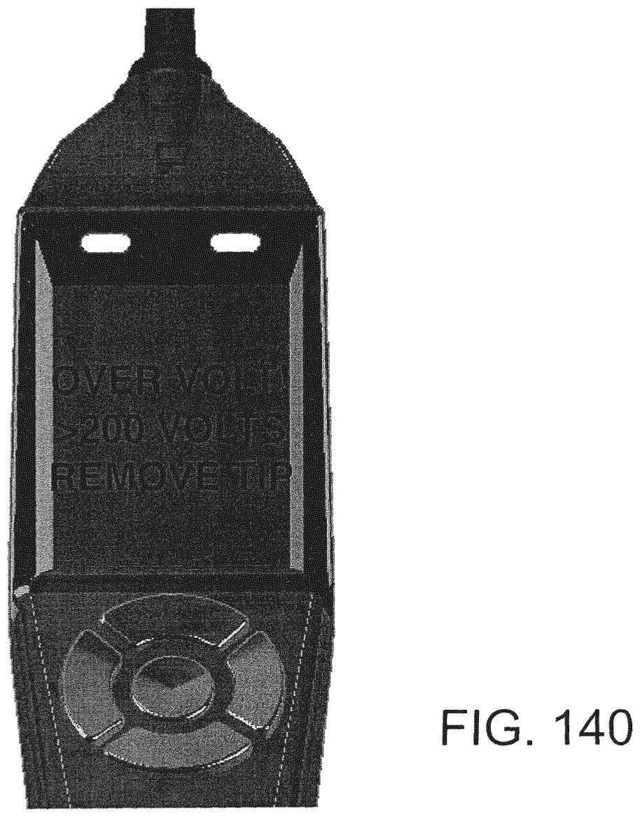

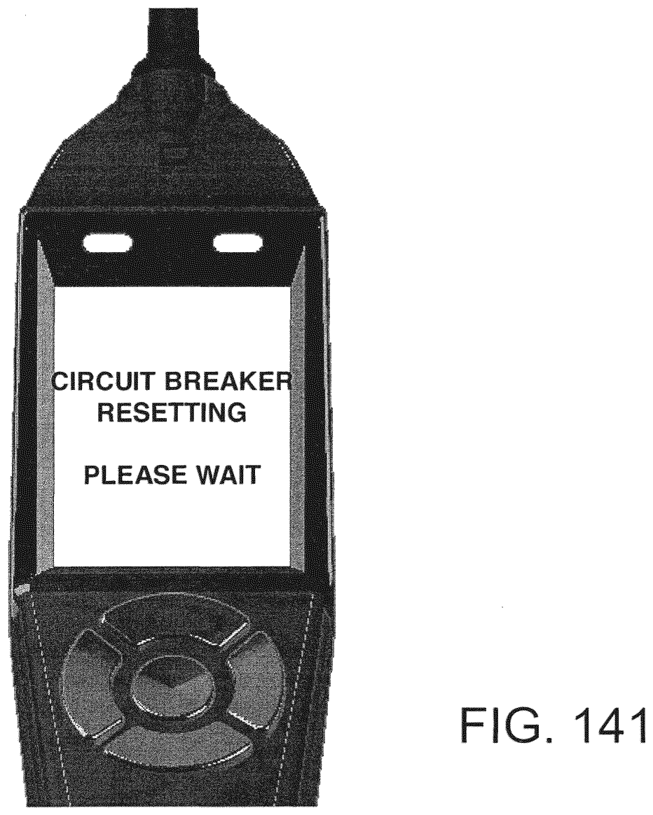

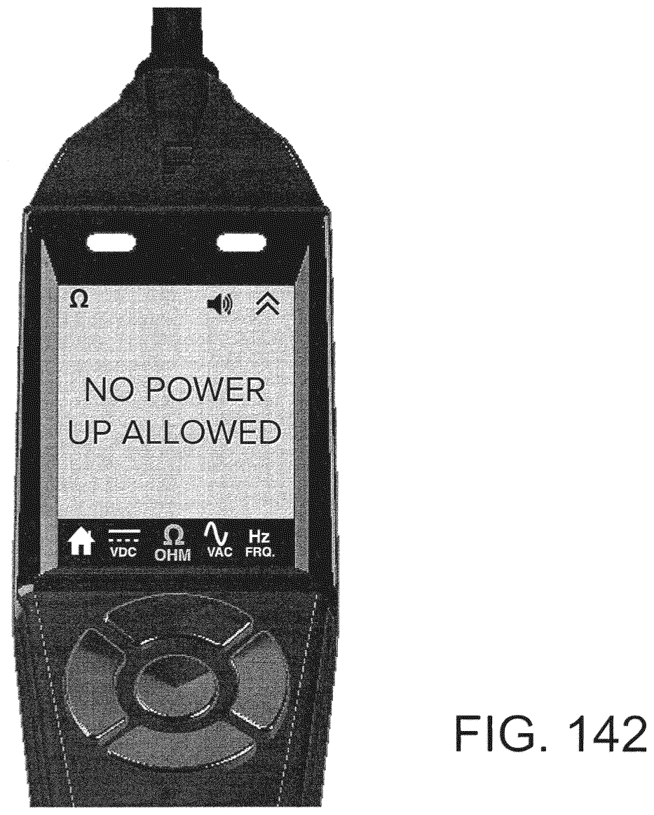

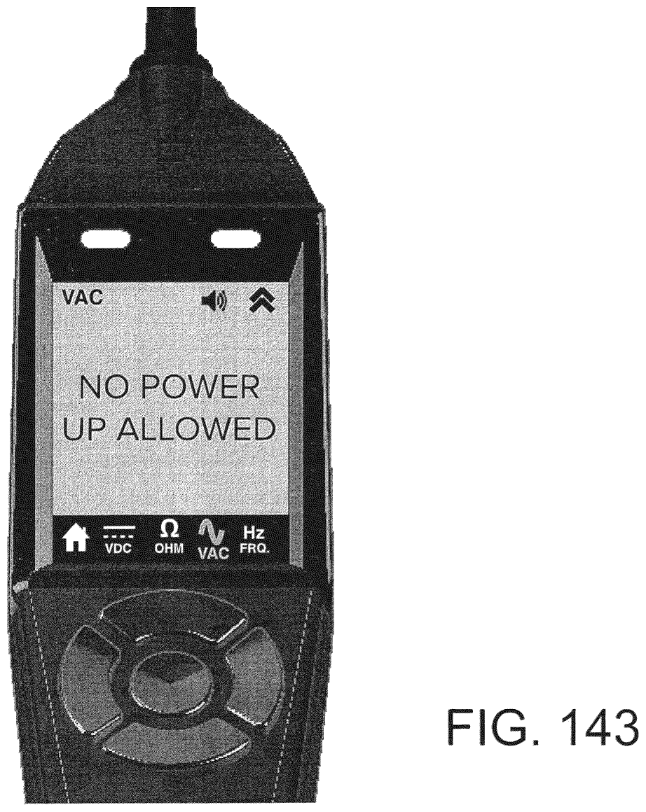

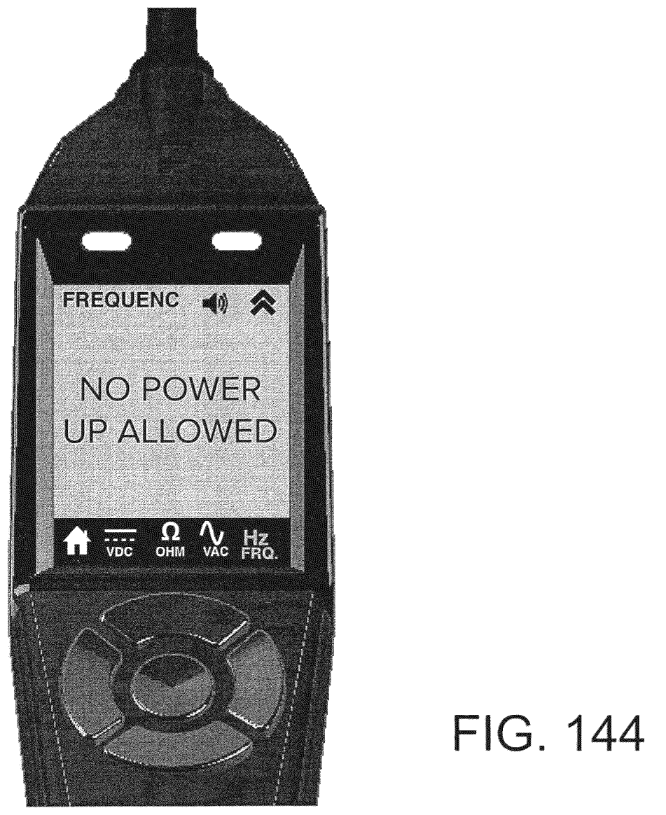

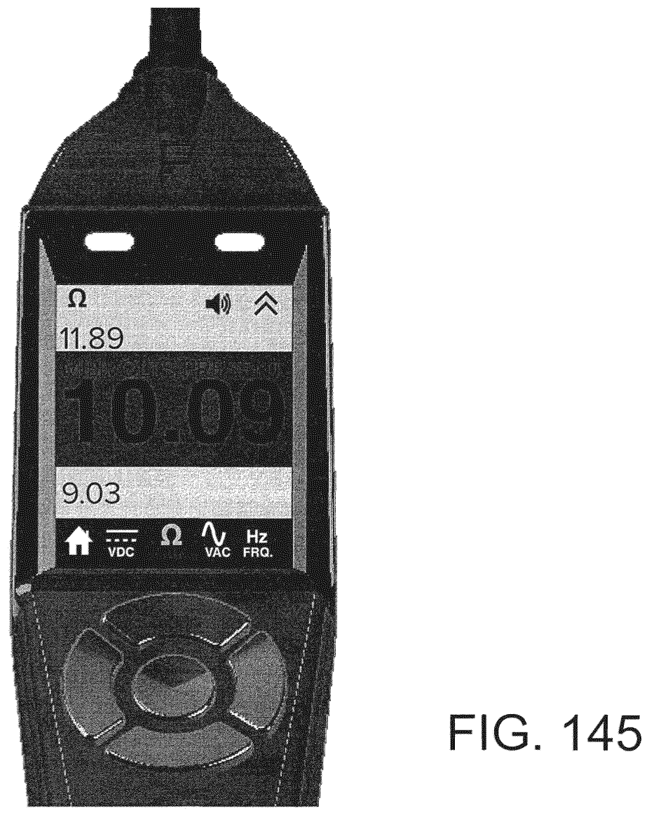

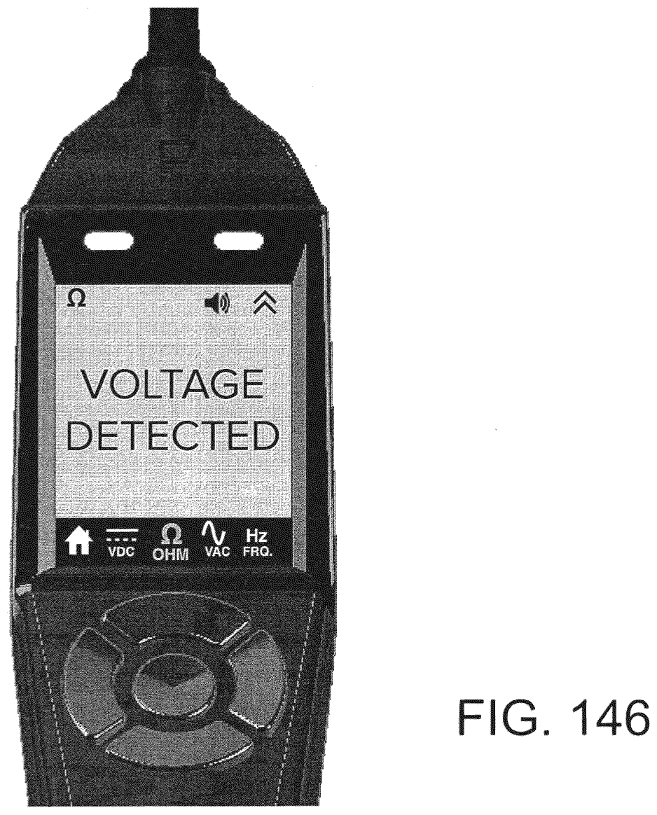

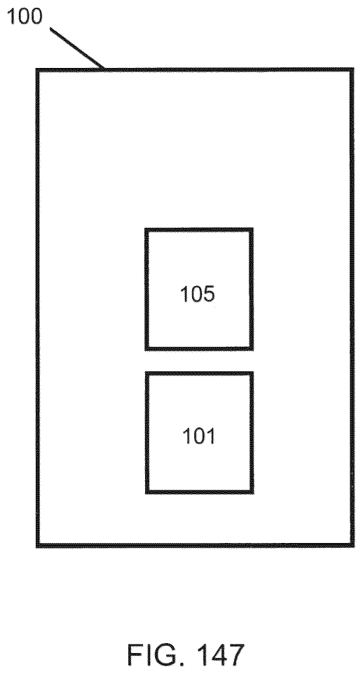

FIGS. 132-134 illustrate a multiplicity of settings that facilitate updating an operating system of the intelligent diagnostic probe 100 of FIGS. 1-5 that is accessible by selecting an Updates icon shown in FIG. 132. FIGS. 135-137 illustrate a multiplicity of setting that facilitate selecting a desired operational language of the intelligent diagnostic probe 100 of FIGS. 1-5 that is accessible by selecting a Language icon shown in FIG. 135. FIG. 138 illustrates an exemplary embodiment of Home icon whereby the intelligent diagnostic probe 100 of FIGS. 1-5 may be returned to a default home screen shown in FIG. 1. FIGS. 139-146 illustrate exemplary embodiments of various alert screens that may be displayed during the course of operating the intelligent diagnostic probe 100 of FIGS. 1-5, as described hereinabove.

While the invention has been described in terms of particular variations and illustrative figures, those of ordinary skill in the art will recognize that the invention is not limited to the variations or figures described. In addition, where methods and steps described above indicate certain events occurring in certain order, those of ordinary skill in the art will recognize that the ordering of certain steps may be modified and that such modifications are in accordance with the variations of the invention. Additionally, certain of the steps may be performed concurrently in a parallel process when possible, as well as performed sequentially as described above. To the extent there are variations of the invention, which are within the spirit of the disclosure or equivalent to the inventions found in the claims, it is the intent that this patent will cover those variations as well. Therefore, the present disclosure is to be understood as not limited by the specific embodiments described herein, but only by scope of the appended claims.

What is claimed is:

1. An intelligent diagnostic probe for providing troubleshooting guidance during diagnosing faults within vehicle electrical systems, the intelligent diagnostic probe comprising:
a housing configured to be grasped in a hand;
a conductive probe element protruding distally from the housing;
a distal probe tip of the conductive probe element configured to be placed into contact with an electrical circuit;
a display screen configured to display measurement data;
a power cable extending from a bottom end of the housing and configured to be connected to a motor vehicle battery; and
a ground lead coupled with the power cable and configured to be electrically connected a ground source; and
wherein the intelligent diagnostic probe is configured to provide an icon-based user interface.

2. The intelligent diagnostic probe of claim 1, wherein the icon-based user interface includes any one or more of a Multimeter icon, an Injector icon, an EZ-Leaming icon, a Settings icon, a Guided Diagnostics icon, and a Sensors icon.

3. The intelligent diagnostic probe of claim 2, wherein the intelligent diagnostic probe includes one or more navigation buttons and a selection button configured to facilitate an operator interacting with the icon-based user interface.

4. The intelligent diagnostic probe of claim 1, wherein the intelligent diagnostic probe is configured to interpret the measurement data so as to provide actionable output for a practitioner operating the intelligent diagnostic probe.

5. The intelligent diagnostic probe of claim 1, wherein the intelligent diagnostic probe is configured to divide diagnosing faults within the vehicle electrical system into procedural segments.

6. The intelligent diagnostic probe of claim 1, wherein the intelligent diagnostic probe is configured to provide appropriate tolerance ranges related to the measurement data.

7. The intelligent diagnostic probe of claim 6, wherein the intelligent diagnostic probe is configured to provide feedback and suggestions regarding the measurement data.

8. The intelligent diagnostic probe of claim 1, wherein the intelligent diagnostic probe is configured to operate as an artificial intelligence that uses a large number of previously coded measurements to learn to accurately diagnose electrical faults based on the current measurement data.

9. The intelligent diagnostic probe of claim 1, wherein the intelligent diagnostic probe comprises a database server system which stores data that is needed during operation of the intelligent diagnostic probe.

10. The intelligent diagnostic probe of claim 9, wherein the database server system comprises data specific to vehicle electrical diagnosis procedures, such as vehicle types, makes and models, measurable tolerance ranges for various components, and any other vehicle-related information that may be associated with operating the intelligent diagnostic probe.

11. The intelligent diagnostic probe of claim 10, wherein the intelligent diagnostic probe is configured to predict vehicle electrical diagnoses by using the vehicle-related data stored in the database server system and raw measurement data to intelligently predict the most likely electrical faults.

12. The intelligent diagnostic probe of claim 1, wherein the intelligent diagnostic probe includes one or more illumination lights that are configured to convey visual indications to an operator of the probe.

13. The intelligent diagnostic probe of claim 12, wherein the one or more illumination lights are light emitting diodes (LEDs) that are configured to emit green and red light so as to convey information to the operator.

14. The intelligent diagnostic probe of claim 13, wherein a green light indicates a measured voltage that is close to a ground voltage and a red light indicates a voltage near a battery voltage.

15. The intelligent diagnostic probe of claim 1, wherein the display screen is configured to display different background colors to indicate different measurement modes.

16. The intelligent diagnostic probe of claim 1, further including a guided multimeter functionality that is divided into a series guided segments in which suitable minimum and maximum values are shown in relation to each measured value.

17. The intelligent diagnostic probe of claim 16, wherein the guided multimeter functionality is configured to facilitate measuring DC/AC voltages, electrical resistance, and electrical frequencies.

18. The intelligent diagnostic probe of claim 1, further including a guided fuel injector analysis functionality that is configured to guide a practitioner through a series of steps comprising a fuel injector analysis.

19. The intelligent diagnostic probe of claim 1, further including a sensor diagnosis functionality that is configured to guide a practitioner through a series of sensor analysis steps and provide troubleshooting based on measured values.

20. The intelligent diagnostic probe of claim 1, further including a guided diagnostic functionality that is configured to guide a practitioner through a series of steps comprising measuring and diagnosing faults in various components comprising a vehicle electrical system.
